(19) United States
(12) Patent Application Publication
(10) Pub. No.: US 2010/0261103 A1
(43) Pub. Date: Oct. 14, 2010

(54) ORGANIC PIGMENT FINE PARTICLES AND METHOD OF PRODUCING THE SAME, PIGMENT-DISPERSION COMPOSITION, PHOTOCURABLE COMPOSITION AND INK-JET INK CONTAINING THE SAME, AND COLOR FILTER USING THE SAME AND METHOD OF PRODUCING THE SAME

(75) Inventors: Daisuke Sasaki, Shizuoka (JP); Hidenori Takahashi, Shizuoka (JP); Makoto Ohmoto, Kanagawa (JP); Toshitaka Ninomiya, Shizuoka (JP); Masato Nakao, Shizuoka (JP)

Correspondence Address: SUGHRUE MION, PLLC, 2100 PENNSYLVANIA AVENUE, N.W., SUITE 800, WASHINGTON, DC, 20037, US

(73) Assignee: FUJIFILM Corporation, Minato-ku, Tokyo (JP)

(21) Appl. No.: 12/739,614

(22) PCT Filed: Oct. 24, 2008
(86) PCT No.: PCT/JP2008/069377

§ 371 Date: Apr. 23, 2010

(30) Foreign Application Priority Data
Oct. 25, 2007 (JP) 2007-277471
Apr. 28, 2008 (JP) 2008-117583

(51) Int. Cl. G03C 1/73; G03F 1/00

(52) U.S. Cl. 430/7; 430/270.1; 430/286.1; 430/287.1

(57) ABSTRACT

Organic pigment fine particles, having capability of self-dispersion, having an organic pigment and a polymer compound, the organic pigment fine particles of being nanometer-sized fine particles obtained by mixing an organic pigment solution and a second solvent, thereby to precipitate the fine particles in the mixed liquid, the organic pigment solution prepared by dissolving the organic pigment and the polymer compound in a first solvent, the second solvent of being served as a poor solvent for the organic pigment and being compatible with the first solvent, in which a compound insoluble in the second solvent is used as the polymer compound, and the organic pigment fine particles are provided with a capability of self-dispersing in a third solvent different from any of the first solvent and the second solvent.

### TECHNICAL FIELD

The present invention relates to organic pigment fine particles and a method of producing the same; a pigment-dispersion composition, a photocurable composition and an ink-jet ink containing the same; and a color filter using the same and a method of producing the same.

### BACKGROUND ART

Color filters are precision members for use in cutting-edge imaging-related equipments such as liquid crystal color displays and video cameras, having pixel sections colored in red (R), green (G) and blue (B), respectively, formed on a substrate. Each of these colored pixel sections has a microstructure in which a thin film of a resin having an organic pigment of said each colors dispersed therein is provided on the substrate so that the display of a predetermined hue may be reproduced. A photocurable pigment composition used for forming this colored pixel section is prepared by regulating chemical properties by adding a resin or the like as necessary, to a pigment dispersion liquid formed by dispersing an organic pigment and a photocurable compound.

In order to satisfy the requirements of the imaging-related equipments such as those described above, very sophisticated properties are to be possessed in the precision members. High performance and high quality are also required of color filters. Thus, an improvement is attempted to achieve the organic pigments for suitably use in the production of color filters. Specifically, organic pigments are required to have excellent storage stability in the preparation of a pigment dispersion composition, excellent contrast of the coating of the color filter colored pixel sections using the pigment dispersion composition, and the like.

Therefore, for example, a study is being vigorously conducted to reduce the size of pigment particles to a range of 10 to 100 nm and to apply the pigment particles to various applications. This is an attempt to discover a new characteristic that is conventionally unpredictable, through an operating effect that is exhibited for the first time by reducing the size of the pigment particles to a nanometer size. For example, the research and development of the pigment particles are in progress for paints, printing inks, electrophotographic toners, inkjet inks, color filters, and the like. Particularly, in regard to the color filters and inkjet inks mentioned above, efforts are being taken for an enhancement of performance using fine chemistry technologies, in anticipation of the results.

Here, to mention a method for dispersing an organic pigment, there are available various milling methods (break-down methods) such as a bead milling method or a salt milling method, and a liquid phase method, but it is difficult to sufficiently micronize an organic pigment by the milling methods and to disperse the organic pigment in a composition (see JP-A-2000-239554 (“JP-A” means unexamined published Japanese patent application)). The liquid phase method is suitable for obtaining fine pigment particles, and specifically, there has been suggested a method of mixing a pigment solution prepared by dissolving a pigment in a good solvent (first solvent), with a poor solvent (second solvent) to precipitate nanoparticles, and adding a predetermined polymer compound thereto (see WO 2006/121016 pamphlet, JP-A-2004-43776, JP-A-2007-119586 and JP-A-2007-23169). However, in regard to the conventional technologies, there are no disclosures on efficiently removing the first solvent and the second solvent, and redispersing the produced pigment fine particles sufficiently in a third solvent which is different from these first and second solvents; and on providing the produced fine particles with spontaneous dispersibility (self-dispersibility) in this third solvent. For example, in Patent Document 5, particles are formed by dissolving polyvinylpyrrolidone in a pigment solution, but since this polymer is dissoluble in an aqueous medium that is used as the second solvent (poor solvent), it is difficult to remove the polymer from a fine particle dispersion liquid obtained by mixing the pigment solution and the second solvent. Furthermore, in order to disperse the pigment fine particles in a new third solvent, usually it is necessary to add a dispersant other than the above-described polymer.

### DISCLOSURE OF INVENTION

According to the present invention, there is provided the following means:
(1) Organic pigment fine particles, having capability of self-dispersion, having:

an organic pigment and a polymer compound,

the organic pigment fine particles of being nanometer-sized fine particles obtained by mixing an organic pigment solution and a second solvent, thereby to precipitate the fine particles in the mixed liquid, the organic pigment solution prepared by dissolving the organic pigment and the polymer compound in a first solvent, the second solvent of being served as a poor solvent for the organic pigment and being compatible with the first solvent,

wherein a compound insoluble in the second solvent is used as the polymer compound, and the organic pigment fine particles are provided with a capability of self-dispersing in a third solvent different from any of the first solvent and the second solvent.
(2) The organic pigment fine particles as described in the above item (1), wherein a mass average molecular weight of the polymer compound is 1,000 to 500,000.
(3) The organic pigment fine particles as described in the above item (1) or (2), wherein the polymer compound is at least one selected from the group consisting of a polymer or copolymer of a vinyl monomer, an ester polymer, an ether polymer, a modified substance thereof, and a copolymer thereof.
(4) The organic pigment fine particles as described in any one of the above items (1) to (3), wherein the polymer compound is a polymer and/or copolymer of a vinyl monomer having a hydrocarbon group having 4 or more carbon atoms.
(5) The organic pigment fine particles as described in any one of the above items (1) to (4), wherein the polymer compound has a repeating unit represented by formula (1):

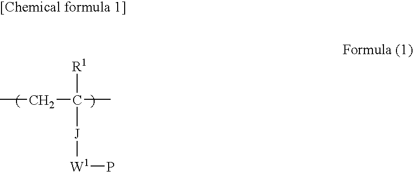

wherein R¹ represents a hydrogen atom or a methyl group; J represents —CO—, —COO—, —CONR⁶—, —OCO—, a phenylene group, or —C₆H₄CO—; R⁶ represents a hydrogen atom, an alkyl group, an aryl group, or an aralkyl group; W¹ represents a straight-chain, branched, or cyclic alkylene group or aralkylene group, or a single bond; and P represents a heterocyclic group.
(6) The organic pigment fine particles as described in any one of the above items (1) to (5), wherein the polymer compound has a repeating unit represented by formula (2) or (3):

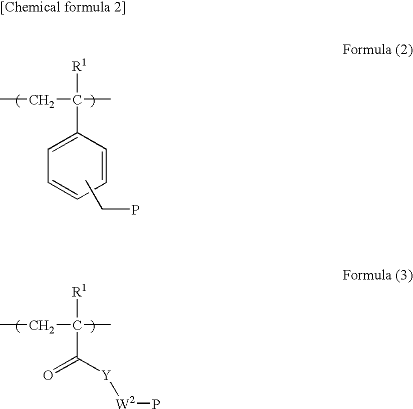

wherein R¹ represents a hydrogen atom or a methyl group; Y represents —NH—, —O—, or —S—; W² represents a single bond or a divalent linking group; and P represents a heterocyclic group.
(7) The organic pigment fine particles as described in the above item (5) or (6), wherein P in formula (1), (2) and (3) is represented by formula (4) or a tautomeric structure thereof:

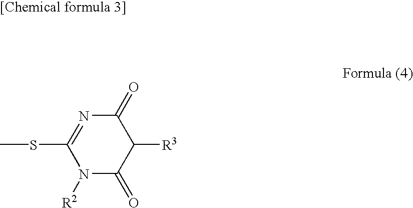

wherein R² represents a substituted or unsubstituted alkyl group, a substituted or unsubstituted aryl group, or a hydrogen atom; and R³ represents a hydrogen atom, an alkyl group, an aryl group, a halogen atom, or an azo group.
(8) The organic pigment fine particles as described in any one of the above items (1) to (7), wherein the polymer compound is a graft copolymer having a side chain formed from a polymerizable oligomer having an ethylenically unsaturated double bond at its terminal.
(9) The organic pigment fine particles as described in any one of the above items (1) to (8), wherein the organic pigment solution further has at least one organic compound having a basic group or an acidic group.
(10) The organic pigment fine particles as described in any one of the above items (1) to (9), wherein the organic pigment solution and the second solvent are mixed under a condition in which a Reynolds number Re represented by expression (1) is 50 or more:

Re=ρUL/μ (1)

wherein Re represents the Reynolds number; ρ represents a density of the organic pigment solution; U represents a relative velocity at which the organic pigment solution comes in contact with the second solvent; L represents an equivalent diameter of a flow path or a supply inlet at a part where the organic pigment solution comes in contact with the second solvent; and μ represents a viscosity coefficient of the organic pigment solution.
(11) The organic pigment fine particles as described in any one of the above items (1) to (10), wherein the first solvent is at least one selected from the group consisting of an organic acid, an organic base, a sulfoxide compound solvent, and an amide compound solvent.
(12) The organic pigment fine particles as described in any one of the above items (1) to (11), wherein the second solvent is at least one selected from the group consisting of an aqueous medium and an alcohol compound solvent.
(13) The organic pigment fine particles as described in any one of the above items (1) to (12), wherein the third solvent is at least one selected from the group consisting of an ether compound solvent, an ester compound solvent, an aromatic hydrocarbon compound solvent, and an aliphatic hydrocarbon compound solvent.
(14) The organic pigment fine particles as described in any one of the above items (1) to (13), wherein the organic pigment solution has the polymer compound in an amount of 10 to 300 parts by mass, to 100 parts by mass of the organic pigment.
(15) A method of producing organic pigment fine particles, having the steps of:

mixing an organic pigment solution with a second solvent, an organic pigment solution prepared by dissolving an organic pigment and a polymer compound in a first solvent, the second solvent of being served as a poor solvent for the organic pigment and being compatible with the first solvent; to precipitate nanometer-sized fine particles having the organic pigment and the polymer compound in the mixed liquid,

wherein a compound insoluble in the second solvent is used as the polymer compound, and the organic pigment fine particles are provided with a capability of self-dispersing in a third solvent different from any of the first solvent and the second solvent.
(16) A pigment-dispersion composition prepared by self-dispersing the organic pigment fine particles as described in any one of the above items (1) to (14) in the third solvent.
(17) The pigment-dispersion composition as described in the above item (16), further having a pigment dispersant.
(18) A photocurable composition, having the pigment-dispersion composition as described in the above item (16) or (17), a photopolymerizable compound, and a photopolymerization initiator.
(19) The photocurable composition as described in the above item (18), further having an alkali-soluble resin.
(20) The photocurable composition as described in the above item (18) or (19), which is used for a color filter.
(21) A color filter, having a colored pattern, formed on a substrate, by using the photocurable composition as described in any one of the above items (18) to (20).
(22) A method of producing a color filter, having the steps of:

a photosensitive film forming step of forming a photosensitive film by applying the photocurable composition as described in any one of the above items (18) to (20) on a substrate directly or a predetermined layer disposed on the substrate, and

a colored pattern forming step of forming a colored pattern by subjecting the formed photosensitive film to a pattern exposure and a development in this order.
(23) An inkjet ink prepared by incorporating the organic pigment fine particles as described in any one of the above items (1) to (14), into a medium containing a polymerizable monomer and/or a polymerizable oligomer.
(24) The inkjet ink as described in the above item (23), which is used for a color filter.

Other and further features and advantages of the invention will appear more fully from the following description.

### BEST MODE FOR CARRYING OUT INVENTION

Hereinafter, the present invention will be explained in detail.

An organic pigment that can be used in the present invention is not limited in hue thereof, and examples include a perylene, perynone, quinacridone, quinacridonequinone, anthraquinone, anthanthrone, benzimidazolone, condensed disazo, disazo, azo, indanthrone, phthalocyanine, triaryl carbonium, dioxazine, aminoanthraquinone, diketopyrrolopyrrole, thioindigo, isoindoline, isoindolinone, pyranthrone or isoviolanthrone-series pigment, or a mixture thereof.

Among these, a quinacridone-series pigment, a diketopyrrolopyrrole-series pigment, a dioxazine-series pigment, a phthalocyanine-series pigment, and an azo-series pigment are preferable; and a diketopyrrolopyrrole-series pigment, a phthalocyanine-series pigment and a dioxazine-series pigment are more preferable.

Examples of the organic pigment may include:
C. I. Pigment Yellow 11, 24, 31, 53, 83, 93, 99, 108, 109, 110, 138, 139, 147, 150, 151, 154, 155, 167, 180, 185, and 199;
C. I. Pigment Orange 36, 38, 43, and 71;
C. I. Pigment Red 81, 105, 122, 149, 150, 155, 171, 175, 176, 177, 209, 220, 224, 242, 254, 255, 264, and 270;
C. I. Pigment Violet 19, 23, 32, 37, and 39;
C. I. Pigment Blue 1, 2, 15, 15:1, 15:3, 15:6, 16, 22, 60, and 66;
C. I. Pigment Green 7, 36, and 37;
C. I. Pigment Brown 25, and 28; and
C. I. Pigment Black 1, and 7.

The pigment in the present invention is not particularly limited. However, among above, preferable examples of the organic pigment include:
C. I. Pigment Yellow 11, 24, 108, 109, 110, 138, 139, 150, 151, 154, 167, 180, and 185;
C. I. Pigment Orange 36, and 71;
C. I. Pigment Red 122, 150, 171, 175, 177, 209, 224, 242, 254, 255, and 264;
C. I. Pigment Violet 19, 23, and 37;
C. I. Pigment Blue 15:1, 15:3, 15:6, 16, 22, 60, and 66;
C. I. Pigment Green 36; and
C. I. Pigment Black 7.

In the present invention, two or more organic pigments or solid solutions of organic pigment may be used in combination, or alternatively, a pigment may be used in combination with an organic dye.

The polymer compound that is used in the present invention is not particularly limited as long as the polymer compound has a function of imparting self-dispersibility in the third solvent to organic pigment fine particles (from the point of this view, the polymer compound may be referred to as “self-dispersing polymer compound”), and the polymer compound is dissoluble in the first solvent while being insoluble in the second solvent, that is, for which the second solvent serves as a poor solvent. Among the polymer compounds, a polymer compound which is likely to function as a dispersant when the pigment is precipitated by mixing the organic pigment solution with the second solvent, so as to quickly adsorb onto the precipitated pigment fine particles, is preferred. Here, in the present invention, if the solubility of a compound for a solvent is 2.0% by mass or less, the compound is insoluble in the solvent; in other words, the solvent is defined as a poor solvent for the compound.

The mass average molecular weight of the polymer compound is not particularly limited, but is preferably 1000 to 500000, more preferably 2000 to 300000, and particularly preferably 3000 to 200000. The shape of the polymer compound may be linear or branched (for example, graft, star-shape, or the like). When the polymer compound is a copolymer, the copolymer may be any of a random copolymer, an alternating copolymer, a block copolymer and a terminal-modified copolymer. It should be noted that when described simply as a molecular weight in the present invention, the molecular weight means mass average molecular weight, unless otherwise specified, and the mass average molecular weight means a mass average molecular weight calculated in terms of polystyrene that is measured by gel permeation chromatography (carrier: tetrahydrofuran).

The polymer compound is not particularly limited, but examples thereof include a polymer or a copolymer of a vinyl monomer (for example, a homopolymer of alkyl methacrylate, a homopolymer of styrenes, a copolymer of alkyl methacrylate/styrenes, polyvinyl butyral, or the like), an ester-series polymer (for example, polycaprolactone or the like), an ether-series polymer (for example, polytetramethylene oxide or the like), an urethane-series polymer (for example, a polyurethane formed from tetramethylene glycol and hexamethylene diisocyanate, or the like), an amide-series polymer (for example, polyamide 6, polyamide 66, or the like), a silicone-series polymer (for example, polydimethylsiloxane or the like), a carbonate-series polymer (for example, a polycarbonate synthesized from bisphenol A and phosgene, or the like), and the like.

As the polymer compound, among these, a polymer or a copolymer of a vinyl monomer, an ester-series polymer, an ether-series polymer, and modification products or copolymers thereof are particularly preferred. From the viewpoints of regulation of solubility in the solvent, cost, ease in synthesis and the like, the polymer compound is particularly preferably a polymer or a copolymer of a vinyl monomer.

The vinyl monomer is not particularly limited. However, preferable example includes (meth)acrylic acid esters, crotonic acid esters, vinyl esters, maleic acid diesters, fumaric acid diesters, itaconic acid diesters, (meth)acrylamides, styrenes, vinyl ethers, vinyl ketones, olefins, maleimides, (meth)acrylonitrile, and the like.

Examples of the (meth)acrylic esters include methyl (meth)acrylate, ethyl(meth)acrylate, n-propyl(meth)acrylate, isopropyl(meth)acrylate, n-butyl(meth)acrylate, isobutyl(meth)acrylate, t-butyl(meth)acrylate, amyl(meth)acrylate, n-hexyl(meth)acrylate, cyclohexyl(meth)acrylate, t-butylcyclohexyl(meth)acrylate, 2-ethylhexyl(meth)acrylate, t-octyl(meth)acrylate, dodecyl(meth)acrylate, octadecyl(meth)acrylate, acetoxyethyl(meth)acrylate, phenyl(meth)acrylate, 2-hydroxyethyl(meth)acrylate, 2-hydroxypropyl(meth)acrylate, 3-hydroxypropyl(meth)acrylate, 4-hydroxybutyl(meth)acrylate, 2-methoxyethyl(meth)acrylate, 2-ethoxyethyl(meth)acrylate, 2-(2-methoxyethoxy)ethyl(meth)acrylate, 3-phenoxy-2-hydroxypropyl(meth)acrylate, 2-chloroethyl(meth)acrylate, glycidyl(meth)acrylate, 3,4-epoxycyclohexylmethyl(meth)acrylate, vinyl(meth)acrylate, 2-phenylvinyl(meth)acrylate, 1-propenyl(meth)acrylate, allyl(meth)acrylate, 2-allyloxyethyl(meth)acrylate, propargyl(meth)acrylate, benzyl(meth)acrylate, diethylene glycol monomethylether(meth)acrylate, diethylene glycol monoethylether(meth)acrylate, triethylene glycol monomethylether(meth)acrylate, triethylene glycol monoethylether(meth)acrylate, polyethylene glycol monomethylether (meth)acrylate, polyethylene glycol monoethylether (meth)acrylate, β-phenoxyethoxyethyl (meth)acrylate, nonylphenoxypolyethylene glycol(meth)acrylate, dicyclopentenyl(meth)acrylate, dicyclopentenyloxyethyl(meth)acrylate, trifluoroethyl(meth)acrylate, octafluoropentyl(meth)acrylate, perfluorooctylethyl(meth)acrylate, dicyclopentanyl(meth)acrylate, tribromophenyl(meth)acrylate, tribromophenyloxyethyl(meth)acrylate, γ-butylolactone(meth)acrylate, and the like.

Examples of the crotonic esters include butyl crotonate, hexyl crotonate and the like.

Examples of the vinyl esters include vinyl acetate, vinylchloro acetate, vinyl propionate, vinyl butyrate, vinyl methoxyacetate, vinyl benzoate and the like.

Examples of the maleic diesters include dimethyl maleate, diethyl maleate, dibutyl maleate and the like.

Examples of the fumaric diesters include dimethyl fumarate, diethyl fumarate, dibutyl fumarate and the like.

Examples of the itaconic diesters include dimethyl itaconate, diethyl itaconate, dibutyl itaconate and the like.

Examples of the (meth)acrylamides include (meth)acrylamide, N-methyl(meth)acrylamide, N-ethyl(meth)acrylamide, N-propyl(meth)acrylamide, N-isopropyl(meth)acrylamide, N-n-butyl acryl(meth)amide, N-t-butyl(meth)acrylamide, N-cyclohexyl(meth)acrylamide, N-(2-methoxyethyl)(meth)acrylamide, N,N-dimethyl(meth)acrylamide, N,N-diethyl(meth)acrylamide, N-phenyl(meth)acrylamide, N-nitrophenyl acrylic amide, N-ethyl-N-phenyl acrylic amide, N-benzyl(meth)acrylamide, (meth)acryloylmorpholine, diacetone acrylamide, N-methylol acrylamide, N-hydroxyethyl acrylamide, vinyl (meth)acrylamide, N,N-diaryl(meth)acrylamide, N-allyl (meth)acrylamide and the like.

Examples of the styrenes include styrene, methylstyrene, dimethylstyrene, trimethylstyrene, ethylstyrene, isopropylstyrene, butylstyrene, hydroxystyrene, methoxystyrene, butoxystyrene, acetoxystyrene, chlorostyrene, dichlorostyrene, bromostyrene, chloromethylstyrene, hydroxystyrenes protected with a group that can be deprotected with an acidic substance (such as t-Boc), methyl vinylbenzoate, α-methylstyrene, and the like.

Examples of the vinyl ethers include methyl vinyl ether, ethyl vinyl ether, 2-chloroethyl vinyl ether, hydroxyethyl vinyl ether, propylvinyl ether, butyl vinyl ether, hexyl vinyl ether, octyl vinyl ether, methoxyethyl vinyl ether, phenyl vinyl ether, and the like.

Examples of the vinyl ketones include methyl vinyl ketone, ethyl vinyl ketone, propyl vinyl ketone, phenyl vinyl ketone, and the like.

Examples of the olefins include ethylene, propylene, isobutylene, butadiene, isoprene, and the like.

Examples of the maleimides include maleimide, butylmaleimide, cyclohexyl maleimide, phenyl maleimide, and the like.

In addition to the compounds mentioned above, (meth)acrylonitrile, N-vinylpyrrolidone, N-vinylformamide, N-vinylacetamide, vinyl caprolactone, and the like can also be used.

Among these, particularly, the polymer compound is more preferably a polymer or a copolymer of a vinyl monomer having a hydrocarbon group having 4 or more carbon atoms, and particularly preferably a polymer or a copolymer of a monomer having a hydrocarbon group having 6 or more and 24 or less carbon atoms. Examples thereof include n-butyl(meth)acrylate, isobutyl(meth)acrylate, t-butyl(meth)acrylate, amyl(meth)acrylate, n-hexyl(meth)acrylate, cyclohexyl(meth)acrylate, t-butylcyclohexyl(meth)acrylate, 2-ethylhexyl(meth)acrylate, octyl(meth)acrylate, t-octyl(meth)acrylate, iso-bornyl(meth)acrylate, dodecyl(meth)acrylate, octadecyl(meth)acrylate, stearyl(meth)acrylate, oleyl(meth)acrylate, and adamantyl(meth)acrylate.

In addition to the above, preferred examples of the vinyl monomer include a vinyl monomer having an acidic group, a vinyl monomer having a basic group, and the like.

Examples of the vinyl monomer having an acidic group include a vinyl monomer having a carboxyl group and a vinyl monomer having a sulfonic acid group. Examples of the vinyl monomer having a carboxyl group include (meth)acrylic acid, vinylbenzoic acid, maleic acid, maleic acid monoalkylester, fumaric acid, itaconic acid, crotonic acid, cinnamic acid, and acrylic acid dimer. Alternatively, an addition reaction product of a monomer having a hydroxy group such as 2-hydroxyethyl(meth)acrylate, and a cyclic anhydride such as maleic anhydride, phthalic anhydride, and cyclohexanedicarboxylic anhydride, and ω-carboxy-polycaprolactone (meth)acrylate may be utilized. Alternatively, as a precursor of a carboxyl group, an anhydride-containing monomer such as maleic anhydride, itaconic anhydride, and citraconic anhydride may be used. In addition, examples of the vinyl monomer having a sulfonic acid group include 2-acrylamido-2-methylpropane sulfonic acid, and examples of the vinyl monomer having a phosphoric acid group include mono(2-acryloyloxyethyl ester)phosphate, and mono(1-methyl-2-acryloyloxyethyl ester)phosphate.

Examples of vinyl monomers having a basic nitrogen atom include: (meth)acrylate esters, such as N,N-dimethylaminoethyl(meth)acrylate, N,N-dimethylaminopropyl(meth)acrylate, 1-(N,N-dimethylamino)-1,1-dimethylmethyl(meth)acrylate, N,N-dimethylaminohexyl(meth)acrylate, N,N-diethylaminoethyl(meth)acrylate, N,N-diisopropyl-aminoethyl (meth)acrylate, N,N-di-n-butylaminoethyl(meth)acrylate, N,N-di-isobutylaminoethyl (meth)acrylate, morpholinoethyl(meth)acrylate, piperidinoethyl(meth)acrylate, 1-pyrrolidinoethyl (meth)acrylate, N,N-methyl-2-pyrrolidylaminoethyl(meth)acrylate, N,N-methyl-phenylaminoethyl(meth)acrylate, and the like; (meth)acrylamides, such as N-(N′,N′-dimethylaminoethyl) acrylamide, N-(N′,N′-dimethylaminoethyl)methacrylamide, N-(N′,N′-diethyl aminoethyl)acrylamide, N-(N′,N′-diethyl aminoethyl)methacrylamide, N-(N′,N′-dimethylaminopropyl)acrylamide, N-(N′,N′-dimethylaminopropyl)methacrylamide, N-(N′,N′-diethylaminopropyl)acrylamide, N-(N′,N′-diethylaminopropyl)methacrylamide, 2-(N,N-dimethylamino)ethyl(meth)acrylamide, 2-(N,N-diethylamino)ethyl(meth)acrylamide, 3-(N,N-diethylamino)propyl(meth)acrylamide, 3-(N,N-dimethylamino)propyl(meth)acrylamide, 1-(N,N-dimethylamino)-1,1-dimethylmethyl(meth)acrylamide and 6-(N,N-diethylamino)hexyl(meth)acrylamide, morpholino(meth)acrylamide, piperidino(meth)acrylamide, N-methyl-2-pyrrolidyl(meth)acrylamide; styrenes, such as N,N-dimethylamino styrene and N,N-dimethylamino methylstyrene; and the like.

A monomer having a hydrocarbon group with 4 or more carbon atoms containing an urea group, an urethane group, and an oxygen ligand, or a monomer containing an alkoxy silyl group, an epoxy group, an isocyanate group, or a hydroxyl group, can also be used. Specific examples thereof include monomers having the following structure.

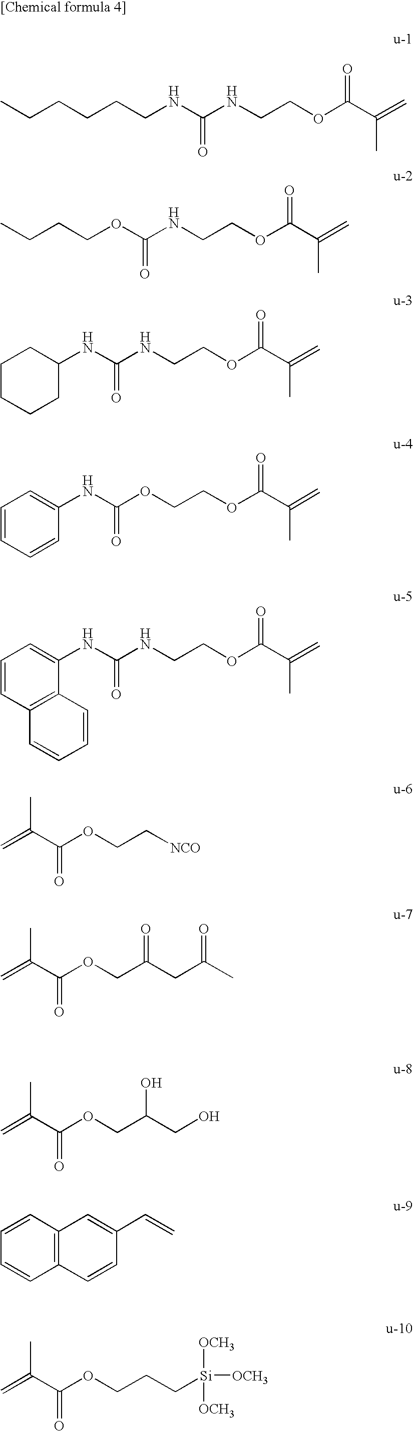

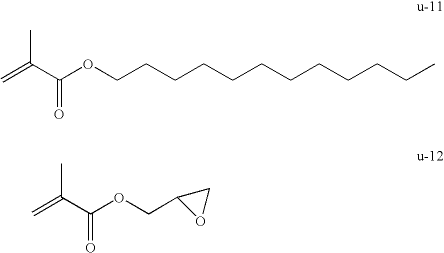

Monomers containing an ionic functional group can be also used. Examples of ionic vinyl monomers (anionic vinyl monomers and cationic vinyl monomers) include anionic vinyl monomers, such as alkali metal salts of the above vinyl monomers having acidic groups and salts of organic amines (for example, tertiary amines, such as triethylamine and dimethylamino ethanol), and cationic vinyl monomers, such as nitrogen-containing vinyl monomers quaternerized with: an alkyl halide (alkyl group: 1 to 18 carbon atoms, halogen atom: chlorine atom, bromine atom or iodine atom); a benzyl halide, such as benzyl chloride or benzyl bromide; an alkylsulfonate (alkyl group: 1 to 18 carbon atoms), such as methanesulfonate; an alkyl arylsulfonate (alkyl group: 1 to 18 carbon atoms), such as benzenesulfonate or toluenesulfonate; a dialkyl sulfate (alkyl group: 1 to 4 carbon atoms); or the like, and dialkyl dallyl ammonium salts and the like.

The polymer compound is one of a monomer having an organic dye structure or a heterocyclic structure. Examples of monomers having an organic dye structure or a heterocyclic structure include: phthalocyanine-, insolubule azo-, azo lake-, anthraquinone-, quinacridone-, dioxazine-, diketopyrolopyrrole-, anthrapyridine-, anthanthrone-, indanthrone-, flavanthrone-, perinone-, perylene- and thioindigo-dye structures; and heterocyclic structure such as thiophene, furan, xanthene, pyrrole, pyrroline, pyrrolidine, dioxolane, pyrazole, pyrazoline, pyrazolidine, imidazole, oxazol, thiazole, oxadiazole, triazole, thiadiazole, pyran, pyridine, piperidine, dioxane, morpholine, pyridazine, pyrimidine, piperazine, triazine, trithiane, isoindoline, isoindolinone, benzimidazolone, benzothiazole, succinic imide, phthalimide, naphthalimide, hydantoin, indole, quinoline, carbazole, acridine, acridone, and anthraquinone.

Among these monomers having an organic dye structure or a heterocyclic structure, more specifically, the polymer compound is preferably a polymer or a copolymer of a monomer represented by formula (1). Here, when the polymer compound is represented by the structure formula of a repeating unit in the present invention, the terminal group may be any atom or any group, and for example, may be simply a hydrogen atom, a residue of a polymerization terminating agent, or the like.

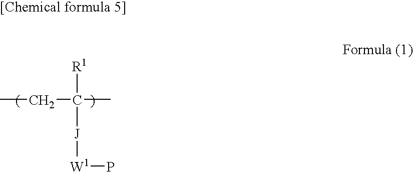

In formula (1), R¹ represents a hydrogen atom or a methyl group; J represents —CO—, —COO—, —CONR⁶—, —OCO—, a phenylene group, or —C₆H₄CO—; R⁶ represents a hydrogen atom, an alkyl group, an aryl group or an aralkyl group; W¹ represents a single bond, a straight-chain, branched, or cyclic alkylene group or aralkylene group; and P represents a heterocyclic group.

In formula (1), J is preferably —CO—, a phenylene group or a benzoyl group. R⁶ represents a hydrogen atom, an alkyl group (e.g., a methyl group, an ethyl group, a n-propyl group, an i-propyl group, a n-butyl group, a n-hexyl group, n-octyl group and a 2-hydroxyethyl group), or an aryl group (e.g., a phenyl group); preferably a hydrogen atom, a methyl group or an ethyl group.

The alkylene group represented by W¹ is preferably an alkylene group having 1 to 10 carbon atoms, and more preferably an alkylene group having 1 to 4 carbon atoms. Examples thereof include a methylene group, an ethylene group, a propylene group, a butylene group, a pentylene group, a hexylene group, an octylene group, a decylene group, and the like, and among them, a methylene group, an ethylene group and a propylene group is preferred. The aralkylene group represented by W¹ is preferably an aralkylene group having 7 to 13 carbon atoms, and examples thereof include a benzylidene group, a cinnamylidene group, and the like. The arylene group represented by W¹ is preferably an arylene group having 6 to 12 carbon atoms, and examples thereof include a phenylene group, a cumenylene group, a mesitylene group, a tolylene group, a xylylene group, and the like. Among them, a phenylene group is particularly preferred.

Furthermore, the linear, branched or cyclic alkylene groups and aralkylene groups represented by W¹ may also have —NR³²—, —NR³²R³³—, —COO—, —OCO—, —O—, —SO₂NH—, —NHSO₂—, —NHCOO—, —OCONH— or a group derived from a heterocyclic ring, included as a linking group. R³² and R³³ each independently represent hydrogen or an alkyl group, and preferable examples thereof include a hydrogen, a methyl group, an ethyl group, a propyl group, and the like.

Among the linking groups represented by W¹, a single bond or an alkylene group is preferred, and a methylene group, an ethylene group and a 2-hydroxypropylene group are more preferred.

In formula (1), P represents a heterocyclic group. Among the heterocyclic groups, a heterocyclic residue constituting an organic pigment is preferred. Examples thereof include heterocyclic residues forming pigments of phthalocyanine-, insoluble azo-, azo lake-, anthraquinone-, quinacridone-, dioxazine-, diketopyrrolopyrrole-, anthrapyrimidine-, anthanthrone-, indanthrone-, flavanthrone-, perinone-, perylene-, thioindigo- and quinophthalone-series residue. Preferable examples of the heterocyclic residue include thiophene, furan, xanthene, pyrrole, pyrroline, pyrrolidine, dioxolane, pyrazole, pyrazoline, pyrazolidine, imidazole, oxazole, thiazole, oxadiazole, triazole, thiadiazole, pyran, pyridine, piperidine, dioxane, morpholine, pyridazine, pyrimidine, piperazine, triazine, trithiane, isoindoline, isoindolinone, benzimidazolone, benzothiazole, succinimide, phthalimide, naphthalimide, hydantoin, indole, quinoline, barbitur, thiobarbitur, carbazole, acridine, acridone, quinacridon, anthraquinone, phthalimide, quinaldine and quinophthalone. Among these, thiophene, furan, xanthene, pyrrole, imidazole, isoindoline, isoindolinone, benzimidazolone, indole, quinoline, carbazole, acridine, acridone, quinacridon, anthraquinone, phthalimide, quinaldine and quinophthalone are preferable; and benzimidazolone, indole, quinoline, barbitur, thiobarbitur, carbazole, acridine, acridone, anthraquinone and phthalimide are particularly preferable. These heterocyclic residues can be appropriately selected in view of the structure or the electronic properties of the pigment used.

The repeating unit represented by formula (1) is preferably a repeating unit represented by formula (2) or (3):

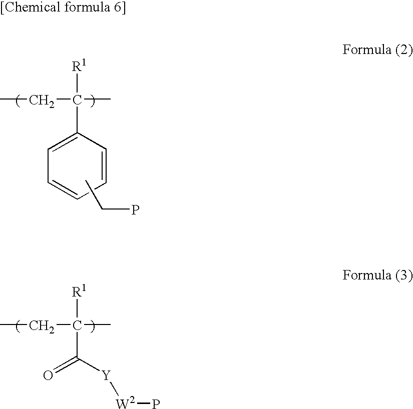

R¹ represents a hydrogen atom or a methyl group; and Y represents —NH—, —O—, or —S—. W² represents a single bond or a divalent linking group; preferably a single bond, or a straight-chain, branched or cyclic alkylene group or aralkylene group. P represents a heterocyclic group. In formulae (2) and (3), a preferred range of W² is the same as that of W¹ in formula (1). In formulae (2) and (3), P is identical with P in formula (1).

Specific preferred examples of the structures represented by formulas (1), (2) and (3) will be listed in the following. However, the present invention is not limited thereto.

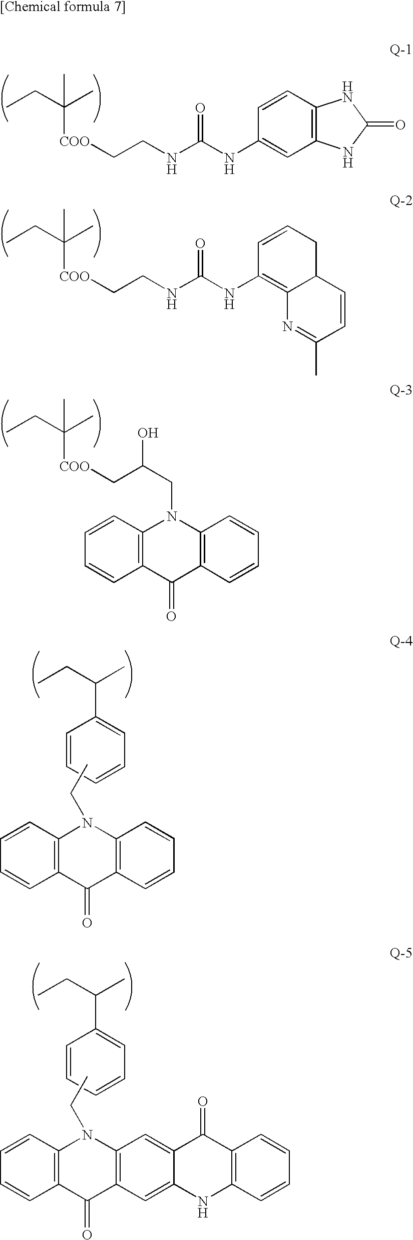

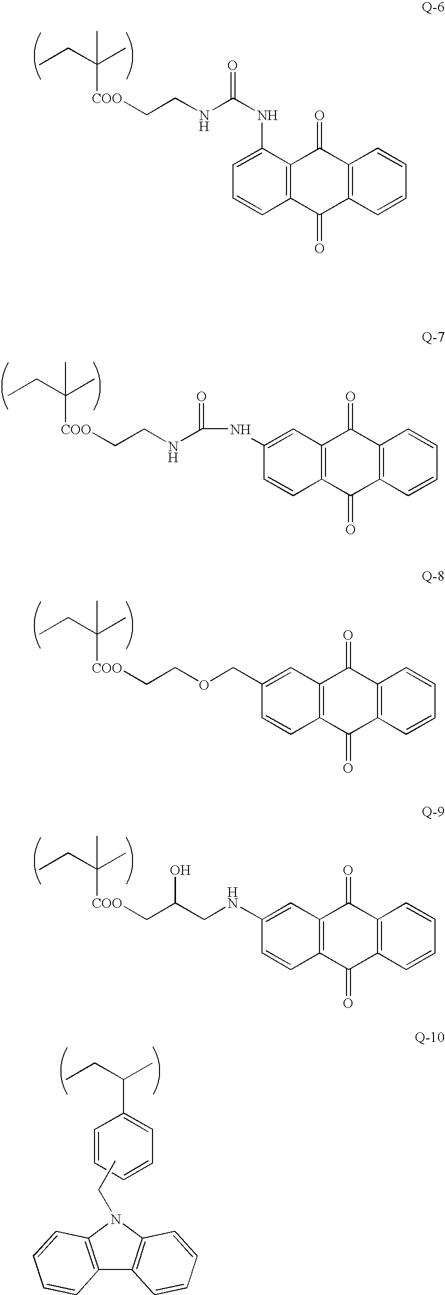

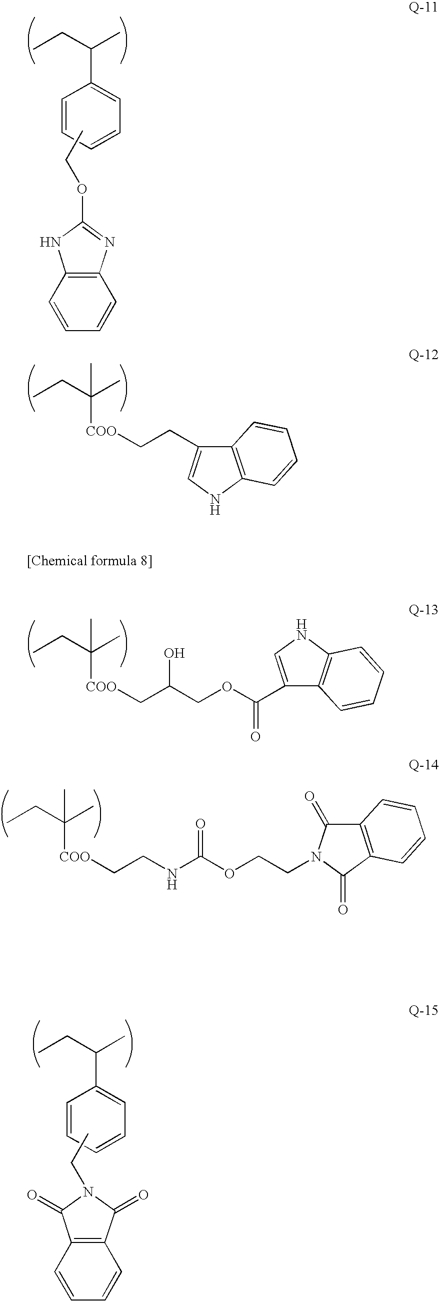

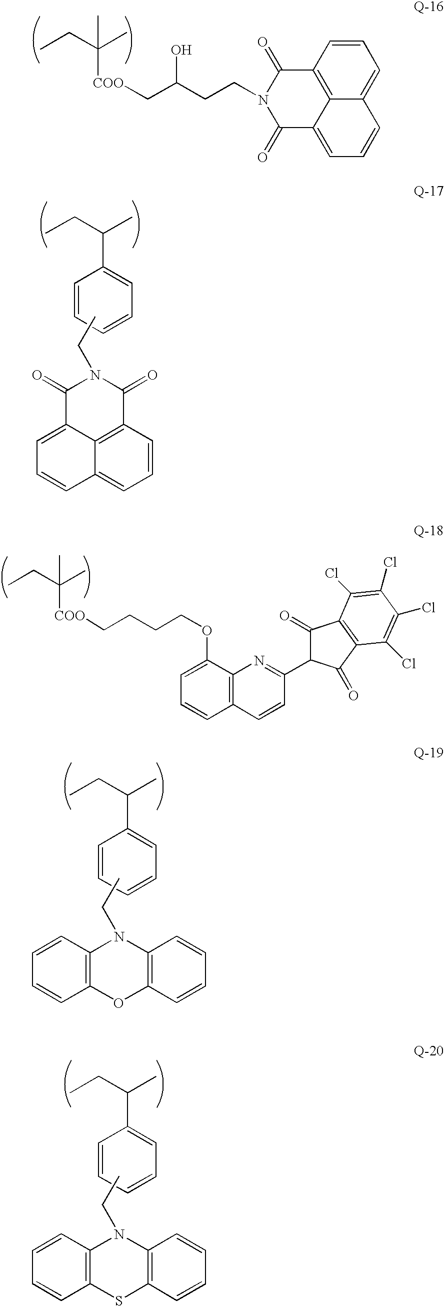

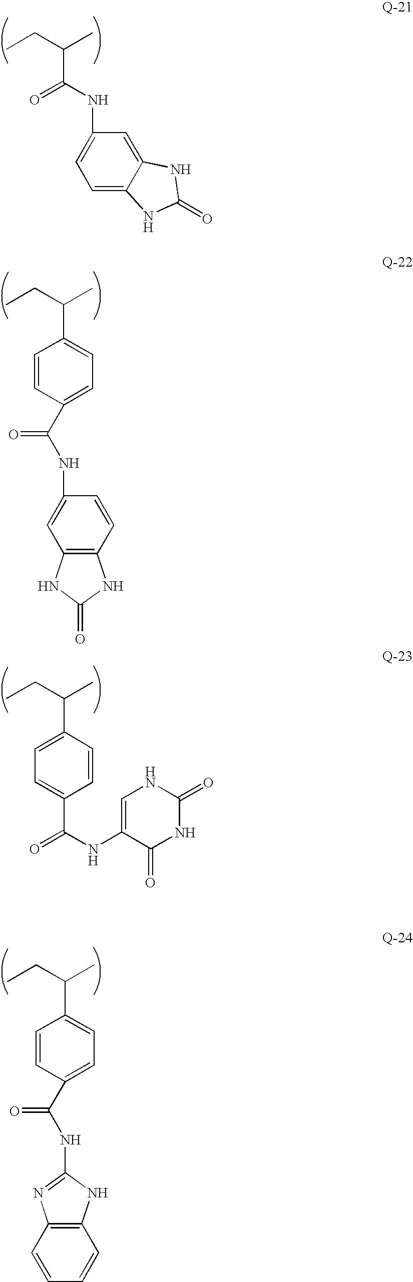

In addition to those exemplified above, it is also preferable that P in the repeating unit represented by formula (1), (2) or (3) is represented by the following formula (4) or a tautomeric structure thereof.

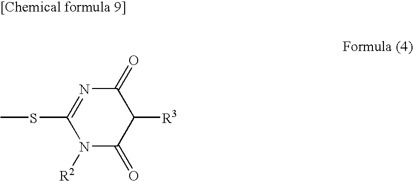

R² represents a hydrogen atom, a substituted or unsubstituted alkyl group, or a substituted or unsubstituted aryl group; and R³ represents a hydrogen atom, an alkyl group, an aryl group, a halogen atom, or an azo group.

Here, tautomerism will be explained. Tautomerism is reversible interconversion between isomers, and is a phenomenon in which hydrogen atoms undergo mutual transposition mainly by proton migration. Furthermore, tautomers refer to structural isomers capable of interconversion, which can undergo mutual conversion at a fast rate, and can reach an equilibrium state where all isomers can co-exist. As a generally shown example, tautomerism occurs as a result of a transposition reaction of hydrogen atoms, that is, protons, which is accompanied by conversion between a single bond and a double bond. The rate or equilibrium ratio of isomerization varies also with a temperature or a pH, and whether the system is in the liquid phase or solid phase, and in the case of a solution, with the type of solvent. In many cases, the isomerization is still called tautomerism even if the time takes from several hours to several days to reach equilibrium.

In the present invention, a chemical structure (moiety) representing the tautomerism in the polymer compound is referred to as a tautomer structure (moiety), and the chemical structures (tautomer structure) obtained by a tautomerization reaction in the repeating unit represented by formula (4) include the following formulas (a) to (h).

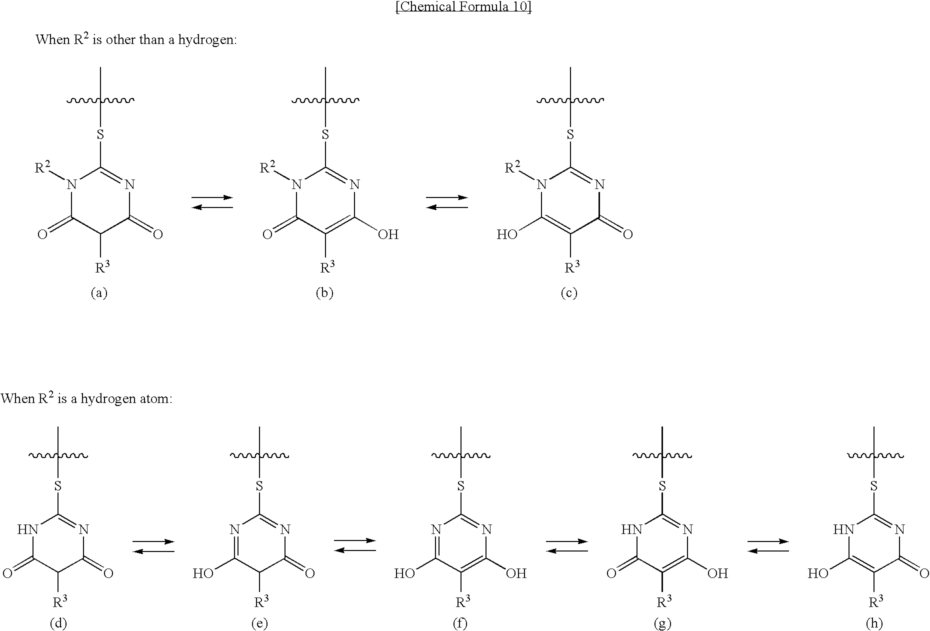

Among those, R² is preferably a hydrogen atom, a methyl group, an ethyl group, a 2-ethylhexyl group, or a phenyl group.

It is preferable that a substituent represented by R³ has, among those, an azo structure represented by the following formula (7).

### [Chemical Formula 11]

—N═N—R²³ Formula (7)

R²³ represents a substituted or unsubstituted, aromatic ring or heteroatom-containing (for example, an oxygen atom, a sulfur atom, a nitrogen atom or the like) heterocyclic ring. Among them, a 5-membered or 6-membered monocyclic ring or bicyclic condensed ring is preferred as the aromatic and heterocyclic structure. Even among them, a benzene ring, a pyridine ring, a pyrimidine ring, an imidazole ring, an isoxazole ring, an oxazole ring, a thiazole ring, a pyrazole ring, a triazole ring, a tetrazole ring, a benzimidazole ring, a benzothiazole ring, a benzoxazole ring, a benzisoxazole ring, and a benzothiazole-thiadiazole ring are preferred.

There will be shown below specific preferred examples of repeating units having a group represented by formula (4) as a heterocyclic group P, but the present invention is not limited thereto. Furthermore, the structures mentioned as these specific examples are only examples among those conceived tautomeric structures, and other tautomeric structures can also be adopted.

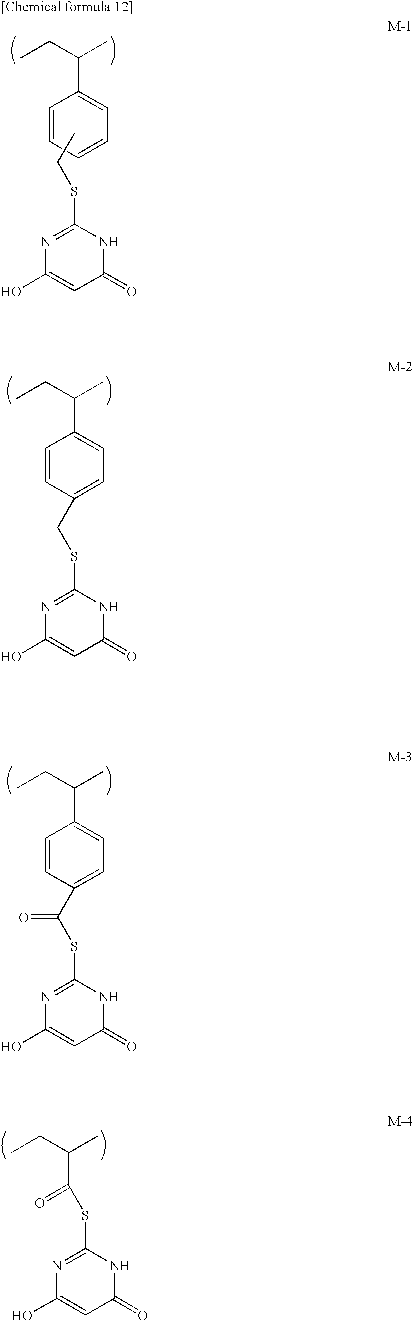

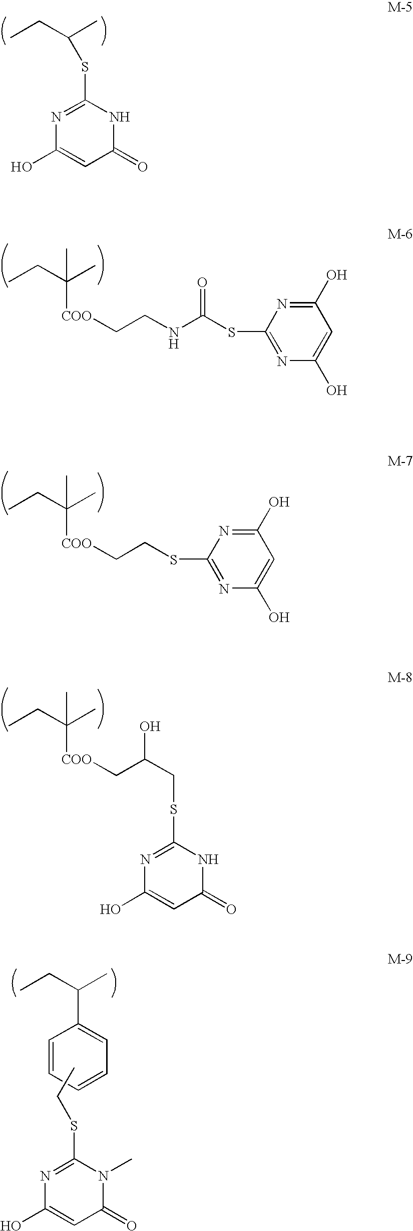

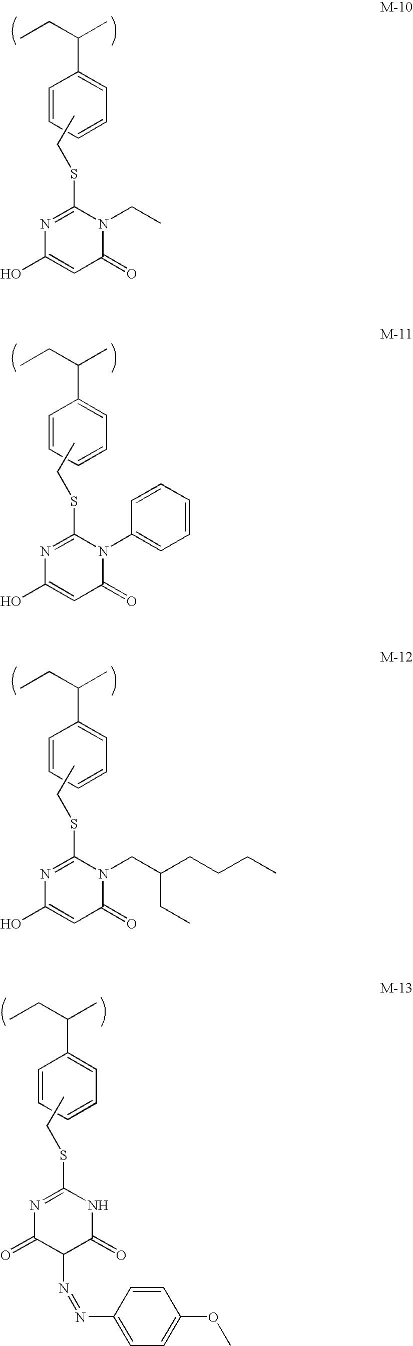

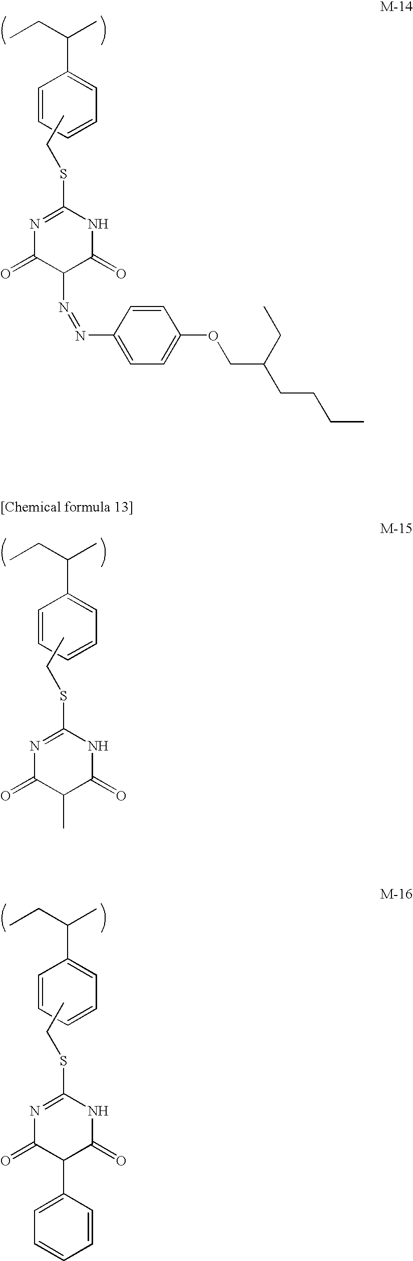

The polymer compound is preferably a graft copolymer that contains a repeating unit obtained by copolymerizing polymerizable oligomers having an ethylenically unsaturated double bond at its terminal. Such a polymerizable oligomer having an ethylenically unsaturated double bond at its terminal is a compound having a given molecular weight and is therefore called a macromonomer. The specific polymerizable oligomer preferably contains a polymer chain moiety and a polymerizable functional group moiety having an ethylenically unsaturated double bond at a terminal of the polymer chain. From the viewpoint of obtaining the desired graft copolymer, the group having an ethylenically unsaturated double bond is preferably present at only one of the terminals of the polymer chain. The group having an ethylenically unsaturated double bond is preferably a (meth)acryloyl group or a vinyl group, and more preferably a (meth)acryloyl group.

The polystyrene-equivalent number-average molecular mass (Mn) of the macromonomer is preferably in the range of 1,000 to 20,000, particularly preferably in the range of 2,000 to 10,000.

The polymer chain moiety is preferably a homopolymer or a copolymer formed from at least one monomer selected from the group consisting of alkyl (meth)acrylates, styrene and derivatives thereof, acrylonitrile, vinyl acetate, and butadiene, or is a polyethylene oxide, a polypropylene oxide, and a polycaprolactone.

The polymerizable oligomer is preferably an oligomer represented by the following formula (5).

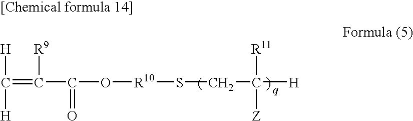

R⁹ and R¹¹ each independently denote a hydrogen atom or a methyl group. R¹⁰ denotes an alkylene group having 1 to 12 carbon atoms, and preferably an alkylene group having 2 to 4 carbon atoms. The alkylene group may have a substituent (e.g. a hydroxy group), and may be bonded via an ester bond, an ether bond, an amide bond, etc. Z denotes a phenyl group, a phenyl group having an alkyl group having 1 to 4 carbon atoms, or —COOR¹² (R¹² denotes an alkyl group having 1 to 6 carbon atoms, a phenyl group, or an arylalkyl group having 7 to 10 carbon atoms), and q is 20 to 200. Z is preferably a phenyl group or —COOR¹² (R¹² denotes an alkyl group having 1 to 12 carbon atoms).

Preferred examples of the polymerizable oligomer (macromonomer) include poly(methyl (meth)acrylate), poly(n-butyl (meth)acrylate), poly(i-butyl (meth)acrylate), and a polymer having a (meth)acryloyl group bonded to one terminal of a polystyrene molecule. Such polymerizable oligomers that are commercially available include a single terminal methacryloylated polystyrene oligomer (Mn=6,000, trade name: AS-6, Toagosei Co., Ltd.), a single terminal methacryloylated polymethyl methacrylate oligomer (Mn=6,000, trade name: AA-6, Toagosei Co., Ltd.), a single terminal methacryloylated poly-n-butyl methacrylate oligomer (Mn=6,000, trade name: AB-6, Toagosei Co., Ltd.).

The polymerizable oligomer is not only a polymerizable oligomer represented by formula (5) above, but is preferably a polymerizable oligomer represented by formula (6) below.

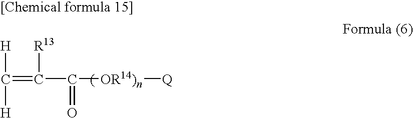

In formula (6), R¹³ denotes a hydrogen atom or a methyl group, and R¹⁴ denotes an alkylene group having 1 to 8 carbon atoms. Q denotes —OR¹⁵ or —OCOR¹⁶. R¹⁵ and R¹⁶ denote a hydrogen atom, an alkyl group, or an aryl group. n denotes 2 to 200.

In formula (6), R¹³ denotes a hydrogen atom or a methyl group. R¹⁴ denotes an alkylene group having 1 to 8 carbon atoms; among them, an alkylene group having 1 to 6 carbon atoms is preferable, and an alkylene group having 2 to 3 carbon atoms is more preferable. Q denotes —OR¹⁵ or —OCOR¹⁶. R¹⁵ is a hydrogen atom, an alkyl group having 1 to 18 carbon atoms, a phenyl group, or a phenyl group substituted with an alkyl group having 1 to 18 carbon atoms. R¹⁶ is an alkyl group having 1 to 18 carbon atoms. Furthermore, n denotes 2 to 200, preferably 5 to 100, and more preferably 10 to 100.

Examples of the polymerizable oligomer represented by formula (6) above include polyethylene glycol mono(meth)acrylate, polypropylene glycol mono(meth)acrylate, polyethylene glycol polypropylene glycol mono(meth)acrylate, and polytetramethylene glycol monomethacrylate, and they may be commercial products or may be synthesized as appropriate.

The polymerizable monomer represented by formula (6) above is commercially available as described above, and examples of the commercial products include methoxy polyethylene glycol methacrylate (trade names: NK ESTER M-40G, M-90G, and M-230G, all manufactured by Shin-Nakamura Chemical Co., Ltd.; trade names: BLEMMER PME-100, PME-200, PME-400, PME-1000, PME-2000, and PME-4000, all manufactured by NOF Corporation), polyethylene glycol monomethacrylate (trade names: BLEMMER PE-90, PE-200, and PE-350, manufactured by NOF Corporation), polypropylene glycol monomethacrylate (trade names: BLEMMER PP-500, PP-800, and PP-1000, manufactured by NOF Corporation), polyethylene glycol polypropylene glycol monomethacrylate (trade name: BLEMMER70PEP-350B, manufactured by NOF Corporation), polyethylene glycol polytetramethylene glycol monomethacrylate (trade name: BLEMMER 55PET-800, manufactured by NOF Corporation), and polypropylene glycol polytetramethylene glycol monomethacrylate (trade name: BLEMMER NHK-5050, manufactured by NOF Corporation).

In addition to the polymerizable oligomers of the formulas (5) and (6), a polycaprolactone monomer is also preferable, and commercially available products include a polycaprolactone monomethacrylate (trade names: PLACCEL FM2D, FM3, FM5, FA1DDM, FA2D, manufactured by Daicel Chemical Industries, Ltd.), and the like.

In the production of the polymer or copolymer of a vinyl monomer, for example, a method according to a radical polymerization method can be applied. Polymerization conditions during manufacturing the polymer or the copolymer of the vinyl monomer with the radical polymerization method, such as a temperature, pressure, type of a radical initiator and amount thereof, type of solvent, and the like are easily determined by a person skilled in the art, and the polymerization conditions can be determined experimentally.

The polymer or copolymer of a vinyl monomer may be a polymer compound having a functional group at its terminal. The functional group is preferably a functional group having an excellent adsorption capability to a precipitated pigment.

A polymer compound having a functional group at its terminal can be synthesized by, for example, a method of performing radical polymerization using a chain transfer agent containing a functional group, a method of performing polymerization (for example, radical polymerization, cationic polymerization, anionic polymerization or the like) using a polymerization initiator containing a functional group, or the like.

Examples of the chain transfer agent capable of introducing a functional group at a polymer compound terminal include mercapto compounds (such as, for example, thioglycolic acid, thiomalic acid, thiosalicylic acid, 2-mercaptopropionic acid, 3-mercaptopropionic acid, 3-mercaptobutyric acid, N-(2-mercaptopropyonyl)glycine, 2-mercaptonicotinic acid, 3-[N-(2-mercaptoethyl)carbamoyl]propionic acid, 3-[N-(2-mercaptoethyl)amino]propionic acid, N-(3-mercaptopropionyl)alanine, 2-mercaptoethanesulfonic acid, 3-mercaptopropanesulfonic acid, 4-mercaptobutanesulfonic acid, 2-mercaptoethanol, 3-mercapto-1,2-propanediol, 1-mercapto-2-propanol, 3-mercapto-2-butanol, mercaptophenol, 2-mercaptoethylamine, 2-mercaptoimidazole, 2-mercapto-3-pyridinol, benzenethiol, toluenethiol, mercaptoacetophenone, naphthalenthiol, and naphthalenemethanethiol), disulfide compounds which are the oxidized compounds of the foregoing mercapto compounds, and halogenated compounds (such as, for example, 2-iodoethanesulfonic acid, and 3-iodopropanesulfonic acid).

Examples of the polymerization initiator capable of introducing a functional group at a polymer compound terminal include 2,2′-azobis (2-cyanopropanol), 2,2′-azobis (2-cyanopentanol), 4,4′-azobis (4-cyanovaleric acid), 4,4′-azobis(4-cyanovaleric acid chloride), 2,2′-azobis[2-(5-methyl-2imidazoline-2-yl)propane], 2,2′-azobis [2-(2-imidazoline-2-yl)propane], 2,2′-azobis[2-(3,4,5,6-tetrahydropyrimidine-2-yl) propane], 2,2′-azobis {2-[1-(2-hydroxyethyl)-2-imidazoline-2-yl]propane}, 2,2′-azobis [2-methyl-N-(2-hydroxyethyl)-propionamide], and the like, and derivatives thereof.

The amount of use of the self-dispersing polymer compound is not particularly limited, but as an amount incorporated into the organic pigment solution upon the precipitation of organic pigment fine particles, the amount of use is preferably in the range of 10 to 300 parts by mass, more preferably in the range of 10 to 120 parts by mass, and particularly preferably in the range of 20 to 100 parts by mass, to 100 parts by mass of the pigment. Within the mentioned range, the particle size of the organic pigment fine particles can be effectively controlled to a nanometer size, and the precipitated organic pigment fine particles can be taken out efficiently in the form of flock. Furthermore, self-dispersibility in the third solvent can be imparted to the organic pigment fine particles. The polymer compound may be used singly, or may be used in combination of two or more thereof

In the present invention, the term “self-dispersibility” means that when fine particles present in a given dispersion (dispersion liquid) are placed in a dispersion medium (third dispersion medium) that is different from the dispersion medium (continuous phase) constituting the given dispersion by substantially removing the dispersion medium constituting the given dispersion, the fine particles spontaneously exhibit well dispersibility in the different dispersion medium (third dispersion medium) even without adding any other dispersant or surfactant. At this time, it is preferable to remove 70% by mass or more and 100% by mass or less of the total medium and to add the replacing third dispersion medium, and it is preferable that the sediment constitutes 0 to 10% by mass of the total amount of the fine particles when the dispersion is left to stand for 24 hours after redispersion. Specific methods of removal and concentration of the solvents (first solvent and second solvent) used in the production of the fine particles will be described later.

The amount of the polymer compound contained in the organic pigment fine particles is not particularly limited, but it is practical that the polymer compound is incorporated and contained in an amount of about 10 to 100 parts by mass, relative to 100 parts by mass of the pigment in the organic pigment fine particles, when, for example, the fine particles are taken out in the form of flock or when redispersed in the third solvent. The total amount of the self-dispersing polymer compound in the redispersed dispersion is not particularly limited, but the total amount, including the amount of the polymer compound in the organic pigment fine particles, is preferably 10 to 200 parts by mass, and more preferably 10 to 100 parts by mass, relative to 100 parts by mass of the pigment in the dispersion. On the other hand, the content of the organic pigment is not particularly limited, but it is practical that the content is 20 to 90% by mass in the organic pigment fine particles.

Examples of the polymer compound that can be used in the present invention is shown below, but the present invention is not intended to be limited thereto.
(1) Polymethyl methacrylate
(2) Polypropylene glycol
(3) Poly(ε-caprolactone)
(4) A copolymer of methyl methacrylate, and styrene
(5) A copolymer of benzyl methacrylate, and acrylic acid
(6) A copolymer of methyl methacrylate, and dimethylaminopropyl acrylamide
(7) A copolymer of methyl methacrylate, and a monomer, which provides the above exemplified component Q-17
(8) A copolymer of methyl methacrylate, a monomer, which provides the above exemplified component Q-17, and polymethyl methacrylate having a methacryloyl group at its terminal
(9) A copolymer of a monomer, which provides the above exemplified component M-1, styrene, and methacrylic acid
(10) A copolymer of a monomer, which provides the above exemplified component M-1, polymethyl methacrylate having a methacryloyl group at its terminal, and methacrylic acid
(11) A copolymer of a monomer, which provides the above exemplified component M-1, polymethyl methacrylate having a methacryloyl group at its terminal, and dimethylaminopropyl acrylamide
(12) A copolymer of a monomer, which provides the above exemplified component Q-22, polystyrene having a methacryloyl group at its terminal, and methacrylic acid
(13) A copolymer of a monomer, which provides the above exemplified component Q-10, polybutyl methacrylate having a methacryloyl group at its terminal, and methacrylic acid
(14) A copolymer of a monomer, which provides the above exemplified component M-1, polyethylene glycol polypropylene glycol having a (meth)acryloyl group at its terminal, and methacrylic acid
(15) A copolymer of a monomer, which provides the above exemplified component Q-4, polyethylene glycol having a (meth)acryloyl group at its terminal, and methacrylic acid
(16) A copolymer of a monomer, which provides the above exemplified component Q-1, polypropylene glycol having a (meth)acryloyl group at its terminal, and methacrylic acid
(17) A copolymer of a monomer, which provides the above exemplified component M-1, polycaprolactone having a methacryloyl group at its terminal, and methacrylic acid
(18) A copolymer of a monomer, which provides the above exemplified component Q-21, polystyrene having a methacryloyl group at its terminal, methacrylic acid, and dimethylaminopropyl acrylamide
(19) A copolymer of a monomer, which provides the above exemplified component M-1, and polymethyl methacrylate having a methacryloyl group at its terminal
(20) A copolymer of a monomer, which provides the above exemplified component Q-22, styrene, and dimethylaminopropyl acrylamide
(21) A copolymer of a monomer, which provides the above exemplified component M-1, N,N-dimetyl-4-vinylbenzamide, and methacrylic acid
(22) A copolymer of a monomer, which provides the above exemplified component Q-23, 4-t-butyl styrene, and methacrylic acid
(23) A copolymer of a monomer, which provides the above exemplified component M-3, methacrylic acid, and polymethyl methacrylate having a methacryloyl group at its terminal
(24) A copolymer of a monomer, which provides the above exemplified component Q-24, methacrylic acid, and polycaprolactone having a methacryloyl group at its terminal
(25) A copolymer of a monomer, which provides the above exemplified component M-2, polymethyl methacrylate having a methacryloyl group at its terminal, and polyethylene glycol polypropylene glycol having a (meth)acryloyl group at its terminal
(26) A copolymer of a monomer, which provides the above exemplified component M-7, methacrylic acid, polymethyl methacrylate having a methacryloyl group at its terminal, and polyethylene glycol mono(meth)acrylate
(27) A copolymer of a monomer, which provides the above exemplified component Q-9, 4-vinylpyridine, and polymethyl methacrylate having a methacryloyl group at its terminal
(28) A copolymer of a monomer, which provides the above exemplified component M-10, polybutyl methacrylate having a methacryloyl group at its terminal, and N-vinylimidazole
(29) A copolymer of a monomer, which provides the above exemplified component M-1, methacrylic acid, poly(n-butyl methacrylate) having a methacryloyl group at its terminal, polymethyl methacrylate having a methacryloyl group at its terminal
(30) A copolymer of a monomer, which provides the above exemplified component Q-4, acrylic acid, and polymethyl methacrylate having a methacryloyl group at its terminal
(31) A copolymer of a monomer, which provides the above exemplified component M-13, styrene, and methacrylic acid
(32) A copolymer of a monomer, which provides the above exemplified compound M-1, methacrylic acid, polymethyl methacrylate having a methacryloyl group at its terminal, and dodecyl methacrylate
(33) A copolymer of a monomer, which provides the above exemplified component Q-1, methacrylic acid, polystyrene having a methacryloyl group at its terminal, and stearyl methacrylate
(34) A copolymer of methacrylic acid, polymethyl methacrylate having a methacryloyl group at its terminal, and iso-bornyl methacrylate
(35) A copolymer of cyclohexyl methacrylate, and 4-vinylpyridine
(36) A copolymer of a monomer, which provides the above exemplified component Q-1, and butyl methacrylate
(37) A copolymer of a monomer, which provides the above exemplified component M-1, styrene, methacrylic acid, and methyl methacrylate
(38) A copolymer of a monomer, which provides the above exemplified component M-2, styrene, and butyl methacrylate
(39) A copolymer of a monomer, which provides the above exemplified component Q-21, t-butyl methacrylate, and methacrylic acid
(40) A copolymer of a monomer, which provides the above exemplified component Q-10, styrene, and butyl acrylamide
(41) A copolymer of methyl methacrylate, and methacrylic acid

Furthermore, commercially available polymer compounds may also be used in addition to the above compounds. Examples of commercially available block polymers include “Disperbyk-2000 and 2001” (trade names, manufactured by BYK Chemie), “EFKA 4330, 4340” (trade names, manufactured by EFKA), and the like.

Examples of commercially available graft polymers include “SOLSPERSE 24000, 28000, 32000, 38500, 39000, and 55000” (trade names, manufactured by Lubrizol Corporation) and “Disperbyk-161, 171 and 174” (trade names, manufactured by BYK Chemie).

Examples of commercial terminal modified polymers include “SOLSPERSE 3000, 17000, and 27000” (trade names, manufactured by Lubrizol Corporation).

The polymer compounds mentioned above may be coexist with an organic compound having a basic group or an acidic group in the organic pigment solution, but it is preferable not to use a nitrogen-containing polymer compound and a polymer compound having an acidic group in combination. When the two kinds of compounds are used in combination to be present together, the nitrogen atom of the nitrogen-containing polymer compound and the acidic group of the polymer compound having an acidic group interact with each other, and therefore the organic pigment fine particles may easily aggregate, causing a decrease in contrast or the like when the organic pigment fine particles are used in color filters. Furthermore, if the polymer compound includes a nitrogen-containing polymer compound, it is preferable not to incorporate a compound having a basic nitrogen atom into the pigment solution. When these compounds are allowed to be present together, coloration may occur due to baking when the organic pigment fine particles are used in color filters.

The first solvent (good solvent) is not particularly limited as long as it can dissolve the organic pigment and polymer pigment, and is compatible, or uniformly mixed, with the second solvent (poor solvent) to be used. With respect to the solubility of the organic pigment in the first solvent, the solubility of the organic pigment is preferably 0.2 mass % or more, and more preferably 0.5 mass % or more. The solubility of the organic pigment in the first solvent has no particular upper limit, but it is practical that the solubility is 50 mass % or less in consideration of an organic pigment to be ordinarily used. The solubility of the self-dispersing polymer compound in the first solvent is preferably 4.0% by mass or more, and more preferably 10.0% by mass or more. This solubility has no particular upper limit, but upon considering those conventionally used polymer compounds, a practical value is 70% by mass or less.

Compatibility or uniform mixing property between the first solvent and the second solvent is such that the solubility of the first solvent in the second solvent is preferably 30 mass % or more, more preferably 50 mass % or more. The solubility of the first solvent in the second solvent has no particular upper limit, but it is practical that the solvents can mix with each other at an arbitrary ratio.

The first solvent is not particularly limited. Preferred examples thereof include organic acids (e.g., formic acid, dichloroacetic acid, and methansulfonic acid), organic bases (e.g., diazabicycloundecene (DBU), tetrabutylammonium hydroxide, and sodium methoxide), aqueous solvents (e.g., water, hydrochloric acid, and aqueous sodium hydroxide solution), alcohol-series solvents (e.g., methanol, ethanol, and n-propanol), ketone-series solvents (e.g., methyl ethyl ketone, methyl isobutyl ketone, and cyclohexanone), ether-series solvents (e.g., tetrahydrofuran, propylene glycol monomethyl ether, and propylene glycol monomethyl ether acetate), sulfoxide-series solvents (e.g., dimethyl sulfoxide, hexamethylene sulfoxide, and sulfolane), ester-series solvents (e.g., ethyl acetate, n-butyl acetate, and ethyl lactate), amide-series solvents (e.g., N,N-dimethylformamide, and 1-methyl-2-pyrrolidone), aromatic hydrocarbon-series solvents (e.g., toluene and xylene), aliphatic hydrocarbon-series solvents (e.g., octane), nitrile-series solvents (e.g., acetonitrile), halogen-series solvents (e.g., carbon tetrachloride, and dichloromethane), ionic liquids (e.g., 1-ethyl-3-methylimidazolium tetrafluoroborate), carbon disulfide solvents, and mixed solvents thereof.

Among these, organic acids, organic bases, aqueous solvents, alcohol-series solvents, ketone-series solvents, ether-series solvents, sulfoxide-series solvents, ester-series solvents, amide-series solvents, or mixed solvents thereof are preferable; and organic acids, organic bases, sulfoxide-series solvents, amide-series solvents, or mixed solvents thereof are particularly preferable.

Examples of the organic acid include a sulfonic acid compound, a carboxylic acid compound, an acid anhydride compound, and the like, but are not intended to be limited to these.

Examples of the sulfonic acid compound include an alkylsulfonic acid, a halogenated alkylsulfonic acid, an aromatic sulfonic acid, and the like, and the alkyl chain or aromatic ring may be unsubstituted or may be substituted with a substituent T. The substituent T as used herein may be any substituent as long as it can be substituted on a sulfonic acid compound.

Examples of the substituent T include: aliphatic groups, aryl groups, heterocyclic groups, acyl groups, nitro groups, amino groups, acyloxy groups, acylamino groups, aliphatic oxy groups, aryloxy groups, heterocyclic oxy groups, aliphatic oxycarbonyl groups, aryloxycarbonyl groups, heterocyclic oxycarbonyl groups, carbamoyl groups, aliphatic sulfonyl groups, arylsulfonyl groups, heterocyclic sulfonyl groups, aliphatic sulfonyloxy groups, arylsulfonyloxy groups, heterocyclic sulfonyloxy groups, sulfamoyl groups, aliphatic sulfonamide groups, arylsulfonamide groups, heterocyclic sulfonamide groups, amino groups, aliphatic amino groups, arylamino groups, heterocyclic amino groups, aliphatic oxycarbonylamino groups, aryloxycarbonylamino groups, heterocyclic oxycarbonylamino groups, aliphatic sulfinyl groups, arylsulfinyl groups, aliphatic thio groups, arylthio groups, hydroxy groups, cyano groups, sulfo groups, carboxyl groups, aliphatic oxyamino groups, aryloxyamino groups, carbamoylamino groups, sulfamoylamino groups, halogen atoms, sulfamoylcarbamoyl groups, carbamoylsulfamoyl groups, dialiphatic oxyphosphinyl groups, and diaryloxyphosphinyl groups.

Specific examples of the sulfonic acid compound used in the present invention include methanesulfonic acid, ethanesulfonic acid, propanesulfonic acid, butanesulfonic acid, trifluoromethanesulfonic acid, pentafluoroethanesulfonic acid, heptafluoropropanesulfonic acid, nonafluorobutanesulfonic acid, benzenesulfonic acid, toluenesulfonic acid, xylenesulfonic acid, dodecylbenzensulfonic acid, naphthalenesulfonic acid, chlorobenzenesulfonic acid, aminiobenzenesulfonic acid, 1,5-naphthalenedisulfonic acid tetrahydrate, and the like.

Examples of the carboxylic acid compound include an alkylcarboxylic acid, a halogenated alkylcarboxylic acid, an aromatic carboxylic acid, and the like, and the alkyl chain or the aromatic ring may be unsubstituted or may be substituted with the substituent T. Specific examples of the carboxylic acid compound include formic acid, acetic acid, propionic acid, butyric acid, trifluoroacetic acid, trichloroacetic acid, tribromoacetic acid, difluoroacetic acid, dichloroacetic acid, dibromoacetic acid, fluoroacetic acid, chloroacetic acid, bromoacetic acid, chlorodifluoroacetic acid, cyanoacetic acid, phenoxyacetic acid, diphenylacetic acid, thioacetic acid, mercaptoacetic acid, mercaptopropionic acid, 2-chloropropionic acid, 2,2-dichloropropionic acid, 3-chloropropionic acid, 2-bromopropionic acid, 3-bromopropionic acid, 2,3-dibromopropionic acid, 2-chlorobutyric acid, 3-chlorobutyric acid, 4-chlorobutyric acid, isobutyric acid, 2-bromoisobutyric acid, cyclohexanecarboxylic acid, nitroacetic acid, phosphonoacetic acid, pyruvic acid, oxalic acid, propargylic acid trimethylammonium acetate, benzoic acid, tetrafluorobenzoic acid, pentafluorobenzoic acid, 2-chlorobenzoic acid, 2-fluorobenzoic acid, benzoyl formate, benzoyl benzoate, 2-dimethylaminobenzoic acid, 2,6-dihydroxybenzoic acid, picolinic acid, citric acid, cystein, sulfanilic acid, squaric acid and the like.

In the present invention, in addition to the carboxylic acid and sulfonic acid, an acid anhydride can be used as a constituent of the acid, and specific examples include acid anhydrides such as acetic anhydride, propionic anhydride, trifluoromethanesulfonic anhydride and trichloroacetic anhydride. Furthermore, examples of organic acids other than these include phosphoric acid isopropyl ester, phosphoric acid methyl ester, phenylphosphonic acid, ethylenediaminetetraphosphonic acid, 1-hydroxyethane-1,1-diphosphonic acid, and methylenediphosphonic acid.

Among them, preferred as the organic acid are an alkylsulfonic acid, an alkylcarboxylic acid, a halogenated alkylcarboxylic acid and an aromatic sulfonic acid, and methanesulfonic acid, trifluoromethanesulfonic acid, ethanesulfonic acid, trifluoroacetic acid, dichloroacetic acid, chloroacetic acid, formic acid, toluenesulfonic acid and dodecylbenzenesulfonic acid are more preferred.

Examples of the organic base include primary amines, secondary amines, tertiary amines, quaternary amines, anilines, piperidines, piperazines, amidines, formamidines, pyridines, guanidines, morpholines, nitrogen-containing heterocyclic rings, metal alkoxides and the like, but are not limited to these. Among these, tertiary amines, quaternary amines, morpholines, nitrogen-containing heterocyclic rings, metal alkoxides and the like are preferred.

Specific examples include aniline, 2-chloroaniline, 3-fluoroaniline, 2,4-difluoroaniline, 2-nitroaniline, N,N-diethylaniline, 2,6-diethylaniline, 2,4-dimethoxyaniline, p-phenylenediamine, pyridine, 2-aminopyridine, pyrimidine, pyridazine, pyrazine, 2,2-dipyridyl, pyrrolidine, piperidine, imidazole, pyrazole, thiazole, benzothiazole, oxazole, diazabicycloundecene, diazabicyclononene, diazabicyclooctane, 1-cyanoguanidine, N,N′-diphenylguanidine, cyclohexylamine, butylamine, cyclopropylamine, t-butylamine, benzylamine, diisopropylamine, trimethylamine, triethylamine, tributylamine, tetrahydroquinoline, phenyltrimethylammonium hydroxide, benzyltrimethylammonium hydroxide, tetramethylammonium hydroxide, tetrabutylammonium hydroxide, morpholine, thiomorpholine, N-methylmorpholine, hexamethylphosphoramide, 1-methyl-4-piperidone, N-(2-aminoethyl)piperazine, ethylenediamine, diethylenetriamine, bis-(3-aminopropyl) ether, sodium methoxide, sodium ethoxide, sodium t-butoxide, potassium methoxide, potassium ethoxide, potassium t-butoxide, and the like.

Among these, aniline, 2,4-difluoroaniline, pyridine, diazabicycloundecene, diazabicyclononene, diazabicyclooctane, triethylamine, tetrahydroquinoline, phenyltrimethylammonium hydroxide, benzyltrimethylammonium hydroxide, tetramethylammonium hydroxide, tetrabutylammonium hydroxide, N-methylmorpholine, N-(2-aminoethyl)piperazine, sodium methoxide, sodium ethoxide, sodium t-butoxide, potassium methoxide, potassium ethoxide and potassium t-butoxide are preferred, and 2,4-difluoroaniline, diazabicycloundecene, diazabicyclononene, tetrahydroquinoline, phenyltrimethylammonium hydroxide, tetramethylammonium hydroxide, tetrabutylammonium hydroxide, N-methylmorpholine, sodium methoxide and potassium t-butoxide are more preferred.

More specific examples of the sulfoxide-series solvent include dimethyl sulfoxide, diethyl sulfoxide, hexamethylene sulfoxide, sulfolane and the like.

Examples of the amide-series solvents include N,N-dimethylformamide, 1-methyl-2-pyrrolidone, 2-pyrrolidinone, 1,3-dimethyl-2-imidazolidinone, 2-pyrroridinone, ε-caprolactam, formamide, N-methylformamide, acetamide, N-methylacetamide, N,N-dimethylacetamide, N-methylpropaneamide, and hexamethylphosphoric triamide.

The condition under which the organic pigment solution is prepared is not particularly restricted, and can be selected from a range from a normal pressure condition to a subcritical or supercritical condition. The temperature in the case where the solution is prepared under normal pressure is preferably −10 to 150° C., more preferably −5 to 130° C., and particularly preferably 0 to 100° C.

When the organic pigment is uniformly dissolved in the first solvent, in general, in the case of a pigment having in the molecule thereof a group dissociative under alkaline conditions, an alkaline solvent is used, and in the case of a pigment having no group dissociative under alkaline conditions but having in the molecule thereof many nitrogen atoms, to which protons easily adhere, an acidic solvent is preferably used. For example, quinacridone-, diketopyrrolopyrrole-, and condensed disazo-compound pigments can be dissolved in alkaline conditions, while phthalocyanine-compound pigments can be dissolved in acidic conditions.

As a base used when the pigment is dissolved in an alkaline condition, an inorganic base such as lithium hydroxide, sodium hydroxide, potassium hydroxide, calcium hydroxide or barium hydroxide can also be used in addition to the organic bases mentioned above. The amount of the base to be used is not particularly limited. However, in the case of the inorganic base, the amount thereof is preferably from 1.0 to 30 mole equivalents, more preferably from 1.0 to 25 mole equivalents, and further preferably from 1.0 to 20 mole equivalents, to the organic pigment. In the case of the organic base, the amount thereof is preferably from 1.0 to 100 mole equivalents, more preferably from 5.0 to 100 mole equivalents, and further preferably from 20 to 100 mole equivalents, to the organic pigment.

As an acid used when the pigment is dissolved in an acidic condition, an inorganic acid such as sulfuric acid, hydrochloric acid or phosphoric acid can also be used in addition to the organic acids mentioned above. The amount of the acid to be used is not particularly limited, but in many cases, the acid is used in a larger or more excessive amount than the base. The amount of the acid to be used is preferably from 3 to 500 mole equivalents, more preferably from 10 to 500 mole equivalents, and further preferably from 30 to 200 mole equivalents, to the organic pigment.

In the case where an inorganic base or an inorganic acid is mixed with the organic solvent and the mixture is used as a good solvent (first solvent) for the organic pigment, a solvent having high solubility for the alkali or the acid such as water or a lower alcohol can be added in a slight amount to the organic solvent in order that the alkali or the acid may be completely dissolved. The amount of water or the lower alcohol is preferably 50 mass % or less, or more preferably 30 mass % or less with respect to the total amount of the organic pigment solution. Specific examples thereof that can be used include water, methanol, ethanol, n-propanol, isopropanol, and butyl alcohol.

The viscosity of the organic pigment solution is preferably in the range of from 0.5 to 100.0 mPa·s, and more preferably from 1.0 to 50.0 mPa·s.

The organic pigment solution is not particularly limited as long as an organic pigment and a polymer compound are dissolved in a first solvent, and the solution may also contain other component.

The other component is not particularly limited, but suitable examples include an organic compound having an acidic group, an organic compound having basicity, and the like. These components have an effect such that when the pigment is precipitated by mixing the organic pigment solution and the second solvent, the components rapidly adsorb onto the precipitated pigment and treating the pigment surface acidically or basically. The solubility of the other component in the second solvent is not particularly limited, but a compound for which the second solvent serves as a poor solvent is preferred.

Examples of the acidic group of the organic compound having an acidic group that can be used in the present invention include a carboxylic acid group, a sulfonic acid group, a sulfinic acid group, a sulfenic acid group, a phosphonic acid group, a hydroxyl group, a sulfide group and the like, but are not limited to these. The organic compound having an acidic group may also contain in its molecule a single kind of functional group, or two or more kinds identical or different functional groups. These organic compounds having an acidic group may be used singly, or may be used in combination of two or more thereof Among these, compounds having a carboxylic acid group, a sulfonic acid group or a phosphoric acid group are preferred.

Examples of the organic compound having a carboxylic acid group include behenic acid, 13-docosenoic acid, oleic acid, linolic acid, stearic acid, isostearic acid, 2-hexyldecanoic acid, palmitic acid, myristic acid, lauric acid, decanoic acid, octanoic acid, 3,5,5-trimethylhexanoic acid, 1,12-dodecanedicarboxylic acid, sebacic acid, 1-adamantanecarboxylic acid, 1-naphthoic acid, 2-naphthoic acid, pyromellitic acid, p-benzoylaminobenzoic acid, terephthalic acid, isophthalic acid, phthalic acid, benzoic acid, trimellitic acid, 1-hydroxy-2-naphthoic acid, β-oxynaphthoic acid, p-octyloxybenzoic acid, triphenylacetic acid, mandelic acid, perfluorooctanoic acid, p-nitrobenzoic acid, o-benzoylbenzoic acid, 4-sulfamoylbenzoic acid, o-benzoylaminobenzoic acid, 2,6-pyridinedicarboxylic acid, tetrahydrofuranetetracarboxylic acid, 2-quinolinecarboxylic acid, 4,4-biphenyldicarboxylic acid, 4-hydroxybiphenyl-3-carboxylic acid, 2-naphthylacetic acid, 2,6-naphthalenedicarboxylic acid, 6-hydroxy-2-naphthoic acid, 1,4,5,8-naphthalenetetracarboxylic acid, 1,8-naphthalic acid, 3,4,9,10-perylenetetracarboxylic acid, indole-3-butyric acid, 3,7-dicarboxylic acid diphenyl oxide tetrachlorophthalic acid, phthalic acid, folic acid, benzylilc acid, naphthenic acid, diphenyl acetate, 2,4-dichlorobenzoic acid, and the like.

Examples of the organic compound having a sulfonic acid group include β-naphthalenesulfonic acid, dodecylbenzenesulfonic acid, cetylsulfuric acid, C-acid, J-acid, γ-acid, diaminostilbenedisulfonic acid, benzenesulfonic acid, benzenedisulfonic acid, naphthalenesulfonic acid, naphthalenedisulfonic acid, chlorobenzenesulfonic acid, 1-naphthylamine-4-sulfonic acid (naphthionic acid), tobias acid, peri acid, J-acid, Koch acid, metanilic acid, toluenesulfonic acid, octanesulfonic acid, and the like.

Examples of the compound having a sulfinic acid group include p-toluenesulfinic acid, benzenesulfinic acid, p-carboxybenzenesulfinic acid, octylsulfinic acid, ethylsulfinic acid, 4-chloro-3-nitrobenzenesulfinic acid, 4-acetamidebenzenesulfinic acid, thiophene-2-sulfinic acid, methylsulfinic acid, isobutylsulfinic acid, hexadecylsulfinic acid, hydroxylmethanesulfinic acid, and the like.

Examples of the sulfenic acid compound include benzenesulfenic acid, p-toluenesulfenic acid and the like.

Examples of the phosphonic acid compound include stearylphosphonic acid, laurylphosphonic acid and the like.

In the present invention, the amount of addition of the organic compound having an acidic group is preferably in the range of 0.01 to 30% by mass, more preferably in the range of 0.05 to 20% by mass, and particularly preferably in the range of 0.05 to 15% by mass, to the pigment.

Examples of the organic compound having a basic group include an alkylamine, an arylamine, an aralkylamine, a pyrazole derivative, an imidazole derivative, a triazole derivative, a tetrazole derivative, an oxazole derivative, a thiazole derivative, a pyridine derivative, a pyridazine derivative, a pyrimidine derivative, a pyrazine derivative, a triazine derivative and the like. Preferred examples include an alkylamine, an arylamine, and an imidazole derivative.

The number of carbon atoms of the organic compound having a basic group is preferably 6 or more, more preferably 8 or more, and even more preferably 10 or more.

In regard to the organic compound having a basic group, examples of the alkylamine include butylamine, amylamine, hexylamine, heptylamine, octylamine, 2-heptylhexylamine, nonylamine, decylamine, undecylamine, dodecylamine, tridecylamine, tetradecylamine, pentadecylamine, hexadecylamine, octadecylamine, isobutylamine, t-butylamine, 1-methylbutylamine, 1-ethylbutylamine, t-amylamine, 3-aminoheptane, t-octylamine, 1,4-diaminobutane, 1,6-hexadiamine, 1,8-diaminooctane, 1,10-diaminodecane, 1,12-diaminododecane, dibutylamine, dihexylamine, dioctylamine, bis(2-ethylhexyl)amine, didecylamine, N-methyloctadecylamine, triethylamine, tripropylamine, N,N-dimethylbutylamine, N-methyldibutylamine, tributylamine, tripentylamine, N,N-dimethylhexylamine, N,N-dimethyloctylamine, N-methyldioctylamine, trioctylamine, triisooctylamine, N,N-dimethyldodecylamine, tridodecylamine, N-methyl-N-octadecyl-1-octadecylamine, N,N-dibutylethylenediamine, N,N,N′,N′-tetramethylethylenediamine, N,N,N′,N′-tetramethyl-1,6-hexanediamine, N-methylcyclohexylamine, N,N,N′,N′,N″-pentamethyldiethylenetriamine, cyclohexylamine, cycloheptylamine, cyclohexylamine, cyclododecylamine, 1-adamantaneamine and the like. Preferred examples include octylamine, 2-heptylhexylamine, nonylamine, decylamine, undecylamine, dodecylamine, tridecylamine, tetradecylamine, octadecylamine, t-octylamine, 1,8-diaminooctane, 1,10-diaminodecane, 1,12-diaminododecane, dioctylamine, bis(2-ethylhexyl)amine, didecylamine, N-methyloctadecylamine, N,N-dimethyloctylamine, N-methyldioctylamine, trioctylamine, triisooctylamine, N,N-dimethyldodecylamine, tridodecylamine, N-methyl-N-octadecyl-1-octadecylamine, N,N-dibutylethylenediamine, N,N,N′,N′-tetramethylethylenediamine, N,N,N′,N′-tetramethyl-1,6-hexanediamine, N-methylcyclohexylamine, N,N,N′,N′,N″-pentamethyldiethylenetriamine, cyclododecylamine, 1-adamantaneamine, and the like. More preferred examples include decylamine, undecylamine, dodecylamine, tridecylamine, tetradecylamine, didecylamine, N-methyloctadecylamine, N,N-dimethyldodecylamine, tridodecylamine and the like. Furthermore, an organic polymer compound having a basic group, such as polyallylamine or polyvinylamine, is also suitable.

Examples of the arylamine include N,N-dibutylaniline, 4-butylaniline, 4-pentylamine, 4-hexylamine, 4-heptylaniline, 4-octylaniline, 4-decylaniline, 4-dodecylaniline, 4-tetradecylaniline, 4-hexadecylaniline, 4-butoxyaniline, 4-pentyloxyaniline, 4-hexyloxyaniline and the like, but preferred examples include 4-octylaniline, 4-decylaniline, 4-dodecylaniline, 4-tetradecylaniline, 4-hexadecylaniline, 4-pentyloxyaniline, 4-hexyloxyaniline and the like. More preferred examples include 4-decylaniline, 4-dodecylaniline, 4-tetradecylaniline, 4-hexadecylaniline, 4-pentyloxyaniline, 4-hexyloxyaniline and the like.

Examples of the imidazole derivative include 1-(10-hydroxydecyl)imidazole, 1-butylimidazole, 2-undecylimidazole, 2-heptadecylimidazole and the like.

The organic compound having a basic group is preferably at a proportion in the range of 0.01 to 30% by mass, more preferably in the range of 0.05 to 20% by mass, and particularly preferably in the range of 0.05 to 15% by mass, to the pigment.

It is also preferable to add an organic compound composed of a basic group and a heterocyclic group.

Examples of such an organic compound include 2-aminopyridine, 3-aminopyridine, 1-(2-aminophenyl)pyrrole, 5-aminopyrazole, 3-amino-5-methylpyrazole, 5-amino-1-ethylpyrazole, 3-aminotriazole, 2-aminothiazole, 5-aminoindole, 2-aminobenzothiazole, 5-aminobenzimidazole, N,N-dimethyl-5-aminobenzimidazole, phthalimide, 5-aminobenzimidazolone, N,N-dimethyl-5-aminobenzimidazolone, 5-aminouracil, 6-aminouracil, uracil, thymine, adenine, guanine, melamine, aminopyrazine, 8-aminoquinoline, 3-aminoquinoline, 9-aminoacridine, ASTRA Blue 6GLL (basic phthalocyanine derivative), 2-aminoanthraquinone, 3-aminoanthraquinone, acridone, N-acridone, quinacridone, NILE Red, Methylene Violet Naphthalimide, and the like. Preferred examples include 2-aminobenzothiazole, 5-aminobenzimidazole, N,N-dimethyl-5-aminobenzimidazole, 5-aminobenzimidazolone, N,N-dimethyl-5-aminobenzimidazolone, 5-aminouracil, 6-aminouracil, uracil, thymine, adenine, guanine, melamine, 8-aminoquinoline, 3-aminoquinoline, 9-aminoacridine, ASTRA Blue 6GLL (basic phthalocyanine derivative), 2-aminoanthraquinone, 3-aminoanthraquinone, acridone, N-acridone, quinacridone, NILE Red, and Methylene Violet Naphthalimide. More preferred examples include 9-aminoacridine, ASTRA Blue 6GLL (basic phthalocyanine derivative), 2-aminoanthraquinone, 3-aminoanthraquinone, acridone, N-acridone, 5-aminobenzimidazole, N,N-dimethyl-5-aminobenzimidazole, 5-aminobenzimidazolone, N,N-dimethyl-5-aminobenzimidazolone, 5-aminouracil, 6-aminouracil, NILE Red, and Methylene Violet Naphthalimide.

The amount of addition of the organic compound composed of a basic group and a heterocyclic group is preferably in the range of 0.01 to 30% by mass, more preferably in the range of 0.05 to 20% by mass, and particularly preferably in the range of 0.05 to 15% by mass, to the pigment.

In addition to the compounds mentioned above, pigment derivatives described in JP-A-2007-9096, JP-A-7-331182 and the like may be mentioned. A pigment derivative as used herein refers to a pigment derivative type compound that is derived from an organic pigment as a parent substance and is produced by chemically modifying the parent structure, or a pigment derivative type compound obtained by a pigmentization reaction of a chemically modified pigment precursor. Commercially available products include, for example, “EFKA6745 (phthalocyanine derivative)” manufactured by EFKA Chemicals GmbH, “Solsperse 5000 (phthalocyanine derivative)” manufactured by Lubrizol Corp., and the like (all trade names). When a pigment derivative is used, the amount of use is preferably in the range of 0.5 to 30% by mass, more preferably in the range of 3 to 20% by mass, and particularly preferably in the range of 5 to 15% by mass, to the pigment.

For the second solvent (poor solvent), there is no particular limitation. The solubility of the organic pigment in the second solvent is preferably 0.02 mass % or less, more preferably 0.01 mass % or less. The solubility of the organic pigment in the second solvent has no particular lower limit, but it is practical that the solubility is 0.0001 mass % or more, in consideration of an organic pigment to be ordinarily used. Furthermore, the solubility of the self-dispersing polymer compound in the second solvent is 2.0% by mass or less (insoluble), and preferably 1.0% by mass or less. The solubility of the organic pigment in the second solvent has no particular lower limit, but it is practical that the solubility is 0.001 mass % or more, in consideration of a polymer compound to be ordinarily used.

The second solvent is not particularly limited. Preferred examples thereof include aqueous solvents (e.g., water, hydrochloric acid, and aqueous sodium hydroxide solution), alcohol-series solvents (e.g., methanol, ethanol, and n-propanol), ketone-series solvents (e.g., methyl ethyl ketone, methyl isobutyl ketone, and cyclohexanone), ether-series solvents (e.g., tetrahydrofuran, propylene glycol monomethyl ether, and propylene glycol monomethyl ether acetate), sulfoxide-series solvents (e.g., dimethyl sulfoxide, hexamethylene sulfoxide, and sulfolane), ester-series solvents (e.g., ethyl acetate, n-butyl acetate, and ethyl lactate), amide-series solvents (e.g., N,N-dimethylformamide, and 1-methyl-2-pyrrolidone), aromatic hydrocarbon-series solvents (e.g., toluene and xylene), aliphatic hydrocarbon-series solvents (e.g., octane), nitrile-series solvents (e.g., acetonitrile), halogen-series solvents (e.g., carbon tetrachloride, and dichloromethane), ionic liquids (e.g., 1-ethyl-3-methylimidazolium tetrafluoroborate), carbon disulfide solvents, and mixed solvents thereof.

Among these, aqueous solvents, alcohol-series solvents, ketone-series solvents, sulfoxide-series solvents, ester-series solvents, amide-series solvents, nitrile-series solvents, and mixed solvents thereof are more preferable; and aqueous solvents, alcohol-series solvents, and mixed solvents thereof are particularly preferable.

Examples of the aqueous solvents include water, hydrochloric acid, aqueous sodium hydroxide solution and aqueous potassium hydroxide solution.

Examples of the alcohol-series solvents include methanol, ethanol, isopropyl alcohol, n-propyl alcohol, and 1-methoxy-2-propanol.

The above-described examples of the first solvent and those of the second solvents overlap, but the identical solvent is not selected for both the first solvent and the second solvent. Any solvents may be used in combination of them as long as each organic pigment and polymer compound to be used shows solubility in the first solvent sufficiently higher than that in the second solvent. In regard to the pigment, for example, the difference in solubility between the first solvent and the second solvent is preferably 0.2 mass % or more, and more preferably 0.5 mass % or more. There is no particular upper limit to the difference in solubility between the first solvent and the second solvent. However, if ordinarily used organic pigments are taken into consideration, it is practical that the upper limit is 50 mass % or less. In regard to the polymer compound, for example, the solubility difference between the first solvent and the second solvent is preferably 2.0% by mass or more, and more preferably 5.0% by mass or more. There is no particular upper limit to the difference in solubility between the first solvent and the second solvent, but upon considering a conventionally used polymer compound, it is practical that the upper limit is 70% by mass or less. The condition for the second solvent is not particularly restricted, and can be selected from a range from a normal pressure condition to a subcritical or supercritical condition. The temperature at which the organic particles are formed under normal pressure is preferably −30 to 100° C., more preferably −10 to 60° C., and particularly preferably 0 to 30° C. The viscosity of the organic pigment solutions is preferably in the range of from 0.5 to 100.0 mPa·s, and more preferably from 1.0 to 50.0 mPa·s.

When the organic pigment solution and the second solvent are mixed, mixing may be carried out by adding any of the two liquids. However, it is preferable to perform mixing by jet flowing the organic pigment solution into the second solvent, and at that time, it is preferable that the second solvent is in a stirred state. The stirring rate is preferably 100 to 10,000 rpm, more preferably 150 to 8,000 rpm, and particularly preferably 200 to 6,000 rpm. A pump or the like may be or may not be used for adding. As the adding method, a method of adding a liquid inside the other liquid or a method of adding a liquid outside the other liquid may be used; a method of adding a liquid inside the other liquid is preferable. Further, it is preferred that one of the liquids be successively fed from inside of the other liquid through a feed pipe using a pump. The inner diameter of the feed pipe is preferably in the range of from 0.1 mm to 200 mm, and more preferably from 0.2 mm to 100 mm. The speed fed from the feed pipe into the other liquid is preferably in the range of from 1 to 10,000 ml/min, and more preferably from 5 to 5,000 ml/min.

Upon mixing the organic pigment solution and the second solvent, the particle size of the pigment nanoparticles that are produced by precipitation can be controlled by regulating the Reynolds number. Here, the Reynolds number is a dimensionless number representing the flow state of a fluid and is represented by the following expression.

Re=ρUL/μ expression (1)

wherein Re represents the Reynolds number; ρ represents a density of the organic pigment solution; U represents a relative velocity at which the organic pigment solution comes in contact with the second solvent; L represents an equivalent diameter of a flow path or a supply inlet at a part where the organic pigment solution comes in contact with the second solvent; and μ represents a viscosity coefficient of the organic pigment solution.

The equivalent diameter L refers to the diameter of an equivalent cylindrical tube when a cylindrical tube which is equivalent to the opening diameter or the flow channel of a pipe having an arbitrary cross-section shape is envisaged. The equivalent diameter L is represented by the following expression (2), in which the cross-section of the pipe is designated as A and the wetted perimeter (circumference) of the pipe or the outer perimeter of the flow channel is designated as p.

L=4A/p expression (2)

It is preferable to form particles by injecting the organic pigment solution into the second solvent through a pipe, and when a circular tube is used as the pipe, the equivalent diameter coincides with the diameter of the circular tube. For example, the equivalent diameter can be adjusted by varying the opening diameter of the liquid supply inlet. The value of the equivalent diameter L is not particularly limited, but for example, the equivalent diameter is identical in meaning with a preferred inner diameter of the supply inlet.

The relative velocity U at which the organic pigment solution comes in contact with the second solvent, is defined as the relative velocity in a direction perpendicular to the plane of the part where the two liquids come in contact. That is, for example, in the case of mixing by injecting the organic pigment solution into the second solvent which is stationary, the velocity of injecting from the supply inlet is identical to the relative velocity U. The value of the relative velocity U is not particularly limited, but for example, the value is preferably set at 0.5 to 100 m/s, and more preferably at 1.0 to 50 m/s.

The density ρ of the organic pigment solution is a value that is determined by the type of the selected material, but it is practical that ρ is, for example, 0.8 to 2.0 kg/m³. Furthermore, the coefficient of viscosity μ of the organic pigment solution is also a value that is determined by the material used, the environment temperature or the like, but its preferred range is identical with a preferred velocity of the organic pigment solution.

A smaller value of Reynolds number (Re) is likely to form a laminar flow, and a larger value is likely to form a turbulent flow. For example, the particle size of the pigment nanoparticles may be obtained under control by adjusting the Reynolds number to be 60 or more, and it is preferable to adjusting the Reynolds number to 100 or more, and more preferably to 150 or more. The Reynolds number has no particular upper limit, but well pigment nanoparticles can be obtained under control by adjusting the Reynolds number, for example, to the range of 100,000 or less, which is preferable. Alternatively, the conditions may be adjusted such that the Reynolds number is increased so that the average particle size of the obtainable nanoparticles would be 60 nm or less. In this case, within the range mentioned above, pigment nanoparticles having a smaller particle size can be obtained under control usually by increasing the Reynolds number.

The mixing ratio of the organic pigment solution and the second solvent is preferably in a range of from 1/50 to 2/3, more preferably from 1/40 to 1/2, and particularly preferably from 1/20 to 3/8, in terms of volume ratio. The particle concentration in the liquid when organic fine particles are precipitated is not particularly limited, but the organic particle concentration is preferably in the range of 10 to 40,000 mg, more preferably in the range of 20 to 30,000 mg, and particularly preferably in the range of 50 to 25,000 mg, to 1,000 ml of the solvent. There is no particular limitation to the scale of preparation at the time when the organic fine particles are prepared. However, it is preferred that the preparation scale is such that the amount of the second solvent to be mixed is preferably from 10 to 2,000 L, and more preferably from 50 to 1,000 L.

As to an average particle diameter of organic particles, an average scale of a group can be represented by digitalizing by several measurement methods. There are frequently-used parameters, such as mode diameter indicating the maximum value of distribution, median diameter corresponding to the median value in the integral frequency distribution curve, and various average diameters (e.g., number-averaged diameter, length-averaged diameter, area-averaged diameter, mass-averaged diameter, volume-averaged diameter, or the like), and the like. In the present invention, the average particle diameter means a number-averaged diameter, unless otherwise specified.

The average diameter of the organic fine particles (primary particles) in the present invention is preferably 1 nm to 1 μm, more preferably 1 to 200 nm, still more preferably 2 to 100 nm, and particularly preferably 5 to 80 nm. The particles prepared may be crystalline or amorphous particles, or the mixture thereof.

Further, in the present invention, a ratio (Mv/Mn) of volume-averaged diameter (Mv) to number-averaged diameter (Mn) is used as the indicator of the monodispersity of particles (degree of the uniformity in particle size), unless otherwise particularly specified. In the present invention, the monodispersity, the ratio Mv/Mn, of the organic fine particles (primary particles) is preferably 1.0 to 2.0, more preferably 1.0 to 1.8, and particularly preferably 1.0 to 1.5.

Examples of a method of measuring the particle diameter of the organic particle include a microscopic method, a gravimetric method, a light scattering method, a light shielding method, an electric resistance method, an acoustic method, and a dynamic light scattering method. Of these, the microscopic method and the dynamic light scattering method are particularly preferable. Examples of a microscope to be used in the microscopic method include a scanning electron microscope and a transmission electron microscope. Examples of a particle measuring device in the dynamic light scattering method include Nanotrac UPA-EX 150 manufactured by NIKKISO Co., Ltd., and a dynamic light scattering photometer DLS-7000 series manufactured by OTSUKA ELECTRONICS CO., LTD.

Upon precipitating pigment fine particles and preparing a dispersion liquid, at least one of the pigment solution and the second solvent may contain a compound for which at least the second solvent serves as a good solvent (the solubility of the pigment fine particles in the second solvent being 4.0% by mass or more) (hereinafter, may be referred to as a particle size adjusting agent).

Examples of the polymer particle size adjusting agent include polyvinylpyrrolidone, polyvinyl alcohol, polyvinyl methyl ether, polyethylene glycol, polypropylene glycol, polyacrylamide, a vinyl alcohol-vinyl acetate copolymer, partially formalated polyvinyl alcohol, partially butyralated polyvinyl alcohol, a vinylpyrrolidone-vinyl acetate copolymer, a polyethylene oxide/propylene oxide block copolymer, polyacrylic acid, polyacrylic acid sodium salt, polyvinyl sulfate, poly(4-vinylpyridine) salt, polyallylamine, polyallylamine hydrochloride, polyvinylamine hydrochloride, an allylamine hydrochloride/diallylamine hydrochloride copolymer, a diallylamine-based monomer/SO₂ copolymer, a diallylamine hydrochloride/maleic acid copolymer, polydiallylmethylamine hydrochloride, polydiallyldimethylammonium chloride, a diallyldimethylammonium chloride/acrylamide copolymer, a condensed naphthalenesulfonic acid salt, a cellulose derivative, a starch derivative and the like. Besides, natural polymer compounds can also be used, examples of which include alginic acid salts, gelatin, albumin, casein, gum arabic, tragacanth gum, and ligninsulfonic acid salts. Among them, polyvinylpyrrolidone, polyacrylic acid, polyallylamine, polyallylamine hydrochloride, polyvinylamine hydrochloride, an allylamine hydrochloride/diallylamine hydrochloride copolymer, a diallylamine-based monomer/SO₂ copolymer and the like are preferred. These particle size adjusting agents can be used singly, or in combination of two or more thereof.

The particle size adjusting agent preferably has a mass average molecular weight of 1,000 to 500,000, more preferably 10,000 to 500,000, and particularly preferably 10,000 to 100,000.

Examples of the anionic particle size adjusting agent (anionic surfactant) include N-acyl-N-alkyltaurine salts, fatty acid salts, alkylsulfates, alkylbenzenesulfonates, alkylnaphthalenesulfonates, dialkylsulfosuccinates, alkylphosphates, naphthalenesulfonic acid/formalin condensates, and polyoxyethylenealkylsulfates. Among these, N-acyl-N-alkyltaurine salts are preferable. As the N-acyl-N-alkyltaurine salts, those described in JP-A-3-273067 are preferable. These anionic particle size adjusting agents may be used singly or in combination of two or more thereof.

Examples of the cationic particle size adjusting agent (cationic surfactant) include quaternary ammonium salts, alkoxylated polyamines, aliphatic amine polyglycol ethers, aliphatic amines, diamines and polyamines derived from aliphatic amine and aliphatic alcohol; imidazolines derived from aliphatic acid, and salts of these cationic substances. These cationic particle size adjusting agents may be used singly or in combination of two or more thereof.

The amphoteric particle size adjusting agent is a dispersing agent having, in the molecule thereof, an anionic group moiety which the anionic particle size adjusting agent has in the molecule and a cationic group moiety which the cationic particle size adjusting agent has in the molecule.

Examples of the nonionic particle size adjusting agents (nonionic surfactant) include polyoxyethylenealkyl ethers, polyoxyethylenealkylaryl ethers, polyoxyethylene fatty acid esters, sorbitan fatty acid esters, polyoxyethylenesorbitan fatty acid esters, polyoxyethylenealkylamines, and glycerin fatty acid esters. Among these, polyoxyethylenealkylaryl ethers are preferable. These nonionic particle size adjusting agents may be used singly or in combination of two or more thereof.

The content of the particle size adjusting agent is preferably in the range of 0.1 to 100% by mass, more preferably in the range of 0.1 to 50% by mass, and even more preferably in the range of 0.1 to 20% by mass, to the pigment, so as to further enhance the control of the particle size of the pigment fine particles. The particle size adjusting agent may be used singly or may be used in combination of plural agents.

The type of the third solvent is not particularly limited, but is preferably an organic solvent. The solvent is preferably, for example, an ester compound solvent, an alcohol compound solvent, an aromatic compound solvent, or an aliphatic compound solvent. An ester compound solvent, an aromatic compound solvent or an aliphatic compound solvent is more preferred, and an ester compound solvent is particularly preferred. The third solvent may be a pure solvent obtained from a solvent described above, or may be a mixed solvent obtained from a plurality of solvents.

In the present invention, the medium of the dispersion composition is not limited to the third solvent described above, but is considered to include a fourth solvent that is described later. Solvents different from any of the good solvent (first solvent) and the poor solvent (second solvent) are collectively referred to as the “third solvent.”

Examples of the ester compound solvents include 2-(1-methoxy)propyl acetate, ethyl acetate, and ethyl lactate. Examples of the alcohol compound solvents include methanol, ethanol, n-butanol and isobutanol. Examples of the aromatic compound solvents include benzene, toluene and xylene. Examples of the aliphatic compound solvents include n-hexane and cyclohexane.

Among these solvents, ethyl lactate, ethyl acetate, ethanol, and 2-(1-methoxy)propyl acetate are preferable. Especially, ethyl lactate and 2-(1-methoxy)propyl acetate are preferable. These may be used singly, or may be used in combination of two or more thereof. The third solvent is not identical to the first solvent or the second solvent.

The time for adding the third solvent is not particularly limited as long as the addition occurs subsequently to the precipitation of pigment nanoparticles, but the third solvent may be added to the mixed liquid from which the pigment nanoparticles have been precipitated, may be added after removing a portion of the solvent fraction of the mixed liquid; or may be added after all of the solvent is eliminated (concentrated).

That is, the third solvent is used as a solvent for substitution, and the solvent fraction formed by the first solvent and the second solvent in the dispersion liquid from which the pigment nanoparticles have been precipitated, can be substituted with the third solvent.

Alternatively, the third solvent may be added after the first solvent and the second solvent are completely removed (concentrated) to take out the organic particles as a pigment particle powder.

Furthermore, in the case of obtaining a pigment-dispersion composition that will be described later, a first solvent fraction removal process (first removal) may be conducted, and then the third solvent is added to substitute the solvent. The solvent fraction may be removed by a removal process for a second solvent fraction (second removal), and the residue may be made into a powder. Subsequently, a pigment dispersant and/or a solvent may be added to produce a desired pigment dispersion composition.

Alternatively, the first solvent and the second solvent can be completely removed (concentrated), the residue is taken out as a pigment particle powder, and then the third solvent and/or a pigment dispersant can be added to produce a desired pigment-dispersion composition.

The addition amount of the third solvent is not particularly limited, but preferably in the range of 100 parts by mass to 300,000 parts by mass, and more preferably from 500 parts by mass to 10,000 parts by mass with respect to 100 parts by mass of the pigment nanoparticle.

The removal process for a solvent fraction from the mixed liquid after the precipitation of the organic pigment fine particles is not particularly limited, but there may be mentioned, for example, a method of filtering through a filter or the like, a method of sedimenting the organic pigment fine particles by centrifugation and then concentrating the fine particles, and the like.

For the apparatus for filtering, for example, an apparatus such as filtration under reduced pressure or filtration under pressure can be used. Preferable examples of the filter to be used include filter paper, nano-sized filter, ultrafilter, and the like.

A centrifugal separator may be any device as long as the device can sediment organic pigment fine particles. Examples of the centrifugal separator include a widely used device, a system having a skimming function (function with which a supernatant layer is sucked during the rotation of the system, to discharge to the outside of the system), and a continuous centrifugal separator for continuously discharging solid matter. As the conditions for centrifugal separation, the centrifugal force (a value representing a ratio of an applied centrifugal acceleration to the gravitational acceleration) is preferably 50 to 10,000, more preferably 100 to 8,000, and particularly preferably 150 to 6,000. The temperature at the time of centrifugal separation is preferably −10 to 80° C., more preferably −5 to 70° C., and particularly preferably 0 to 60° C., though a preferable temperature varies depending on the kind of the solvent of the dispersion liquid.

Furthermore, as the removal process for a solvent fraction, a method of concentrating by subliming the solvent through vacuum freeze-drying, a method of concentrating by drying the solvent under heating or under reduced pressure, a method of combining those methods, and the like can also be used.

The pigment nanoparticles can be used, for example, as dispersed in a vehicle. The vehicle, if paint is taken as an example, means a portion of a medium in which a pigment is dispersed when the paint is in a liquid state. The vehicle is in a liquid state and contains a portion (binder) that bonds to the pigments to solidify a coated film and a component (organic solvent) that dissolves and dilutes the portion. In the present invention, the polymer compound used at the time of nanoparticle formation and/or the pigment dispersant used in redispersion are collectively called binders.

The concentration of pigment nanoparticles in a dispersion composition of the pigment nanoparticles after re-dispersion can be properly determined in accordance with a purpose of their use. However, the concentration of the organic nanoparticles is preferably in the range of from 2 to 30 mass %, more preferably in the range of from 4 to 20 mass %, and especially preferably in the range of from 5 to 15 mass %, to the total amount of the dispersion composition. In the case where the organic nanoparticles are dispersed with such vehicles as described above, amounts of the binder and the dissolution and dilution component can be properly determined depending on, for example, the kind of the organic pigment. However, the amount of the binder is preferably in the range of from 1 to 30 mass %, more preferably in the range of from 3 to 20 mass %, and especially preferably in the range of from 5 to 15 mass %, to the total amount of the dispersion composition. The amount of the dissolution and dilution component is preferably in the range of from 5 to 80 mass %, and more preferably in the range of from 10 to 70 mass %, to the total amount of the dispersion composition.

The content of the organic pigment fine particles (the organic pigment fine particles may have a self-dispersing polymer compound and the like incorporated in the inside. Hereinafter, unless particularly stated otherwise, the same applies) in the pigment-dispersion composition of the present invention is not particularly limited, but the content is preferably 1.0 to 35.0% by mass, and more preferably 5.0 to 25.0% by mass.

When the organic pigment fine particles of the present invention are redispersed in a third solvent, the organic pigment fine particles have a property that the aggregated state of the organic pigment fine particles is spontaneously loosened in the third solvent, and the organic pigment fine particles are dispersed in the medium even though other dispersants or the like are not added. As previously mentioned, organic pigment fine particles having this property are regarded as “capable of self-dispersing” or “having self-dispersibility.” However, in order to further enhance redispersibility in the present invention, a pigment dispersant and the like may be added at the time of redispersion of the organic pigment fine particles.

Examples of a method that can be employed for redispersing such aggregated organic pigment fine particles, include a dispersing method with using a supersonic wave and a method involving applying physical energy. Apparatus for ultrasonic wave irradiation is preferably an apparatus that is capable of applying an ultrasonic wave at 10 kHz or more, and examples thereof include an ultrasonic wave homogenizer, an ultrasonic wave cleaning machine, and the like. The liquid temperature during ultrasonic wave irradiation is preferably kept at 1 to 100° C., more preferably 5 to 60° C., since increase in the liquid temperature leads to thermal aggregation of nanoparticles. The temperature can be controlled, for example, by adjusting the temperature of dispersion liquid, by adjusting the temperature of a temperature-controlling layer for controlling of dispersion liquid temperature, or the like.

A dispersion machine to be used at the time of dispersing the pigment nanoparticles by the application of physical energy is not particularly limited, and examples of the dispersion machine include a kneader, a roll mill, an attritor, a super mill, a dissolver, a homomixer, and a sand mill. Further, a high pressure dispersion method and a dispersion method of using fine particle beads are also exemplified as a preferable method.

The pigment-dispersion composition of the present invention can have a conventionally known dispersant such as a pigment dispersant or a surfactant added, for the purpose of further enhancing the dispersibility of the pigment, to the extent of not impairing the effect of the present invention.

Examples of the pigment dispersant include a polymer dispersant (for example, a linear polymer, a block polymer, a graft polymer, a terminal-modified polymer, or the like), a surfactant (polyoxyethylene alkyl phosphoric acid ester, polyoxyethylene alkylamine, alkanolamine, or the like), a pigment derivative, and the like. The dispersant acts to be adsorbed by the pigment surface, thereby preventing re-aggregation. Therefore, the preferred structure is that of end-modified polymers, graft polymers, and block polymers having an anchor site for the pigment surface. In contrast, the pigment derivatives demonstrate an effect of enhancing the adsorption of the polymer dispersant by modifying the pigment surface.

Specific examples of the the block polymer as the polymer compound include “Disperbyk-2000 and 2001” (trade names, manufactured by BYK Chemie), and “EFKA 4330 and 4340” (trade names, manufactured by EFKA). Examples of the graft polymer include “trade name: SOL-SPERSE 24000, 28000, 32000, 38500, 39000 and 55000”, manufactured by Lubrizol Corp. and “trade name: Disperbyk-161, 171 and 174”, manufactured by BYK Chemie.

Examples of the terminal-modified polymer include “trade name: SOL-SPERSE 3000, 17000 and 27000”, manufactured by Lubrizol Corp.

In the present invention, the pigment derivative (hereinafter, also referred to as “pigment derivative type dispersant”) is defined as a pigment derivative type dispersant which is derived from an organic pigment as a parent substance and is produced by chemically modifying the parent structure, or as a pigment derivative type dispersant obtained by a pigmentization reaction of a chemically modified pigment precursor. In general, the pigment derivative is also referred to as synergistic dispersant.

Although not particularly limited, for example, those pigment derivatives having an acidic group, pigment derivatives having a basic group, pigment derivatives having a functional group such as a phthalimidemethyl group introduced therein, and the like as described in JP-A-2007-9096, JP-A-7-331182 or the like are suitably used.

Commercially available products of the pigment derivative include “EFKA6745 (phthalocyanine derivative), 6750 (azo pigment derivative)” manufactured by EFKA Chemicals, “Solsperse 5000 (phthalocyanine derivative), 22000 (azo pigment derivative)” manufactured by Lubrizol Corp., and the like (all trade names).

Examples of the linear polymer include alkali-soluble resins which will be described later, and it is also preferable to use the linear polymer in combination with the pigment derivative.

The pigment dispersant may be used singly, or may be used in combination of two or more kinds thereof.

The photocurable composition of the present invention includes a dispersion composition of the organic pigment fine particles, a photopolymerizable compound and a photopolymerization initiator (hereinafter, may also be referred to as photopolymerization initiator-series), and preferably, further includes an alkali-soluble resin. Hereinafter, the respective components of the photocurable composition will be explained.

Methods for preparing organic pigment fine particles and dispertion composition thereof are already described in detail. The content of organic pigment fine particles in a photocurable composition is preferably from 3 to 90 mass %, more preferably from 20 to 80 mass %, and still more preferably from 25 to 60 mass %, to the total solids in the photocurable composition (the term “total solids” used in the invention refers to summation of all ingredients but the organic solvent in the photocurable composition). When the content is too high, there sometimes occurs an increase in viscosity of the resultant dispersion liquid and leading to a problem in production suitability. When the content is too low, on the other hand, sufficient coloring power cannot be obtained. For the purpose of toning, the pigment fine particles may be used in combination with pigments in common use. As the pigments, those recited hereinbefore as pigments can be used.

The photopolymerizable compound (herein, also referred to as polymerizable monomer or polymerizable oligomer) is preferably a multifunctional monomer which has two or more ethylenically unsaturated double bonds and which undergoes addition-polymerization by irradiation with light. The photopolymerizable compound may be a compound having at least one addition-polymerizable ethylenically unsaturated group therein and having a boiling point of 100° C. or higher at normal pressure. Examples thereof include: a monofunctional acrylate and a monofunctional methacrylate such as polyethylene glycol mono(meth)acrylate, polypropylene glycol mono(meth)acrylate, and phenoxyethyl(meth)acrylate; polyethylene glycol di(meth)acrylate, polypropylene glycol di(meth)acrylate, trimethylolethane triacrylate, trimethylolpropane tri(meth)acrylate, trimethylolpropane diacrylate, neopentyl glycol di(meth)acrylate, pentaerythritol tetra(meth)acrylate, pentaerythritol tri(meth)acrylate, dipentaerythritol hexa(meth)acrylate, dipentaerythritol penta(meth)acrylate, hexanediol di(meth)acrylate, trimethylolpropane tri(acryloyloxypropyl)ether, tri(acryloyloxyethyl)isocyanurate, tri(acryloyloxyethyl)cyanurate, glycerin tri(meth)acrylate; a polyfunctional acrylate or polyfunctional methacrylate which may be obtained by adding ethylene oxide or propylene oxide to a polyfunctional alcohol such as trimethylolpropane or glycerin and converting the adduct into a (meth)acrylate. Further, another preferred examples include those compounds that are obtained by addition reaction of ethylene oxide or propylene oxide to polyfunctional alcohol, followed by (meth)acrylation, as described in formulae (1) and (2) of JP-A-10-62986.

Examples of the monomer and oligomer further include urethane acrylates as described in JP-B-48-41708 (“JP-B” means examined Japanese patent publication), JP-B-50-6034, and JP-A-51-37193; and polyester acrylates as described in JP-A 48-64183, JP-B-49-43191, and JP-B-52-30490; polyfunctional acrylates or polyfunctional methacrylates such as epoxy acrylates which is a reaction product of an epoxy resin and (meth)acrylic acid.

Among these, trimethylolpropane tri(meth)acrylate, pentaerythritol tetra(meth)acrylate, dipentaerythritol hexa(meth)acrylate, and dipentaerythritol penta(meth)acrylate are preferable.

Further, other than the above, “polymerizable compound B” described in JP-A-11-133600 can be mentioned as a preferable example.

These photopolymerizable compound may be used singly or as a mixture of two or more kinds thereof. The content of the polymerizable compound is generally in a range of from 5 mass % to 50 mass %, preferably from 10 mass % to 40 mass %, based on the total solid content in the photocurable compositon. If this content is too large, control of development properties becomes difficult, raising problems of production suitability. If the content is too small, a curing force at the time of exposure becomes insufficient.

Examples of the photopolymerization initiator or the photopolymerization initiator series (in the present specification, the term “photo-polymerization initiator series” means a polymerization initiating composition that exhibits a function of photo-polymerization initiation with a plurality of compounds combined with each other) include vicinal polyketaldonyl compounds disclosed in U.S. Pat. No. 2,367,660, acyloin ether compounds described in U.S. Pat. No. 2,448,828, aromatic acyloin compounds substituted by an α-hydrocarbon described in U.S. Pat. No. 2,722,512, polynuclear quinone compounds described in U.S. Pat. No. 3,046,127 and U.S. Pat. No. 2,951,758, combinations of triarylimidazole dimer and p-aminoketone described in U.S. Pat. No. 3,549,367, benzothiazole compounds and trihalomethyl-s-triazine compounds described in JP-B-51-48516, trihalomethyl-triazine compounds described in U.S. Pat. No. 4,239,850, and trihalomethyloxadiazole compounds described in U.S. Pat. No. 4,212,976. In particular, trihalomethyl-s-triazine, trihalomethyloxadiazole, and triarylimidazole dimer are preferable.

In addition, “polymerization initiator C” described in JP-A-11-133600, and oximes such as 1-phenyl-1,2-propanedion-2-(o-ethoxycarbonyl)oxime, O-benzoyl-4′-(benzmercapto)benzoyl-hexyl-ketoxime, 2,4,6-trimethylphenylcarbonyl-diphenylphosphonyloxide, and hexafluorophosphoro-trialkylphenyl phosphonium salts can also be mentioned as preferable examples.

These photopolymerization initiators and photopolymerization initiator series each may be used singly. Alternatively, a mixture of two or more selected from these photopolymerizable initiators and photopolymerization initiator series may be used. In particular, it is preferable to use two or more kinds of photopolymerizable initiators and photopolymerization initiator series. When two or more kinds of photopolymerizable initiators and photopolymerization initiator series are used, the display property, particularly evenness of display, can be improved. As to the content of the photo-polymerization initiator or the photo-polymerization initiator series, the content thereof is generally in the range of from 0.5 to 20 mass %, preferably from 1 to 15 mass %, based on the total solid content in the photocurable composition. If the amount of the initiator or the initiator series is too large, exposure sensitivity becomes too high, which causes difficulty in control. If the amount of the initiator or the initiator series is too small, exposure sensitivity may become too low.

The alkali-soluble resin is preferably a photocurable composition, and may be added during preparation of the inkjet ink for color filter, but preferably added during preparation of the organic pigment fine particle dispersion composition or during formation of the organic pigment fine particles. The alkali-soluble resin may be preferably added to both or one of the organic pigment solution and the second solvent for forming organic pigment fine particles by adding the organic pigment solution thereto. It is also preferable to add a alkali-soluble resin solution, which is independently prepared, at the time of the formation of the organic pigment fine particles.

As the alkali-soluble resin, a binder having a acidic group is preferable, and an alkali-soluble polymer having a polar group such as a carboxylic acid group or a carboxylic acid salt group on its side chain is preferable. Examples thereof include a methacrylic acid copolymer, an acrylic acid copolymer, an itaconic acid copolymer, a crotonic acid copolymer, a maleic acid copolymer, and a partially esterified maleic acid copolymer described in, for example, JP-A-59-44615, JP-B-54-34327, JP-B-58-12577, JP-B-54-25957, JP-A-59-53836, and JP-A-59-71048. The examples further include a cellulose derivative having a carboxylic acid group, a carboxylate group or the like on its side chain. In addition to the foregoing, a product obtained by adding a cyclic acid anhydride to a polymer having a hydroxyl group can also be preferably used. In addition, particularly preferable examples of the binder include a copolymer of benzyl (meth)acrylate and (meth)acrylic acid and a multi-component copolymer of benzyl (meth)acrylate, (meth)acrylic acid, and any other monomer described in U.S. Pat. No. 4,139,391.

Each of these alkali-soluble resins may be used singly, or may be used in combination with an ordinary film formable polymer so that they are used in a state of a composition. The alkali-soluble resin is added in an amount of generally 10 to 200 parts by mass, and preferably 25 to 100 parts by mass with respect to 100 parts by mass of the organic pigment fine particles.

Further, for the purpose of improving crosslinking efficiency, a polymerizable group may be included in the side chain of the alkali-soluble resin, and ultraviolet curing resins and thermosetting resins are also useful. Further as the alkali-soluble resin, resins having a water-soluble atomic group at a part of their side chains can be used.

In the photocurable composition, an organic solvent for photocurable composition preparation (fourth solvent) may be further used in addition to the components described above. Examples of the fourth solvent preferably include, but not particularly limited to, alcohol-series solvents, ketone-series solvents, ether-series solvents, sulfoxide-series solvents, ester-series solvents, amide-series solvents, aromatic hydrocarbon-series solvents, aliphatic hydrocarbon-series solvents, nitrile-series solvents, and mixed solvents thereof. Among these, ketone-series solvents, ether-series solvents, ester-series solvents, aromatic hydrocarbon-series solvents, aliphatic hydrocarbon-series solvents, and mixed solvents thereof are more preferable.

Examples of the ketone-series solvents include methyl ethyl ketone, methyl isobutyl ketone, cyclohexanone and 2-heptanone. Examples of the ether-series solvents include propylene glycol monomethyl ether, and propylene glycol monomethyl ether acetate. Examples of the ester-series solvents include 1,3-butylene glycol diacetate, methyl 3-methoxypropionate, methyl 3-ethoxypropionate, ethyl 3-ethoxypropionate, ethyl cellosolve acetate, ethyl lactate, butyl acetate, ethyl carbitol acetate and butyl carbitol acetate. Examples of the aromatic hydrocarbon-series solvents include toluene and xylene. Examples of the aliphatic hydrocarbon-series solvents include cyclohexane and n-hexane.

These solvents may be used singly or in combination of two or more thereof. Further, if necessary, a solvent having a boiling point of from 180° C. to 250° C. may be used. The content of the organic solvent is preferably 10 to 95 mass %, to the total content of the photocurable composition.

It is preferred that the photocurable composition includes a proper surfactant therein. Preferable examples of the surfactant include surfactants disclosed in JP-A-2003-337424 and JP-A-11-133600. The content of the surfactant is preferably 5 mass % or less based on the total amount of the photocurable composition.

It is preferred that the photocurable composition includes a thermal polymerization inhibitor. Examples of the thermal polymerization inhibitor include hydroquinone, hydroquinone monomethyl ether, p-methoxyphenol, di-t-butyl-p-cresol, pyrogallol, t-butylcatechol, benzoquinone, 4,4′-thiobis(3-methyl-6-t-butylphenol), 2,2′-methylenebis(4-methyl-6-t-butylphenol), 2-mercaptobenzimidazole, and phenothiazine. The content of the thermal polymerization inhibitor is preferably 1 mass % or less based on the total amount of the photocurable composition.

If necessary, in addition to the aforementioned coloring agent (pigment), other coloring agents (dyes or pigments) may be added to the photocurable composition. When the coloring agent is a pigment, the pigment is preferably dispersed in the photocurable composition uniformly. Examples of the dye and pigment include the colorants described in paragraph Nos. [0038] to [0040] of JP-A-2005-17716, pigments described in paragraph Nos. [0068] to [0072] of JP-A-2005-361447, and coloring agents described in paragraph Nos. [0080] to [0088] of JP-A-2005-17521. The content of dyes or pigments to be used supplementary is preferably 5 mass % or less based on the total amount of the photocurable composition.

If necessary, the photocurable composition may include an ultraviolet absorber. Examples of the ultraviolet absorber include compounds described in JP-A-5-72724, a salicylate-based ultraviolet absorber, a benzophenone-based ultraviolet absorber, a benzotriazole-based ultraviolet absorber, a cyanoacrylate-based ultraviolet absorber, a nickel-chelate-based ultraviolet absorber, and a hindered-amine-based ultraviolet absorber. The content of the ultraviolet absorber is preferably 5 mass % or less, based on the total amount of the photocurable composition.

In addition to the aforementioned additives, the photocurable composition may further include an “adhesion auxiliary” described in JP-A-11-133600 and other additives.

The photocurable composition can be prepared into an inkjet ink by appropriately adjusting the composition. The inkjet ink may be a conventional inkjet ink for color filter as well as printing or the like, but among them, it is preferable to prepare an inkjet ink for color filter.

It is not particularly limited as long as the inkjet ink of the present invention includes the organic pigment fine particles previously mentioned. The inkjet ink contains the previously mentioned organic pigment fine particles in a medium containing a polymerizable monomer and/or a polymerizable oligomer. Here, as the polymerizable monomer and/or polymerizable oligomer, those described previously for the photocurable composition can be used.

In the photocurable composition, it is preferred to control the temperature of the ink so that a deviation of viscosity of the ink would be within ±5%. The viscosity at the time of injection is preferably from 5 to 25 mPa·s, more preferably from 8 to 22 mPa·s, and especially preferably from 10 to 20 mPa·s (the viscosity used in the present specification is a value at 25° C., unless specifically indicated otherwise). In addition to setting of the above-described injection temperature, the viscosity may be adjusted by controlling the kind of components to be contained in the ink and the amount thereof. The viscosity may be measured using ordinary equipments such as a cone-and-plate-system rotational viscometer and an E type viscometer.

It is preferred that the surface tension of the ink at the time of injection be from 15 to 40 mN/m, from the viewpoint of improvement in smoothness (flatness) of the pixel (surface tension used in the present specification is a value at 23° C. unless specifically indicated otherwise). The surface tension is more preferably from 20 to 35 mN/m, and most preferably from 25 to 30 mN/m. The surface tension may be adjusted by adding surfactants and selecting the kind of solvent to be used. The surface tension may be measured according to a platinum plate method using measuring equipments such as a surface tension-measuring device (CBVP-Z, manufactured by Kyowa Interface Science Co., Ltd.) and a full automatic balancing type electro surface tensiometer ESB-V (manufactured by Kyowa Science).

As a method of spraying the inkjet ink for the color filter, it is possible to employ any of various methods such as a method of continuously spraying an electrified ink and then controlling the ink by electric field, a method of intermittently spraying an ink using a piezoelectric element, and a method of intermittently spraying an ink with utilizing bubbles generated by heating the ink.

As to the inkjet method used for forming each pixel (image element), any of ordinary methods such as a method of thermally curing an ink, a photo-curing method, and a method of previously forming a transparent image-receiving layer on a substrate, followed by stroke of ink droplets.

As an inkjet head (hereinafter sometimes simply referred to as a head), ordinary heads, such as continuous type heads and dot-on-demand type heads can be used. Of these dot-on-demand-type heads, preferred as thermal heads are those of the type having a movable bulb for discharge as described in JP-A-9-323420. As the piezo head, use can be made of heads described in, for example, EP 277,703A and EP 278,590A. It is preferred that the head has a temperature control function so that the temperature of the ink can be managed. Specifically, it is preferred to set an injection temperature so that the viscosity at the time of injection would be within the range of from 5 to 25 mPa·s and to control the temperature of the ink so that the deviation of the viscosity would be within ±5%. It is preferred that the head operates with a drive frequency in the range of from 1 to 500 kHz.

After formation of each pixel, it is possible to set a heat step in which a thermal processing (a so-called bake processing) is performed. In the heat step, a substrate having thereon a layer photo-polymerized by light irradiation is heated in a heating machine such as an electric furnace and a drying oven, or alternatively said substrate is irradiated using an infrared lamp. The temperature and time required for heating depend on a composition of the colored photosensitive composition and the thickness of the formed layer. Generally, it is preferred to heat at a temperature of from about 120° C. to about 250° C. for a time ranging from about 10 minutes to about 120 minutes, from such the viewpoints of attaining sufficient solvent resistance, alkali resistance, and ultraviolet absorbance.

The pattern shape of the thus-formed color filter is not particularly limited. Accordingly, it may be a stripe shape, which is a general black matrix shape, or a lattice shape, or a delta configuration shape.

In the present invention, it is preferred to use a preparation method in which a barrier rib is formed prior to the image element-forming step using an inkjet ink for color filter, and then the ink is supplied to a portion surrounded with the barrier rib. The barrier rib is not particularly limited. However, in the case where a color filter is formed, it is preferred to use a barrier rib having a black matrix function and a light shielding effect (hereinafter, such the barrier rib is simply referred to as “barrier rib”). The barrier rib may be prepared by the same materials and according to the same method as ordinary black matrixes for color filter. Examples of the black matrix include those described in paragraph Nos. [0021] to [0074] of JP-A-2005-3861 and paragraph Nos. [0012] to [0021] of JP-A-2004-240039, and black matrixes for inkjet described in paragraph Nos. [0015] to [0020] of JP-A-2006-17980 and paragraph Nos. [0009] to [0044] of JP-A-2006-10875.

The above-described photocurable composition may be used to form a coating film. The thickness of the coating film formed by using the photocurable composition may be properly determined. However, the thickness is preferably in the range of from 0.5 μm to 5.0 μm, and more preferably from 1.0 μm to 3.0 μm. In the coating film formed by using the photocurable composition, a polymerized coating of the photocurable composition may be formed by polymerizing the monomer or oligomer incorporated in the composition, thereby to prepare a color filter having the thus-formed polymerized coating. (A preparation of the color filter will be described later.) Polymerization of the photopolymerizable compound may be performed by causing the photo-polymerization initiator or photo-polymerization initiator series to act by irradiation of light.

The aforementioned coating film can be formed by coating the photocurable composition by a general coating method, followed by drying. In the present invention, it is preferred that the colored photosensitive resin composition be coated by using a slit nozzle having a slit at a portion through which the coating liquid is discharged. Specifically, slit nozzles and slit coaters described in JP-A-2004-89851, JP-A-2004-17043, JP-A-2003-170098, JP-A-2003-164787, JP-A-2003-10767, JP-A-2002-79163, and JP-A-2001-310147 are preferably used.

As a method of coating the photocurable composition on a substrate, a spin coating is excellent in such the point that a thin film of 1 μm to 3 μm can be uniformly coated with high precision. Therefore, the spin coating can be widely and generally used for preparation of color filters. In recent yeas, however, it is required to further improve production efficiency and production cost in accordance with inclination to large-sized liquid crystal display devices and mass production thereof. Therefore, the slit coating, which is more suited for coating on a wide and large area substrate than the spin coating, has been adopted in production of color filters. Besides, the slit coating is superior to the spin coating from the viewpoint of saving of liquid to be used; and the slit coating can obtain a uniform coating from a lesser coating amount.

The slit coating is a coating method characterized by the steps of using a coating head having a slit (gap) of a width of several ten microns at a tip and having a length corresponding to the coating width of a rectangular substrate, and moving the substrate and/or the coating head at a definite relative speed, while maintaining a clearance (gap) between the substrate and the coating head at a distance of from several ten microns to several hundred microns, and coating on the substrate a coating liquid fed from the slit in a predetermined discharge amount. The slit coating has such advantages as follows: (1) a liquid loss is less than a spin coating; (2) a workload at the time of conducting a wash processing is reduced because no coating liquid would be spattered; (3) no contamination (re-inclusion) owing to the spattered liquid component to a coating film would be caused; (4) a tact time is shortened because no dwell time to start up spinning is necessary; (5) it easily coats a large-sized substrate; and the like. From these advantages, the slit coating is suitable to production of a color filter for a large-sized-screen liquid crystal display device, and the slit coating has been expected as a coating method that is also useful for reduction in a coating amount of the liquid.

The coating operation in the production method above may be carried out, for example, with a common coating apparatus. However, in the present invention, it is preferably performed with a coating apparatus (slit coater) having a slit nozzle, as explained in the previous. Preferable examples of the slit coater are as described above.

The color filter of the present invention is excellent in contrast. The term “contrast” used in the present specification means a ratio of the amount of transmitted light when polarization axes are parallel to the amount of transmitted light when polarization axes are perpendicular, with respect to a color filter placed between two polarizing plates (see, for example, The 7th Color Optics Conference 1990; Color Filter for 512-color 10.4″-size TFT-LCD; Ueki, Koseki, Fukunaga, Yamanaka).

The color filter having a high contrast enables enlarging a discrimination of brightness at the time when the color filter is combined with a liquid crystal. Therefore, the high contrast is a very important performance in enhancing replacement of CRTs by liquid crystal display devices.

In the case where the color filter in the present invention is used as a color filter for a television monitor, the difference (ΔE) between the chromaticity of the red (R) photosensitive resin layer measured under a F10 light source and the target chromaticity for red shown in the following table, the difference (ΔE) between the chromaticity of the green (G) photosensitive resin layer measured under a F10 light source and the target chromaticity for green shown in the following table, the difference (ΔE) between the chromaticity of the blue (B) photosensitive resin layer measured under a F10 light source and the target chromaticity for blue shown in the following table, are each preferably 5 or less, more preferably 3 or less, still more preferably 2 or less.

| | x | y | Y |
|---|---|---|---|
| R | 0.656 | 0.336 | 21.4 |
| G | 0.293 | 0.634 | 52.1 |
| B | 0.146 | 0.088 | 6.90 |

Herein, chromaticity in the present invention is measured by a microscopic spectrophotometer (OSP100 or 200, manufactured by Olympus Optics) and expressed in terms of xyY values of the xyz color system obtained by calculation as a result under an F10-light source at 2-degree viewing angle. In addition, the difference from the target chromaticity is expressed in terms of a color difference of a La*b* color system.

A liquid crystal display device equipped with the color filter of the present invention has high contrast and excellent definition such as black depth, and particularly, the liquid crystal display device is preferably of VA mode. The liquid crystal display device of the present invention can be suitably used also as a large screen liquid crystal display device such as a display for a notebook computer and a television monitor. The color filter of the present invention can be used in CCD devices, and exhibits excellent performance.

According to the present invention, organic pigment fine particles that can improve the properties of color filters used in liquid crystal display devices and the like, and a method of producing the organic pigment fine particles can be provided. In particular, there can be provided organic pigment fine particles which can increase the contrast of color filters, can increase the production quality, production efficiency and environmental suitability, and can realize well display properties in liquid crystal display devices; a method of producing the organic pigment fine particles; a dispersion composition, a photocurable composition and an inkjet ink obtained by the organic pigment fine particles; a color filter formed by them, and a method of producing the color filter.

The organic pigment fine particles of the present invention and a pigment-dispersion composition, a photocurable composition and an inkjet ink containing the organic pigment fine particles, improve the properties of color filters, and particularly, they offer an excellent operating effect of increasing the contrast of color filters, capable of increasing the production quality, production efficiency and environmental suitability, and realizing well display properties in liquid crystal display devices. According to the production method in the present invention, the organic pigment fine particles having excellent properties as described above can be produced with good efficiency and with high purity, and a color filter using these organic pigment fine particles and having a well display quality can be efficiently produced at reduced cost.

### Examples

The present invention will be described in more detail based on examples given below, but the invention is not meant to be limited by these. In the examples “parts” means “mass parts”, and “%” means “mass %”, unless otherwise indicated.

### Synthesis Example 1

### Synthesis of Monomer M-1

45.28 parts of 2-thiobarbituric acid and 13.82 parts of sodium hydroxide are dissolved in 200 parts of dimethyl sulfoxide, and the solution was heated to 25° C. 57.53 parts of chloromethylstyrene was added dropwise thereto, and the mixture was further subjected to heating and stirring at 55° C. for 5 hours. After the heating and stirring, 150 parts of methanol and 150 parts of distilled water were added to this reaction liquid, and the mixture was stirred for one hour. Subsequently, this solution was poured into 2000 parts of distilled water while being stirred, and the resulting precipitates were separated by filtration and washed. Thus, 80.1 parts of a vinyl monomer constituting the repeating unit M-1 (hereinafter, simply referred to as “monomer M-1”) is obtained.

### Synthesis of Polymer P-1

A monomer solution as described below was introduced into a three-necked flask purged with nitrogen, and was stirred with a stirrer (trade name, manufactured by Shinto Scientific Co., Ltd., Three-One Motor). While nitrogen was being flowed into the flask, the content of the flask was heated to raise the temperature to 78° C. and was stirred for 30 minutes. Subsequently, an initiator solution as described below was added to the liquid mentioned above, and the mixture was heated and stirred at 78° C. for 2 hours. After the heating and stirring, an operation of further adding an initiator solution as described below and heating under stirring at 78° C. for 2 hours, was repeated two times in total. After the last stirring for 2 hours, the mixture was continuously heated and stirred at 90° C. for 2 hours. The resulting reaction liquid was poured into 1500 parts of isopropanol while being stirred, and generated precipitates were collected by filtration and heated to dry. Thus, a graft polymer P-1 was obtained.

| | |
|---|---|
| (Monomer solution) | |
| Monomer M-1 | 2.0 parts |
| styrene | 16.0 parts |
| Methacrylic acid | 2.0 parts |
| 1-Methyl-2-pyrrolidone | 46.67 parts |
| (Initiator solution) | |
| Dimethyl 2.2′-azobis(isobutyrate) (trade name: | 0.6 part |
| V-601, manufactured by Wako Pure | |
| Chemical Industries, Ltd.) | |
| 1-Methyl-2-pyrrolidone | 2 parts |

### Synthesis Example 2

### Synthesis of Polymer P-2

A graft polymer P-2 was obtained in the same manner as Synthesis Example 1, except that the styrene used in the Synthesis Example 1 was replaced with a polymethyl methacrylate having a methacryloyl group at its terminal (number average molecular weight 6000, trade name: AA-6, manufactured by Toagosei Co., Ltd.), and the amount of V-601 added to the initiator solution was changed to 0.1 parts.

### Synthesis Examples 3 to 35

Polymers P-3 to P-35 were obtained in the same manner as Synthesis Example 1, except that the component composition of the monomer solution and the component composition of the initiator solution shown in the Synthesis Example 1 were changed as indicated in Table 1.

TABLE 1

| Synthesis | Polymer | Monomer solution | | | | Reaction | Initiator solution | |
|---|---|---|---|---|---|---|---|---|
| example | compound | Monomer 1 | Monomer 2 | Monomer 3 | Monomer 4 | solvent | Initiator | Solvent |
| Synthesis | P-1 | M-1, | St, | MAA, | | NMP, | V-601, | NMP, |
| example 1 | | 2 parts | 16 parts | 2 parts | | 46.67 parts | 0.6 parts | 2 parts |
| Synthesis | P-2 | M-1, | AA-6, | MAA, | | NMP, | V-601, | NMP, |
| example 2 | | 2 parts | 16 parts | 2 parts | | 46.67 parts | 0.1 parts | 2 parts |
| Synthesis | P-3 | M-1, | AA-6, | DMAPAAm, | | NMP, | V-601, | NMP, |
| example 3 | | 2 parts | 16 parts | 2 parts | | 46.67 parts | 0.1 parts | 2 parts |
| Synthesis | P-4 | Q-22, | AS-6, | MAA, | | NMP, | V-601, | NMP, |
| example 4 | | 2 parts | 16 parts | 2 parts | | 46.67 parts | 0.1 parts | 2 parts |
| Synthesis | P-5 | Q-10, | AB-6, | MAA, | | NMP, | V-601, | NMP, |
| example 5 | | 2 parts | 16 parts | 2 parts | | 46.67 parts | 0.1 parts | 2 parts |
| Synthesis | P-6 | M-1, | PEP-350B, | MAA, | | NMP, | V-601, | NMP, |
| example 6 | | 2 parts | 16 parts | 2 parts | | 46.67 parts | 0.3 parts | 2 parts |
| Synthesis | P-7 | Q-4, | PE-350, | MAA, | | NMP, | V-601, | NMP, |
| example 7 | | 2 parts | 16 parts | 2 parts | | 46.67 parts | 0.3 parts | 2 parts |
| Synthesis | P-8 | Q-1, | PP-1000, | MAA, | | NMP, | V-601, | NMP, |
| example 8 | | 2 parts | 16 parts | 2 parts | | 46.67 parts | 0.3 parts | 2 parts |
| Synthesis | P-9 | M-1, | FM5, | MAA, | | NMP, | V-601, | NMP, |
| example 9 | | 2 parts | 16 parts | 2 parts | | 46.67 parts | 0.3 parts | 2 parts |
| Synthesis | P-10 | Q-21, | AS-6, | MAA, 1.5 | DMAPAAm, | NMP, | V-601, | NMP, |
| example 10 | | 2 parts | 16 parts | parts, | 0.5 parts | 46.67 parts | 0.1 parts | 2 parts |
| Synthesis | P-11 | M-1, | AA-6, | | | NMP, | V-601, | NMP, |
| example 11 | | 4 parts | 16 parts | | | 46.67 parts | 0.1 parts | 2 parts |
| Synthesis | P-12 | Q-22, | St, | DMAPAAm, | | NMP, | V-601, | NMP, |
| example 12 | | 2 parts | 16 parts | 2 parts | | 46.67 parts | 0.6 parts | 2 parts |
| Synthesis | P-13 | M-1, | DMVBAm, | MAA, | | NMP, | V-601, | NMP, |
| example 13 | | 2 parts | 16 parts | 2 parts | | 46.67 parts | 0.6 parts | 2 parts |
| Synthesis | P-14 | Q-23, | tBuSt, | MAA, | | NMP, | V-601, | NMP, |
| example 14 | | 2 parts | 16 parts | 2 parts | | 46.67 parts | 0.6 parts | 2 parts |
| Synthesis | P-15 | M-3, | AA-6, | MAA, | | NMP, | V-601, | NMP, |
| example 15 | | 2 parts | 16 parts | 2 parts | | 46.67 parts | 0.1 parts | 2 parts |
| Synthesis | P-16 | Q-24, | FM5, | MAA, | | NMP, | V-601, | NMP, |
| example 16 | | 2 parts | 16 parts | 2 parts | | 46.67 parts | 0.3 parts | 2 parts |
| Synthesis | P-17 | M-2, | AA-6, | PEP-350B, | | NMP, | V-601, | NMP, |
| example 17 | | 2 parts | 10 parts | 8 parts | | 46.67 parts | 0.1 parts | 2 parts |
| Synthesis | P-18 | M-7, | AA-6, | PME-1000, | MAA, | NMP, | V-601, | NMP, |
| example 18 | | 2 parts | 10 parts | 6 parts | 2 parts | 46.67 parts | 0.1 parts | 2 parts |
| Synthesis | P-19 | Q-9, | AA-6, | 4-Vpy, | | NMP, | V-601, | NMP, |
| example 19 | | 2 parts | 16 parts | 2 parts | | 46.67 parts | 0.1 parts | 2 parts |
| Synthesis | P-20 | M-10, | AB-6, | VIm, | | NMP, | V-601, | NMP, |
| example 20 | | 2 parts | 16 parts | 2 parts | | 46.67 parts | 0.1 parts | 2 parts |
| Synthesis | P-21 | M-1, | AB-6, | AA-6, | MAA, | NMP, | V-601, | NMP, |
| example 21 | | 4 parts | 6 parts | 8 parts | 2 parts, | 46.67 parts | 0.1 parts | 2 parts |
| Synthesis | P-22 | Q-4, | AA-6, | AA, | | NMP, | V-601, | NMP, |
| example 22 | | 2 parts | 16 parts | 2 parts | | 46.67 parts | 0.1 parts | 2 parts |
| Synthesis | P-23 | M-13, | St, | MAA, | | NMP, | V-601, | NMP, |
| example 23 | | 2 parts | 16 parts | 2 parts | | 46.67 parts | 0.6 parts | 2 parts |
| Synthesis | P-24 | M-1, | AA-6, | DMA, | MAA, | NMP, | V-601, | NMP, |
| example 24 | | 2 parts | 8 parts | 8 parts | 2 parts | 46.67 parts | 0.1 parts | 2 parts |
| Synthesis | P-25 | Q-1, | AS-6, | StMA, | MAA, | NMP, | V-601, | NMP, |
| example 25 | | 2 parts | 10 parts | 6 parts | 2 parts | 46.67 parts | 0.1 parts | 2 parts |
| Synthesis | P-26 | IbMA, | AA-6, | MAA, | | NMP, | V-601, | NMP, |
| example 26 | | 6 parts | 12 parts | 2 parts | | 46.67 parts | 0.1 parts | 2 parts |
| Synthesis | P-27 | CyMA, | 4-Vpy, | | | NMP, | V-601, | NMP, |
| example 27 | | 2 parts | 5 parts | | | 46.67 parts | 0.1 parts | 2 parts |
| Synthesis | P-28 | Q-1, | BMA, | | | NMP, | V-601, | NMP, |
| example 28 | | 4 parts | 16 parts | | | 46.67 parts | 0.1 parts | 2 parts |
| Synthesis | P-29 | M-1, | St, | MAA, | MMA, | NMP, | V-601, | NMP, |
| example 29 | | 2 parts | 14 parts | 2 parts | 2 parts | 46.67 parts | 0.6 parts | 2 parts |
| Synthesis | P-30 | M-2, | St, | BMA, | | NMP, | V-601, | NMP, |
| example 30 | | 2 parts | 6 parts | 12 parts | | 46.67 parts | 0.6 parts | 2 parts |
| Synthesis | P-31 | Q-21, | tBMA, | MAA, | | NMP, | V-601, | NMP, |
| example 31 | | 2 parts | 16 parts | 2 parts | | 46.67 parts | 0.6 parts | 2 parts |
| Synthesis | P-32 | Q-10, | St, | BAAm, | | NMP, | V-601, | NMP, |
| example 32 | | 2 parts | 10 parts | 8 parts | | 46.67 parts | 0.6 parts | 2 parts |
| Synthesis | P-33 | MMA, | MAA, | | | NMP, | V-601, | NMP, |
| example 33 | | 18 parts | 2 parts | | | 46.67 parts | 0.6 parts | 2 parts |
| Synthesis | P-34 | MMA, | Q-17, | | | NMP, | V-601, | NMP, |
| example 34 | | 18 parts | 2 parts | | | 46.67 parts | 0.6 parts | 2 parts |
| Synthesis | P-35 | MMA, | Q-17, | AA-6, | | NMP, | V-601, | NMP, |
| example 35 | | 2 parts | 2 parts | 16 parts | | 46.67 parts | 0.6 parts | 2 parts |

AS-6: Polystyrene oligomer having a methacryloyl group at its one terminal (Mn=6,000, manufactured by TOAGOSEI CO., LTD.)
AA-6: Polymethyl methacrylate oligomer having a methacryloyl group at its one terminal (Mn=6,000, manufactured by TOAGOSEI CO., LTD.)
AB-6: Poly-n-butyl methacrylate oligomer having a methacryloyl group at its one terminal (Mn=6,000, manufactured by TOAGOSEI CO., LTD.)
PME-1000: BLENMER PME-1000 (trade name), methoxypolyethylene glycol methacrylate (manufactured by Nippon Oil & Fats Co., Ltd.)
PE-350: BLENMER PE-350 (trade name), polyethylene glycol monomethacrylate (manufactured by Nippon Oil & Fats Co., Ltd.)
PP-1000: BLENMER PP-1000 (trade name), polypropylene glycol monomethacrylate (manufactured by Nippon Oil & Fats Co., Ltd.)
PEP-350B: BLENMER 70PEP-350B (trade name), polyethylene glycol polypropylene glycol monomethacrylate (manufactured by Nippon Oil & Fats Co., Ltd.)
FM5: PLACCEL FM5 (trade name), polycaprolactone monomethacrylate (manufactured by Daicel Chemical Industries, Ltd.)
MAA: Methacrylic acid (manufactured by Wako Pure Chemical Industries, Ltd.) St: Styrene (manufactured by Wako Pure Chemical Industries, Ltd.)
DMAPAAm: Dimethylaminopropyl acrylamide (manufactured by Wako Pure Chemical Industries, Ltd.)
DMVBAm: N,N-dimetyl-4-vinylbenzamide
tBuSt: 4-t-butyl styrene (manufactured by TOKYO CHEMICAL INDUSTRY CO., LTD.)
4-Vpy: 4-vinylpyridine
Vim: N-vinylimidazole
AA: Acrylic acid (manufactured by Wako Pure Chemical Industries, Ltd.)
NMP: 1-Methyl-2-pyrrolidone (manufactured by Wako Pure Chemical Industries, Ltd.)
MMA: Methyl methacrylate (manufactured by Wako Pure Chemical Industries, Ltd.)
BMA: Butyl methacrylate (manufactured by Wako Pure Chemical Industries, Ltd.)
tBMA: t-Butyl methacrylate (manufactured by Wako Pure Chemical Industries, Ltd.)
BAAm: Butyl acrylamide (manufactured by Wako Pure Chemical Industries, Ltd.)
MAAm: Methyl acrylamide (manufactured by Wako Pure Chemical Industries, Ltd.)
StMA: Stearyl methacrylate (manufactured by TOKYO CHEMICAL INDUSTRY CO., LTD.)
DMA: Dodecyl methacrylate (manufactured by TOKYO CHEMICAL INDUSTRY CO., LTD.)
IbMA: Iso-bornyl methacrylate (manufactured by aldrich)
CyMA: Cyclohexyl methacrylate (manufactured by Wako Pure Chemical Industries, Ltd.)
M-X and Q-X mean the vinyl monomers corresponding to the repeating units exemplified above.

### Example 1

While 2,500 ml of methanesulfonic acid (manufactured by Wako Pure Chemical Industries, Ltd.) as a first solvent was being heated to 80° C., 112.5 g of a pigment, C.I. Pigment Violet 23 (manufactured by Clariant Corp., Hostaperm Violet RL-NF [trade name]) and 80.0 g of polymethyl methacrylate (mass average molecular weight 20000) were added thereto. Thus, a pigment solution 1 was prepared.

Apart from the above, 2,000 ml of water containing 20 ml of a 1 mol/l sodium hydroxide solution (manufactured by Wako Pure Chemical Industries, Ltd.) as a second solvent was provided.

Here, in the second solvent having the temperature controlled to 25° C. and stirred at 500 rpm by a GK-0222-10 Ramond stirrer (trade name, manufactured by Fujisawa Pharmaceutical Co., Ltd.), the pigment solution 1 heated to 80° C. was injected using an NP-KX-500 large-capacity pulseless flow pump (trade name, manufactured by Nihon Seimitsu Kagaku Co., Ltd.). The flow channel diameter of the liquid transport pipe and the supply inlet diameter for the pigment solution 1 were set at 2.2 mm, and the supply inlet was placed in the second solvent to inject 220 ml of the pigment solution 1 at a flow rate of 200 ml/min. Thereby, organic pigment particles were precipitated and formed, and thus a pigment dispersion liquid was prepared. For the pigment fine particles contained in the obtained pigment dispersion liquid, the particle diameter of the pigment particles was measured using a sample produced by adding dropwise the pigment-dispersion composition on a mesh prepared by extending a supporting film and drying, by performing an observation using a transmission electron microscope (manufactured by JEOL, Ltd., trade name: JEM-2010) at an accelerating voltage of 100 kV. Subsequently, each of 100 or more particles in the measured photographs was subjected to imaging processing, and the average of the particle size was determined.

The pigment dispersion liquid prepared by the procedure described above was concentrated at 3,000 rpm for 90 minutes using an H-110A centrifugal filter [trade name] manufactured by Kokusan Corp. and a P89C filter cloth [trade name] manufactured by Shikishima Canvas Co., Ltd., to reduce the solvent fraction from the pigment dispersion liquid (first concentration removal step). The residue was dried at 80° C. for 12 hours, and thus a powder V-1 composed of the flock of the organic pigment fine particles was obtained (content of organic pigment 59.0% by mass).

The powder V-1 of the organic pigment fine particles was used to prepare a composition as described below, and the composition was dispersed with a motor mill M-50 (manufactured by Eiger Japan K.K.) using zirconia beads having a diameter of 0.65 mm, at a peripheral velocity of 9 m/s for 2 hours. Thus, a pigment-dispersion composition 1 was produced. At this time, the organic pigment fine particles exhibited well self-dispersibility in 1-methoxy-2-propyl acetate.

| | |
|---|---|
| Powder V-1 of organic pigment fine particles | 20.4 g |
| | (pigment 12.04 g) |
| 1-Methoxy-2-propyl acetate (PGMEA) “Third solvent” | 100.0 g |

### [Measurement of Contrast]

The thus-obtained pigment dispersion composition 1 was applied to a glass substrate to give a layer thickness of 2 μm to thereby produce respective samples. As a backlight unit, a three-wavelength cold-cathode-tube light source (FWL18EX-N, trade name, manufactured by Toshiba Lighting & Technology Corporation) provided with a diffuser plate was used. Each of the samples was placed between two sheets of polarizing plates (HLC2-2518, trade name, the polarizing plates were manufactured by Sanritz Corporation), and then amounts of transmitted light at the time when polarization axes of two polarizing plates were parallel and the time when the polarization axes were perpendicular were measured. The ratio of these transmitted light amounts was defined as a contrast (see Color Filter for 512 color display 10.4″-size TFT-LCD, co-authored by Ueki, Koseki, Fukunaga, and Yamanaka, The seventh Color Optics Conference (1990), etc.). The above-described two sheets of polarizing plates, sample, and color luminance meter were placed at the following positions: A polarizing plate was disposed at the distance of 13 mm from the backlight. A cylinder of 11 mm in diameter and 20 mm in length was disposed at the distance of 40 mm to 60 mm from the backlight. The light transmitted through the cylinder was irradiated to a color filter disposed at the distance of 65 mm from the backlight. The transmitted light was passed through another polarizing plate disposed at the distance of 100 mm from the backlight and measured with a color luminance meter disposed at the distance of 400 mm from the backlight. The measuring angle in the color luminance meter was set to 2°. The light amount of the backlight was set so that its brightness (luminance) would be 1280 cd/m², when the two sheets of polarizing plates were arranged in a position of parallel nicol and no color filter was disposed. The determination results of the obtained contrast are summarized in Table 3.

### Examples 2 to 24

### Comparative Examples 1 and 2

Pigment-dispersion compositions 2 to 24 and pigment-dispersion compositions c1 and c2 for comparison were prepared in the same manner as Example 1, except that the component composition of the respective agents used in Example 1 was replaced with as indicated in the following Table 2, and the contrast of the compositions was measured. The results are presented in Table 3. However, when the first solvent was methanesulfonic acid/formic acid, a pigment solution was prepared by heating 2,000 ml of methanesulfonic acid (manufactured by Wako Pure Chemical Industries, Ltd.) and 500 ml of formic acid (manufactured by Wako Pure Chemical Industries, Ltd.) as a first solvent to 60° C. For the second solvent and the third solvent, the same solvents as those used in Example 1 were used. Furthermore, in the case of using a dispersant for redispersion, each of the produced powders of organic pigment fine particles was used to prepare the compositions shown below, and the composition was dispersed with a motor mill M-50 (manufactured by Eiger Japan K.K.) using zirconia beads having a diameter of 0.65 mm, at a peripheral velocity of 9 m/s for 2 hours. Thus, a pigment-dispersion composition was produced. The number average particle size (Mn) of the pigment fine particles of Examples 2 to 24 and Comparative Examples 1 and 2 was determined in the same manner as Example 1 are shown in Table 3-1.

### Example 25

35.9 ml of a 26% methanol solution of tetramethylammonium hydroxide, 50 g of a pigment, C.I. Pigment Red 254 (Irgaphor Red BT-CF, trade name, manufactured by Ciba Specialty Chemicals Corp.), and 50.0 g of the polymer P-1 were added to 1,000 ml of dimethyl sulfoxide (manufactured by Wako Pure Chemical Industries, Ltd.) as the first solvent, and thus a pigment solution 1 was prepared. Apart from this, 1,000 ml of water containing 16 ml of 1 mol/l hydrochloric acid (manufactured by Wako Pure Chemical Industries, Ltd.) as a second solvent was prepared.

Here, in 1,000 ml of the second solvent having the temperature controlled to 5° C. and stirred at 500 rpm by a GK-0222-10 Ramond stirrer (trade name, manufactured by Fujisawa Pharmaceutical Co., Ltd.), 100 ml of the pigment solution 1 was injected using an NP-KX-500 large-capacity pulseless flow pump (trade name, manufactured by Nihon Seimitsu Kagaku Co., Ltd.) from a liquid transport pipe having a flow channel diameter of 1.1 mm at a flow rate of 400 ml/min. Thus, organic pigment fine particles were formed, and a pigment nanoparticle dispersion liquid 25 was prepared. The number average particle size (Mn) of the pigment fine particles of Example 25 determined in the same manner as Example 1 is shown in Table 3-1.

The pigment nanoparticle dispersion liquid 25 prepared by the procedure described above was concentrated at 500 rpm for 90 minutes using an H-112 centrifugal filter [trade name] manufactured by Kokusan Corp. and a P89C filter cloth [trade name] manufactured by Shikishima Canvas Co., Ltd., to reduce the solvent fraction from the pigment dispersion liquid (first concentration removal process). The residue was dried at 80° C. for 12 hours, and thus a powder V-25 composed of the flock of the organic pigment fine particles was obtained (content of organic pigment 59.0% by mass).

The powder V-25 of the organic pigment fine particles was used to prepare a composition as described below, and the composition was dispersed with a motor mill M-50 (manufactured by Eiger Japan K.K.) using zirconia beads having a diameter of 0.65 mm, at a peripheral velocity of 9 m/s for 12 hours. Thus, a pigment-dispersion composition 25 was produced.

| | |
|---|---|
| Powder V-25 of organic pigment fine particles | 20.4 g (pigment 12.04 g) |
| Solsperse 39000 (trade name, described below) | 1.2 g |
| 1-Methoxy-2-propyl acetate (PGMEA) | 98.8 g |
| “Third solvent” | |

### Examples 26 to 60

### Comparative Examples 3 and 4

Pigment-dispersion compositions 26 to 60 (Examples 26 to 60) and pigment-dispersion compositions c3 and c4 for comparison (Comparative examples 3 and 4) were prepared in the same manner as Example 25, except that the component composition of the respective agents used in Example 25 was replaced with as indicated in the following Table. For the second solvent and the third solvent, the same solvents as those used in Example 25 were used. The number average particle size (Mn) of the pigment fine particles of Examples 26 to 60 and Comparative Examples 3 and 4 was determined in the same manner as Example 1 are shown in Table 3-1.

TABLE 2

| | | | | | | Dispersant |
|---|---|---|---|---|---|---|
| | Dispersion | | Polymer compound contained in pigment | | | used in the |
| | composition | Pigment | solution | Other component | First solvent | re-dispersion |
| Example 1 | 1 | PV-23 | Polymethyl methacrylate (80.0 g) | | MSA | |
| Example 2 | 2 | PV-23 | Polymethyl methacrylate (80.0 g) | | MSA/formic | |
| | | | | | acid | |
| Example 3 | 3 | PV-23 | Polymethyl methacrylate (64.0 g), | | MSA/formic | |
| | | | Polypropylene glycol (16.0 g) | | acid | |
| Example 4 | 4 | PV-23 | Polymethyl methacrylate (40.0 g), Poly(ε- | PVP (10.0 g) | MSA/formic | |
| | | | caprolactone) (30.0 g) | | acid | |
| Example 5 | 5 | PV-23 | Methyl methacrylate/styrene copolymer (80.0 g) | | MSA | |
| Example 6 | 6 | PV-23 | P-34 (80 g) | | MSA | |
| Example 7 | 7 | PV-23 | P-35 (80 g) | | MSA/formic | |
| | | | | | acid | |
| Example 8 | 8 | PV-23 | Poly(ε-caprolactone) (80.0 g) | | MSA/formic | |
| | | | | | acid | |
| Example 9 | 9 | PV-23 | Polypropylene glycol (80.0 g) | | MSA/formic | |
| | | | | | acid | |
| Example 10 | 10 | PV-23 | Benzyl methacrylate/acrylic acid copolymer | | MSA/formic | |
| | | | (80.0 g) | | acid | |
| Example 11 | 11 | PV-23 | Methyl methacrylate/dimethylaminopropyl | | MSA/formic | |
| | | | acrylamide copolymer (80.0 g) | | acid | |
| Example 12 | 12 | PV-23 | Polymethyl methacrylate (80.0 g) | | MSA | Solsperse |
| | | | | | | 39000 |
| Example 13 | 13 | PV-23 | Polymethyl methacrylate (64.0 g) | Poly(allylamine | MSA | Solsperse |
| | | | | hydrochloride) (16.0 g) | | 55000 |
| Example 14 | 14 | PV-23 | Polymethyl methacrylate (64.0 g) | Polyacrylic acid (16.0 g) | MSA/formic | Solsperse |
| | | | | | acid | 39000 |
| Example 15 | 15 | PV-23 | Methyl methacrylate/styrene copolymer | n-Dodecylamine (16.0 g) | MSA/formic | Solsperse |
| | | | (64.0 g) | | acid | 55000 |
| Example 16 | 16 | PV-23 | Methyl methacrylate/styrene copolymer | EFKA6745 (16.0 g) | MSA | Solsperse |
| | | | (64.0 g) | | | 39000 |
| Example 17 | 17 | PV-23 | Benzyl methacrylate/acrylic acid copolymer | | MSA/formic | Solsperse |
| | | | (80.0 g) | | acid | 39000 |
| Example 18 | 18 | PV-23 | Methyl methacrylate/dimethylaminopropyl | | MSA/formic | Solsperse |
| | | | acrylamide copolymer (80.0 g) | | acid | 55000 |
| Example 19 | 19 | PV-23 | P-1 (80 g) | | MSA | Solsperse |
| | | | | | | 39000 |
| Example 20 | 20 | PV-23 | P-2 (80 g) | | MSA | |
| Example 21 | 21 | PV-23 | P-12 (80 g) | | MSA/formic | Solsperse |
| | | | | | acid | 55000 |
| Example 22 | 22 | PV-23 | P-18 (80 g) | | MSA | |
| Example 23 | 23 | PV-23 | P-24 (80 g) | | MSA | |
| Example 24 | 24 | PV-23 | P-30 (80 g) | | MSA | |
| Comparative | c1 | PV-23 | PVP (80 g) | None | MSA | |
| example 1 | | | | | | |
| Comparative | c2 | PV-23 | PVP (80 g) | None | | Solsperse |
| example 2 | | | | | | 55000 |
| Example 25 | 25 | PR-254 | P-1 (50 g) | | DMSO/TMAH | Solsperse |
| | | | | | | 39000 |
| Example 26 | 26 | PR-254 | Polymethyl methacrylate (40.0 g) | Polyacrylic acid (10.0 g) | DMSO/TMAH | Solsperse |
| | | | | | | 39000 |
| Example 27 | 27 | PR-254 | P-2 (50 g) | | NMP/TMAH | |
| Example 28 | 28 | PR-254 | P-3 (50 g) | | NMP/TMAH | |
| Example 29 | 29 | PR-254 | P-4 (50 g) | | NMP/TMAH | |
| Example 30 | 30 | PR-254 | P-5 (50 g) | | NMP/TMAH | |
| Example 31 | 31 | PR-254 | P-6 (50 g) | | NMP/TMAH | |
| Example 32 | 32 | PR-254 | P-7 (50 g) | | NMP/TMAH | |
| Example 33 | 33 | PR-254 | P-8 (50 g) | | NMP/TMAH | |
| Example 34 | 34 | PR-254 | P-9 (50 g) | | NMP/TMAH | |
| Example 35 | 35 | PR-254 | P-10 (50 g) | | NMP/TMAH | Solsperse |
| | | | | | | 55000 |
| Example 36 | 36 | PR-254 | P-11 (50 g) | | NMP/TMAH | |
| Example 37 | 37 | PR-254 | P-12 (50 g) | | DMSO/TMAH | |
| Example 38 | 38 | PR-254 | P-13 (50 g) | | DMSO/TMAH | |
| Example 39 | 39 | PR-254 | P-14 (50 g) | | DMSO/TMAH | Solsperse |
| | | | | | | 55000 |
| Example 40 | 40 | PR-254 | P-15 (50 g) | | NMP/TMAH | |
| Example 41 | 41 | PR-254 | P-16 (50 g) | | NMP/TMAH | |
| Example 42 | 42 | PR-254 | P-17 (50 g) | | NMP/TMAH | |
| Example 43 | 43 | PR-254 | P-18 (50 g) | | NMP/TMAH | |
| Example 44 | 44 | PR-254 | P-19 (50 g) | | NMP/TMAH | |
| Example 45 | 45 | PR-254 | P-20 (50 g) | | NMP/TMAH | |
| Example 46 | 46 | PR-254 | P-21 (50 g) | | NMP/TMAH | |
| Example 47 | 47 | PR-254 | P-22 (50 g) | | NMP/TMAH | |
| Example 48 | 48 | PR-254 | P-23 (50 g) | | DMSO/TMAH | Solsperse |
| | | | | | | 39000 |
| Example 49 | 49 | PR-254 | P-24 (50 g) | | NMP/TMAH | |
| Example 50 | 50 | PR-254 | P-25 (50 g) | | NMP/TMAH | |
| Example 51 | 51 | PR-254 | P-26 (50 g) | | NMP/TMAH | |
| Example 52 | 52 | PR-254 | P-27 (50 g) | | DMSO/TMAH | Solsperse |
| | | | | | | 55000 |
| Example 53 | 53 | PR-254 | P-28 (50 g) | | DMSO/TMAH | Solsperse |
| | | | | | | 39000 |
| Example 54 | 54 | PR-254 | P-29 (50 g) | | DMSO/TMAH | Solsperse |
| | | | | | | 39000 |
| Example 55 | 55 | PR-254 | P-30 (50 g) | | DMSO/TMAH | Solsperse |
| | | | | | | 55000 |
| Example 56 | 56 | PR-254 | P-31 (50 g) | | DMSO/TMAH | Solsperse |
| | | | | | | 39000 |
| Example 57 | 57 | PR-254 | P-32 (50 g) | | DMSO/TMAH | Solsperse |
| | | | | | | 55000 |
| Example 58 | 58 | PR-254 | P-33 (50 g) | | DMSO/TMAH | Solsperse |
| | | | | | | 39000 |
| Example 59 | 59 | PR-254 | Polymethyl methacrylate (80.0 g) | None | DMSO/SM-28 | |
| Example 60 | 60 | PR-254 | Methyl methacrylate/styrene copolymer | None | DMSO/SM-28 | |
| | | | (80.0 g) | | | |
| Comparative | c3 | PR-254 | PVP (80.0 g) | None | DMSO/base | |
| example 3 | | | | | | |
| Comparative | c4 | PR-254 | PVP (80.0 g) | None | DMSO/base | Solsperse |
| example 4 | | | | | | 55000 |

Polymethyl methacrylate (water-insoluble polymer compound, mass average molecular weight: 20000)

Polypropylene glycol (water-insoluble polymer compound, mass average molecular weight: 3000)

Poly(ε-caprolactone) (water-insoluble polymer compound, mass average molecular weight: 10000)

Methyl methacrylate/styrene copolymer (water-insoluble polymer compound, composition ratio: 80/20 mass %, mass average molecular weight: 10000)

Benzyl methacrylate/acrylic acid copolymer (water-insoluble polymer compound, composition ratio: 95/5 mass %, mass average molecular weight: 20000)

Methyl methacrylate/N,N-dimethylaminopropyl acrylamide copolymer (water-insoluble polymer compound, composition ratio: 90/10 mass %, mass average molecular weight: 30000)

PVP: Polyvinylpyrrolidone (water-soluble polymer compound, manufactured by Wako Pure Chemical Industries, Ltd., trade name: K30, mass average molecular weight: 40000)

EFKA6745 (trade name, manufactured by EFKA Chemicals, pigment derivative)

Poly(allylamine hydrochloride) (manufactured by Nitto Denko K. K, mass average molecular weight: 100000)

Polyacrylic acid (mass average molecular weight: 25000)

Solsperse 55000 (trade name, manufactured by Lubrizol Corp., graft type dispersant)

Solsperse 39000 (trade name, manufactured by Lubrizol Corp., graft type dispersant)

MSA: Methansulfonic acid

MPA: 1-Methoxy-2-propyl acetate

DMSO: Dimethyl sulfoxide

SM-28: 28% methanol solution of sodium methoxide

TMAH: 26% methanol solution of tetramethylammonium hydroxide

TABLE 3

| Example | Dispersion composition | Contrast |
|---|---|---|
| Example 1 | Dispersion composition 1 | 8,000 |
| Example 2 | Dispersion composition 2 | 7,500 |
| Example 3 | Dispersion composition 3 | 8,500 |
| Example 4 | Dispersion composition 4 | 7,500 |
| Example 5 | Dispersion composition 5 | 8,000 |
| Example 6 | Dispersion composition 6 | 8,000 |
| Example 7 | Dispersion composition 7 | 8,500 |
| Example 8 | Dispersion composition 8 | 7,000 |
| Example 9 | Dispersion composition 9 | 7,000 |
| Example 10 | Dispersion composition 10 | 7,500 |
| Example 11 | Dispersion composition 11 | 7,500 |
| Example 12 | Dispersion composition 12 | 12,000 |
| Example 13 | Dispersion composition 13 | 9,000 |
| Example 14 | Dispersion composition 14 | 12,500 |
| Example 15 | Dispersion composition 15 | 12,000 |
| Example 16 | Dispersion composition 16 | 11,500 |
| Example 17 | Dispersion composition 17 | 10,500 |
| Example 18 | Dispersion composition 18 | 11,000 |
| Example 19 | Dispersion composition 19 | 11,000 |
| Example 20 | Dispersion composition 20 | 12,000 |
| Example 21 | Dispersion composition 21 | 9,500 |
| Example 22 | Dispersion composition 22 | 11,000 |
| Example 23 | Dispersion composition 23 | 12,000 |
| Example 24 | Dispersion composition 24 | 10,500 |
| Comparative | Dispersion composition c1 | Gelled |
| example 1 | | |
| Comparative | Dispersion composition c2 | Gelled |
| example 2 | | |
| Example 25 | Dispersion composition 25 | 8,000 |
| Example 26 | Dispersion composition 26 | 9,000 |
| Example 27 | Dispersion composition 27 | 11,000 |
| Example 28 | Dispersion composition 28 | 10,000 |
| Example 29 | Dispersion composition 29 | 7,000 |
| Example 30 | Dispersion composition 30 | 8,000 |
| Example 31 | Dispersion composition 31 | 9,500 |
| Example 32 | Dispersion composition 32 | 9,000 |
| Example 33 | Dispersion composition 33 | 10,000 |
| Example 34 | Dispersion composition 34 | 9,500 |
| Example 35 | Dispersion composition 35 | 7,000 |
| Example 36 | Dispersion composition 36 | 11,000 |
| Example 37 | Dispersion composition 37 | 5,000 |
| Example 38 | Dispersion composition 38 | 6,000 |
| Example 39 | Dispersion composition 39 | 8,000 |
| Example 40 | Dispersion composition 40 | 10,000 |
| Example 41 | Dispersion composition 41 | 10,000 |
| Example 42 | Dispersion composition 42 | 8,500 |
| Example 43 | Dispersion composition 43 | 12,000 |
| Example 44 | Dispersion composition 44 | 9,000 |
| Example 45 | Dispersion composition 45 | 8,000 |
| Example 46 | Dispersion composition 46 | 11,000 |
| Example 47 | Dispersion composition 47 | 8,000 |
| Example 48 | Dispersion composition 48 | 6,000 |
| Example 49 | Dispersion composition 49 | 12,000 |
| Example 50 | Dispersion composition 50 | 11,000 |
| Example 51 | Dispersion composition 51 | 10,500 |
| Example 52 | Dispersion composition 52 | 4,500 |
| Example 53 | Dispersion composition 53 | 6,000 |
| Example 54 | Dispersion composition 54 | 9,000 |
| Example 55 | Dispersion composition 55 | 5,000 |
| Example 56 | Dispersion composition 56 | 6,000 |
| Example 57 | Dispersion composition 57 | 7,000 |
| Example 58 | Dispersion composition 58 | 8,000 |
| Example 59 | Dispersion composition 59 | 9,000 |
| Example 60 | Dispersion composition 60 | 10,500 |
| Comparative | Dispersion composition c3 | Gelled |
| example 3 | | |
| Comparative | Dispersion composition c4 | Gelled |
| example 4 | | |

*Gelled: Gelation occurred during dispersion and measurement was impossible.

TABLE 3-1

| | Number average |
|---|---|
| Example | particle diameter (Mn) |
| Example 1 | 25-30 nm |
| Example 2 | 25-30 nm |
| Example 3 | 25-30 nm |
| Example 4 | 25-30 nm |
| Example 5 | 25-30 nm |
| Example 6 | 25-30 nm |
| Example 7 | 25-30 nm |
| Example 8 | 25-30 nm |
| Example 9 | 25-30 nm |
| Example 10 | 25-30 nm |
| Example 11 | 25-30 nm |
| Example 12 | 25-30 nm |
| Example 13 | 25-30 nm |
| Example 14 | 25-30 nm |
| Example 15 | 25-30 nm |
| Example 16 | 25-30 nm |
| Example 17 | 25-30 nm |
| Example 18 | 25-30 nm |
| Example 19 | 25-30 nm |
| Example 20 | 25-30 nm |
| Example 21 | 25-30 nm |
| Example 22 | 25-30 nm |
| Example 23 | 25-30 nm |
| Example 24 | 25-30 nm |
| Comparative example 1 | Particle diameter could |
| | not be measured. |
| Comparative example 2 | Particle diameter could |
| | not be measured. |
| Example 25 | 25-30 nm |
| Example 26 | 25-30 nm |
| Example 27 | 25-30 nm |
| Example 28 | 25-30 nm |
| Example 29 | 25-30 nm |
| Example 30 | 25-30 nm |
| Example 31 | 25-30 nm |
| Example 32 | 25-30 nm |
| Example 33 | 25-30 nm |
| Example 34 | 25-30 nm |
| Example 35 | 20-25 nm |
| Example 36 | 20-25 nm |
| Example 37 | 20-25 nm |
| Example 38 | 25-30 nm |
| Example 39 | 25-30 nm |
| Example 40 | 25-30 nm |
| Example 41 | 25-30 nm |
| Example 42 | 25-30 nm |
| Example 43 | 25-30 nm |
| Example 44 | 25-30 nm |
| Example 45 | 25-30 nm |
| Example 46 | 25-30 nm |
| Example 47 | 25-30 nm |
| Example 48 | 25-30 nm |
| Example 49 | 20-25 nm |
| Example 50 | 20-25 nm |
| Example 51 | 20-25 nm |
| Example 52 | 20-25 nm |
| Example 53 | 20-25 nm |
| Example 54 | 20-25 nm |
| Example 55 | 25-30 nm |
| Example 56 | 25-30 nm |
| Example 57 | 25-30 nm |
| Example 58 | 25-30 nm |
| Example 59 | 30-35 nm |
| Example 60 | 30-35 nm |
| Comparative example 3 | Particle diameter could |
| | not be measured. |
| Comparative example 4 | Particle diameter could |
| | not be measured. |

As shown in Table 3, the organic pigment fine particles of the dispersion compositions of the comparative examples did not show self-dispersibility and gelled, and the contrast could not be measured. On the other hand, the organic pigment fine particles of the present invention (Examples) exhibited well self-dispersibility and realized high contrast, and exhibited even higher contrast when a dispersant for redispersion was added. From the results above, it was found that according to the present invention, the fine particles could be self-dispersed by allowing the polymer compound that was contained in the pigment solution to be used in dispersion stabilization of the fine particles in the fine particle at the time of precipitation, to effect directly on dispersion stabilization of the third solvent, and therefore, the effort for acquisition or conversion of the polymer compound can be omitted to a large extent, while efficient operation of steps and reduction of cost, as well as production with very high environmental suitability can be achieved.

### Example 61

### [Production of Color Filter (Production by Application Using Slit Nozzle)]

### [Formation of Black (K) Image]

A non-alkali glass substrate was washed by a UV washing device, then brush-washed with a cleaner, and then subjected to ultrasonic washing with ultrapure water. The substrate was heat-treated at 120° C. for 3 minutes to stabilize the surface state.

The glass substrate was cooled and its temperature was adjusted to 23° C. Then, the substrate was coated with a photocurable composition K1 having a composition shown in the following Table 4 by a coater having a slit nozzle for a glass substrate (trade name: MH-1600 manufactured by FAS Asia). Subsequently, a part of the solvent was removed by drying with a VCD (vacuum drying apparatus; manufactured by Tokyo Ohka Kogyo Co., Ltd.) for 30 seconds to eliminate the fluidity of the coating layer, and the glass substrate with the coating layer was pre-baked at 120° C. for 3 minutes to give a photocurable composition layer K1 having a thickness of 2.4 μm.

TABLE 4

| | | |
|---|---|---|
| K pigment dispersion (carbon black) | 25 | mass parts |
| 1-Methoxy-2-propyl acetate | 8.0 | mass parts |
| Methyl ethyl ketone | 53 | mass parts |
| Alkali-soluble resin 2 | 9.1 | mass parts |
| Hydroquinone monomethyl ether | 0.002 | mass part |
| DPHA liquid | 4.2 | mass parts |
| Polymerization initiator A | 0.16 | mass part |
| Surfactant 1 | 0.044 | mass part |

Using a proximity-type exposure machine having a ultrahigh pressure mercury lump (manufactured by Hitachi High-Tech Electronics Engineering Co., Ltd.), the substrate was pattern-exposed at an exposure of 300 mJ/cm² with a distance of 200 μm between the photosensitive resin layer and the surface of an exposing mask (quartz exposure mask having an image pattern) while allowing the substrate and the mask to stand straight.

Then, pure water was sprayed through a shower nozzle to uniformly moisten the surface of the photocurable composition Kl, and shower developing was performed at 23° C. for 80 seconds with a KOH-based developer (containing KOH and a nonionic surfactant, trade name: CDK-1, manufactured by Fuji Film Electronic Materials Co., Ltd.) at a flat nozzle pressure of 0.04 MPa to obtain a patterning image. Subsequently, ultrapure water was sprayed through an ultrahigh pressure washing nozzle at a pressure of 9.8 MPa to remove the residue, to obtain a black (K) image K. Subsequently, the substrate having the black image thereon was heat-treated at 220° C. for 30 minutes.

### [Formation of Red (R) Pixels]

Using a photocurable composition R1 having a composition described in Table 5 below, heat-treated R pixels were formed on the substrate having the K image formed thereon, in the same manner as the formation of the black (K) image.

The thickness of the photocurable composition R1, and the coating amounts of the pigments (C.I.P.R.254 and C.I.P.R.177) are shown below.

| | |
|---|---|
| Thickness of the photocurable composition film (μm) | 1.60 |
| Coating amount of the pigments (g/m²) | 1.00 |
| Coating amount of C.I.P.R.254 (g/m²) | 0.70 |
| Coating amount of C.I.P.R.177 (g/m²) | 0.30 |

TABLE 5

| | | |
|---|---|---|
| R pigment dispersion A (C.I.P.P.254) | 35 | mass parts |
| R pigment dispersion B (C.I.P.P.177) | 6.8 | mass parts |
| 1-Methoxy-2-propyl acetate | 7.6 | mass parts |
| Methyl ethyl ketone | 37 | mass parts |
| Alkali-soluble resin 1 | 0.7 | mass part |
| DPHA solution | 3.8 | mass parts |
| Polymerization initiator B | 0.12 | mass part |
| Polymerization initiator A | 0.05 | mass part |
| Phenothiazine | 0.01 | mass part |
| Surfactant 1 | 0.06 | mass part |

### [Formation of Green (G) Pixels]

Using a photocurable composition G1 having a composition described in Table 6 below, heat treated G pixels were formed on the substrate having the K image and R pixels formed thereon, in the same manner as the formation of the black (K) image. The film thickness of the layer of the photocurable composition G1, and the coating amounts of the pigments (C.I.P.G.36 and C.I.P.Y.150) are shown below.

| | |
|---|---|
| Thickness of the photocurable composition film (μm) | 1.60 |
| Coating amount of the pigments (g/m²) | 1.92 |
| Coating amount of C.I.P.G.36 (g/m²) | 1.34 |
| Coating amount of C.I.P.Y.150 (g/m²) | 0.58 |

TABLE 6

| | | |
|---|---|---|
| G pigment dispersion (C.I.P.G.36) | 28 | mass parts |
| Y pigment dispersion (C.I.P.Y.150) | 15 | mass parts |
| 1-Methoxy-2-propyl acetate | 29 | mass parts |
| Methyl ethyl ketone | 26 | mass parts |
| Cyclohexanone | 1.3 | mass parts |
| Alkali-soluble resin 2 | 2.5 | mass parts |
| DPHA liquid | 3.5 | mass parts |
| Polymerization initiator B | 0.12 | mass part |
| Polymerization initiator A | 0.05 | mass part |
| Phenothiazine | 0.01 | mass part |
| Surfactant 1 | 0.07 | mass part |

### [Formation of Blue (B) Pixels]

Using a photocurable composition B1 having a composition described in Table 7 below, heat-treated B pixels were formed on the substrate having the K image, the R pixels, and the G pixels formed thereon, in the same manner as the formation of the black (K) image, so that a desired color filter was obtained.

The thickness of the photocurable composition layer B1, and the coating amounts of the pigments (C.I.P.B.15:6 and C.I.P.V.23) are shown below.

| | |
|---|---|
| Thickness of the photocurable composition layer (μm) | 1.60 |
| Coating amount of the pigments (g/m²) | 0.75 |
| Coating amount of C.I.P.B.15:6 (g/m²) | 0.45 |
| Coating amount of C.I.P.V.23 (g/m²) | 0.30 |

TABLE 7

| | | |
|---|---|---|
| B pigment dispersion (C.I.P.B.15:6) | 15.0 | mass parts |
| V pigment dispersion (C.I.P.V.23) | 7.5 | mass parts |
| 1-Methoxy-2-propyl acetate | 28 | mass parts |
| Methyl ethyl ketone | 26 | mass parts |
| Alkali-soluble resin 3 | 17 | mass parts |
| DPHA liquid | 4.0 | mass parts |
| Polymerization initiator B | 0.17 | mass part |
| Phenothiazine | 0.02 | mass part |
| Surfactant | 0.06 | mass part |

Herein, preparation of the photocurable compositions K1, R1, G1 and B1 described in the above Tables will be explained in more detail.

The photocurable composition K1 was obtained by: measuring off the K pigment dispersion 1 and 1-methoxy-2-propyl acetate respectively in the amounts shown in Table 4, then mixing them at a temperature of 24° C. (±2° C.) and stirring the mixture at 150 rpm for 10 minutes, then measuring off methyl ethyl ketone, the alkali-soluble resin 2, hydroquinone monomethyl ether, the DPHA liquid, the polymerization initiator A (2,4-bis(trichloromethyl)-6-[4′-(N,N-bisethoxycarbonylmethyl)amino-3′-bromophenyl]-s-triazine), and the surfactant 1 respectively in the amounts shown in Table 4, then adding them to the above mixture in this order at a temperature of 25° C. (±2° C.), and then stirring the resultant mixture at 150 rpm at a temperature of 40° C. (±2° C.) for 30 minutes.

Among the composition shown in Table 4, the following components had the following compositions:

K pigment dispersion

| | |
|---|---|
| Carbon black (trade name: Nipex 35, manufactured by Degussa, Japan) | 13.1 mass parts |
| The following pigment-dispersing agent A | 0.65 mass part |
| Polymer (random copolymer of benzyl methacrylate and methacrylic acid (benzyl | 6.72 mass parts |
| methacrylate/methacrylic acid = 72/28 by mol), molecular weight: 37,000) | |
| 1-Methoxy-2-propyl acetate | 79.53 mass parts |

Chemical formula 16

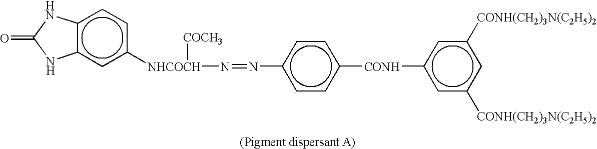

<Alkali-soluble resin 2>

| | |
|---|---|
| Polymer (random copolymer of benzyl methacrylate and | 27 mass parts |
| methacrylic acid (benzyl methacrylate/methacrylic | |
| acid = 78/22 by mol), molecular weight: 38,000) | |
| 1-Methoxy-2-propyl acetate | 73 mass parts |

<DPHA liquid>

| | |
|---|---|
| Dipentaerythritol hexaacrylate (containing 500 ppm | 76 mass parts |
| of polymerization inhibitor MEHQ; manufactured | |
| by Nippon Kayaku Co., Ltd., trade name: | |
| KAYARAD DPHA) | |
| 1-Methoxy-2-propyl acetate | 24 mass parts |

<Surfactant 1>

| | |
|---|---|
| Megafac F-780-F (manufactured by DIC Corporation) | 30 mass parts |
| Copolymer of 40 parts of C₆F₁₃CH₂CH₂OCOCH═CH₂, | |
| 55 parts of H(OCH(CH₃)CH₂)₇OCOCH═CH₂ and | |
| 5 parts of H(OCH₂CH₂)₇OCOCH═CH₂, | |
| (molecular weight: 3 × 10⁴) | |
| Methyl ethyl ketone | 70 mass parts |

The photocurable compostion R1 was obtained by: measuring off the R pigment dispersion A, the R pigment dispersion B, and 1-methoxy-2-propyl acetate respectively in the amounts shown in Table 5, then mixing them at a temperature of 24° C. (±2° C.) and stirring the mixture at 150 rpm for 10 minutes, then measuring off methyl ethyl ketone, the alkali-soluble resin 1, the DPHA liquid, the polymerization initiator B (2-trichloromethyl-5-(p-styrylstyryl)-1,3,4-oxadiazole), the polymerization initiator A, and phenothiazine respectively in the amounts shown in Table 5, then adding them to the above mixture in this order at a temperature of 24° C. (±2° C.) and then stirring the resultant mixture at 150 rpm for 30 minutes, then measuring off the surfactant 1 in the amount shown in Table 5, then adding the surfactant 1 to the mixture at a temperature of 24° C. (±2° C.), then stirring the resultant mixture at 30 rpm for 5 minutes, and then filtering the mixture with a nylon mesh #200.

In the composition described in Table 5, R pigment dispersion A and R pigment dispersion B were prepared using the method described in Example 1 of WO 2006/121016 pamphlet, such that the composition would be as indicated by the following parts by mass.

<R pigment dispersion A>

| | | |
|---|---|---|
| C.I.P.R.254 | 10 | mass parts |
| (trade name: Irgaphor Red BT-CF, manufactured by Ciba | | |
| Specialty Chemicals company) | | |
| Pigment-dispersing agent A (compound 2J shown above) | 1 | mass part |
| Polymer (random copolymer of benzyl methacrylate and | 10 | mass parts |
| methacrylic acid (benzyl methacrylate/methacrylic | | |
| acid = 72/28 by mol), molecular weight: 30,000) | | |
| 1-Methoxy-2-propyl acetate | 79 | mass parts |

<R pigment dispersion B>

| | |
|---|---|
| C.I.P.R.177 (trade name: Cromophtal Red A2B, | 22.5 mass parts |
| manufactured by Ciba Specialty Chemicals company) | |
| Polymer (random copolymer of benzyl methacrylate and | 15 mass parts |
| methacrylic acid (benzyl methacrylate/methacrylic | |
| acid = 72/28 by mol), molecular weight: 30,000) | |
| 1-Methoxy-2-propyl acetate | 62.5 mass parts |

<Alkali-soluble resin 1>

| | |
|---|---|
| Polymer (random copolymer of benzyl methacrylate- | 27 mass parts |
| methacrylic acid-methyl methacrylate (benzyl | |
| methacrylate:methacrylic acid:methyl methacrylate = | |
| 38/25/37 by mol), molecular weight: 40,000) | |
| 1-Methoxy-2-propyl acetate | 73 mass parts |

The photocurable composition G1 was obtained by measuring off the G pigment dispersion, the Y pigment dispersion, and 1-methoxy-2-propyl acetate respectively in the amounts shown in Table 6 then mixing them at a temperature of 24° C. (±2° C.) and stirring the mixture at 150 rpm for 10 minutes, then measuring off methyl ethyl ketone, cyclohexanone, the alkali-soluble resin 2, the DPHA liquid, the polymerization initiator B, the polymerization initiator A and phenothiazine respectively in the amounts shown in Table 6 then adding them to the above mixture in this order at a temperature of 24° C. (±2° C.), then stirring the resultant mixture at 150 rpm for 30 minutes, then measuring off the surfactant 1 in the amount shown in Table 6 then adding the surfactant 1 to the mixture at a temperature of 24° C. (±2° C.), then stirring the resultant mixture at 30 rpm for 5 minutes, and then filtering the mixture with a nylon mesh #200.

Among the compositions shown in Table 6, the G pigment dispersion was “GT-2 (trade name)” manufactured by Fujifilm Electronic Materials Co., Ltd. As the Y pigment dispersion, “CF Yellow EX3393 (trade name)” manufactured by Mikuni Shikiso Co., Ltd. was used.

The photocurable composition B1 was obtained by: measuring off the B pigment dispersion, the V pigment dispersion 1, and 1-methoxy-2-propyl acetate respectively in the amounts shown in Table 7, then mixing them a temperature of 24° C. (±2° C.) and stirring the mixture at 150 rpm for 10 minutes, then measuring off methyl ethyl ketone, the alkali-soluble resin 3, the DPHA liquid, the polymerization initiator B, and phenothiazine respectively in the amounts shown in Table 7, then adding them to the above mixture in this order at a temperature of 25° C. (±2° C.), then stirring the mixture at 150 rpm at a temperature of 40° C. (±2° C.) for 30 minutes, then measuring off the surfactant 1 in the amount shown in Table 7, then adding the surfactant 1 to the mixture at a temperature of 24° C. (±2° C.), then stirring the mixture at 30 rpm for 5 minutes, and then filtering the mixture with a nylon mesh #200.

In the composition shown in Table 7, as the B pigment dispersion, “trade name: CF Blue EX3357” manufactured by Mikuni Shikiso Co., Ltd. was used; and as the V pigment dispersion 1, the pigment-dispersion composition 1 produced in Example 1 was used.

The alkali-soluble resin 3 had the following composition.

<Alkali-soluble resin 3>

| | |
|---|---|
| Polymer (random copolymer of benzyl methacrylate- | 27 mass parts |
| methacrylic acid-methyl methacrylate (benzyl | |
| methacrylate:methacrylic acid:methyl methacrylate = | |
| 36/22/42 by mol), molecular weight: 37,000) | |
| 1-Methoxy-2-propyl acetate | 73 mass parts |

As described above, a color filter 1 was produced. Color filters 2 to 24, c1 and c2 were produced in the same manner as the color filter A, except that the V pigment dispersion composition 1 used in the color filter 1 was replaced with the V pigment-dispersion compositions 2 to 24, c1 and c2, respectively. As the V pigment dispersions 2 to 24, c1 and c2, the pigment-dispersion compositions 2 to 24, c1 and c2 produced respectively in Examples 2 to 24 and Comparative Examples 1 and 2 were used. For each of the color filters, contrast was measured in the same manner as described in [Measurement of contrast], and the results are presented in the following Table 3. In addition, for the V pigment-dispersion compositions c1 and c2, gel-like dispersion compositions in a very highly viscous state were directly used.

TABLE 8

| Example | Color filter | Contrast |
|---|---|---|
| Example 61 | #1 | 6,200 |
| Example 62 | #2 | 5,800 |
| Example 63 | #3 | 6,500 |
| Example 64 | #4 | 5,700 |
| Example 65 | #5 | 6,300 |
| Example 66 | #6 | 6,250 |
| Example 67 | #7 | 6,800 |
| Example 68 | #8 | 5,300 |
| Example 69 | #9 | 5,300 |
| Example 70 | #10 | 5,900 |
| Example 71 | #11 | 5,800 |
| Example 72 | #12 | 10,500 |
| Example 73 | #13 | 7,300 |
| Example 74 | #14 | 10,900 |
| Example 75 | #15 | 10,300 |
| Example 76 | #16 | 9,700 |
| Example 77 | #17 | 9,700 |
| Example 78 | #18 | 9,300 |
| Example 79 | #19 | 10,000 |
| Example 80 | #20 | 10,500 |
| Example 81 | #21 | 8,000 |
| Example 82 | #22 | 10,000 |
| Example 83 | #23 | 11,000 |
| Example 84 | #24 | 10,000 |
| Comparative example 5 | #c1 | 250 |
| Comparative example 6 | #c2 | 400 |

From the results of Table 8, the color filters #1 to #24 of the present invention all had high contrast and could exhibit well display properties when incorporated into a display device. On the other hand, the color filters #c1 and #c2 of the comparative examples had low contrast and were of a level that does not meet the requirements for practical use. From the results, it can be seen that according to the present invention, the above described high performance color filters can be produced efficiently at reduced cost while realizing environmental adaptation, without requiring unnecessary use or conversion of polymer compounds.

### INDUSTRIAL APPLICABILITY

The organic pigment fine particles of the present invention, and a pigment-dispersion composition, a photocurable composition and an inkjet ink containing the organic pigment fine particles can be favorably used in a color filter and a liquid crystal display device using the color filter. The color filter of the present invention has high contrast and is favorable to be incorporated into a display device.

The method of producing organic pigment fine particles of the present invention can produce the organic pigment fine particles described above, with good efficiency and high purity. The method of producing a color filter in the present invention is favorable as a method of efficiently producing a color filter at reduced cost.

Having described our invention as related to the present embodiments, it is our intention that the invention not be limited by any of the details of the description, unless otherwise specified, but rather be construed broadly within its spirit and scope as set out in the accompanying claims.

This non-provisional application claims priority under 35 U.S.C. §119(a) on Patent Application No. 2007-277471 filed in Japan on Oct. 25, 2007, and Patent Application No. 2008-117583 filed in Japan on Apr. 28, 2008, each of which is entirely herein incorporated by reference.

1. Organic pigment fine particles, having capability of self-dispersion, comprising:
an organic pigment and a polymer compound,
the organic pigment fine particles of being nanometer-sized fine particles obtained by mixing an organic pigment solution and a second solvent, thereby to precipitate the fine particles in the mixed liquid, the organic pigment solution prepared by dissolving the organic pigment and the polymer compound in a first solvent, the second solvent of being served as a poor solvent for the organic pigment and being compatible with the first solvent,
wherein a compound insoluble in the second solvent is used as the polymer compound, and the organic pigment fine particles are provided with a capability of self-dispersing in a third solvent different from any of the first solvent and the second solvent.

2. The organic pigment fine particles according to claim 1, wherein a mass average molecular weight of the polymer compound is 1,000 to 500,000.

3. The organic pigment fine particles according to claim 1, wherein the polymer compound is at least one selected from the group consisting of a polymer or copolymer of a vinyl monomer, an ester polymer, an ether polymer, a modified substance thereof, and a copolymer thereof.

4. The organic pigment fine particles according to claim 1, wherein the polymer compound is a polymer and/or copolymer of a vinyl monomer having a hydrocarbon group having 4 or more carbon atoms.

5. The organic pigment fine particles according to claim 1, wherein the polymer compound comprises a repeating unit represented by formula (1): 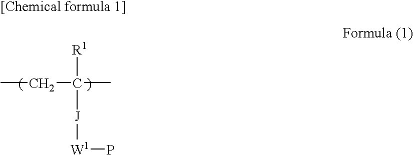
wherein R¹ represents a hydrogen atom or a methyl group; J represents —CO—, —COO—, —CONR⁶—, —OCO—, a phenylene group, or —C₆H₄CO—; R⁶ represents a hydrogen atom, an alkyl group, an aryl group, or an aralkyl group; W¹ represents a straight-chain, branched, or cyclic alkylene group or aralkylene group, or a single bond; and P represents a heterocyclic group.

6. The organic pigment fine particles according to claim 1, wherein the polymer compound comprises a repeating unit represented by formula (2) or (3): 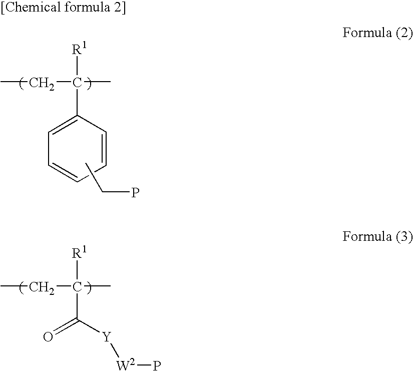
wherein R¹ represents a hydrogen atom or a methyl group; Y represents —NH—, —O—, or —S—; W² represents a single bond or a divalent linking group; and P represents a heterocyclic group.

7. The organic pigment fine particles according to claim 5, wherein P in formula (1), (2) and (3) is represented by formula (4) or a tautomeric structure thereof: 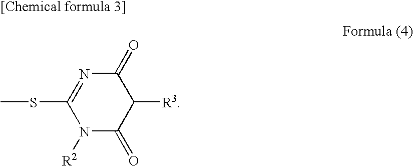
wherein R² represents a substituted or unsubstituted alkyl group, a substituted or unsubstituted aryl group, or a hydrogen atom; and R³ represents a hydrogen atom, an alkyl group, an aryl group, a halogen atom, or an azo group.

8. The organic pigment fine particles according to claim 1, wherein the polymer compound is a graft copolymer having a side chain formed from a polymerizable oligomer having an ethylenically unsaturated double bond at its terminal.

9. The organic pigment fine particles according to claim 1, wherein the organic pigment solution further comprises at least one organic compound having a basic group or an acidic group.

10. The organic pigment fine particles according to claim 1, wherein the organic pigment solution and the second solvent are mixed under a condition in which a Reynolds number Re represented by expression (1) is 50 or more:
Re=ρUL/μ (1)
wherein Re represents the Reynolds number; ρ represents a density of the organic pigment solution; U represents a relative velocity at which the organic pigment solution comes in contact with the second solvent; L represents an equivalent diameter of a flow path or a supply inlet at a part where the organic pigment solution comes in contact with the second solvent; and μ represents a viscosity coefficient of the organic pigment solution.

11. The organic pigment fine particles according to claim 1, wherein the first solvent is at least one selected from the group consisting of an organic acid, an organic base, a sulfoxide compound solvent, and an amide compound solvent.

12. The organic pigment fine particles according to claim 1, wherein the second solvent is at least one selected from the group consisting of an aqueous medium and an alcohol compound solvent.

13. The organic pigment fine particles according to claim 1, wherein the third solvent is at least one selected from the group consisting of an ether compound solvent, an ester compound solvent, an aromatic hydrocarbon compound solvent, and an aliphatic hydrocarbon compound solvent.

14. The organic pigment fine particles according to claim 1, wherein the organic pigment solution comprises the polymer compound in an amount of 10 to 300 parts by mass, to 100 parts by mass of the organic pigment.

15. A method of producing organic pigment fine particles, comprising the steps of:
mixing an organic pigment solution with a second solvent, an organic pigment solution prepared by dissolving an organic pigment and a polymer compound in a first solvent, the second solvent of being served as a poor solvent for the organic pigment and being compatible with the first solvent; to precipitate nanometer-sized fine particles having the organic pigment and the polymer compound in the mixed liquid,
wherein a compound insoluble in the second solvent is used as the polymer compound, and the organic pigment fine particles are provided with a capability of self-dispersing in a third solvent different from any of the first solvent and the second solvent.

16. A pigment-dispersion composition prepared by self-dispersing the organic pigment fine particles according to claim 1 in the third solvent.

17. The pigment-dispersion composition according to claim 16, further comprising a pigment dispersant.

18. A photocurable composition, comprising the pigment-dispersion composition according to claim 16, a photopolymerizable compound, and a photopolymerization initiator.

19. The photocurable composition according to claim 18, further comprising an alkali-soluble resin.

20. The photocurable composition according to claim 18, which is used for a color filter.

21. A color filter, comprosing a colored pattern, formed on a substrate, by using the photocurable composition according to claim 18.

22. A method of producing a color filter, comprising the steps of:
a photosensitive film forming step of forming a photosensitive film by applying the photocurable composition according to claim 18 on a substrate directly or a predetermined layer disposed on the substrate, and
a colored pattern forming step of forming a colored pattern by subjecting the formed photosensitive film to a pattern exposure and a development in this order.

23. An inkjet ink prepared by incorporating the organic pigment fine particles according to claim 1, into a medium containing a polymerizable monomer and/or a polymerizable oligomer.

24. The inkjet ink according to claim 23, which is used for a color filter.
